(19) United States
(12) Patent Application Publication
(10) Pub. No.: US 2024/0118619 A1
(43) Pub. Date: Apr. 11, 2024

(54) RESIST COMPOSITION AND RESIST PATTERN FORMING METHOD

(71) Applicant: TOKYO OHKA KOGYO CO., LTD., Kawasaki-shi (JP)

(72) Inventors: Keiichi Ibata, Kawasaki-shi (JP); Tomotaka Yamada, Kawasaki-shi (JP)

(21) Appl. No.: 18/460,104

(22) Filed: Sep. 1, 2023

(30) Foreign Application Priority Data
Sep. 6, 2022 (JP) 2022-141319

(51) Int. Cl. G03F 7/075; G03F 7/004; G03F 7/20

(52) U.S. Cl. CPC G03F 7/0757; G03F 7/0045; G03F 7/2004

(57) ABSTRACT

A resist composition including a silicon-containing resin and an acid generator component that generates acid upon exposure. The acid generator component includes an onium salt containing an anion moiety having an iodine atom and a cation moiety.

### BACKGROUND OF THE INVENTION

### Field of the Invention

The present invention relates to a resist composition and a resist pattern forming method.

Priority is claimed on Japanese Patent Application No. 2022-141319, filed on Sep. 6, 2022, the content of which is incorporated herein by reference.

### Description of Related Art

In the manufacture of electronic components, a treatment including etching is carried out on a laminate in which a resist film is formed on a substrate such as a silicon wafer using a resist material. For example, a treatment in which a resist pattern is formed on a resist film by selectively exposing the resist film, and dry etching is carried out using the resist film as a mask to form a pattern on the substrate is carried out.

In recent years, in the production of semiconductor elements and liquid crystal display elements, with advances in lithography techniques, rapid progress in the field of pattern fining has been achieved. In general, the pattern fining technique involves shortening the wavelength (increasing the energy) of the light source for exposure.

Resist materials have been required to have lithography characteristics such as sensitivity to these light sources for exposure and resolution capable of reproducing a fine-sized pattern.

As a resist material that satisfies these requirements, a chemical amplification-type resist composition that contains a base material component having solubility in a developing solution, which is changed under action of acid, and an acid generator component that generates acid upon exposure has been used in the related art.

In the chemical amplification-type resist composition, a resin having a plurality of constitutional units is generally used in order to improve lithography characteristics. In addition, a chemical amplification-type resist composition in which an acid generator component is used in combination with an acid diffusion controlling agent that controls the diffusion of the acid generated from the acid generator component upon exposure has been proposed.

Further, as the resist material, a material having etching resistance is required in order to fulfill the function as a mask for substrate processing. On the other hand, a silicon-containing resin is generally used as a base material component.

For example, Patent Document 1 discloses a resist composition containing a silicon-containing resin, an acid generator component, and a photodecomposable base that controls the diffusion of acid in order to cope with pattern fining and etching processing. In [Examples] of Patent Document 1, a pattern on the order of several μm is formed by irradiation with a KrF excimer laser, and a 50 nm pattern is formed by drawing with an electron beam.

### DESCRIPTION OF RELATED ART

### Patent Document

[Patent Document 1] Japanese Unexamined Patent Application, First Publication No. 2022-59575

### SUMMARY OF THE INVENTION

With further advances in lithography techniques, rapid progress in the field of pattern fining is being achieved together with the expansion of application fields. In association with this, in a case of producing a semiconductor element or the like, a technique that makes it possible to form a fine-sized pattern in a favorable shape is required. For example, lithography using an extreme ultraviolet ray (EUV) aims to form a fine pattern in a range of ten and several nm. As the pattern size becomes smaller as described above, it becomes difficult to achieve both etching resistance and lithography characteristics.

The present invention has been made in consideration of the above circumstances, and an object of the present invention is to provide a resist composition which makes it possible to form a fine-sized pattern having both etching resistance and lithography characteristics, and a resist pattern forming method using the resist composition.

In order to achieve the above-described object, the present invention employs the following configurations.

That is, a first aspect of the present invention is a resist composition characterized by containing a silicon-containing resin (A) and an acid generator component (B) that generates acid upon exposure, in which the acid generator component (B) includes an onium salt (B0) consisting of an anion moiety having an iodine atom and a cation moiety.

A second aspect of the present invention is a resist pattern forming method, which is characterized by including a step (i) of forming a resist film on a support using the resist composition according to the first aspect, a step (ii) of exposing the resist film, and a step (iii) of developing the exposed resist film to form a resist pattern.

According to the present invention, it is possible to provide a resist composition which makes it possible to form a fine-sized pattern having both etching resistance and lithography characteristics, and a resist pattern forming method using the resist composition.

### DETAILED DESCRIPTION OF THE INVENTION

In the present specification and the scope of the present patent claims, the term “aliphatic” is a relative concept used with respect to the term “aromatic” and defines a group or compound that has no aromaticity.

The term “alkyl group” includes a monovalent saturated hydrocarbon group that is linear, branched, or cyclic unless otherwise specified. The same applies to the alkyl group of an alkoxy group.

The term “alkylene group” includes a divalent saturated hydrocarbon group that is linear, branched, or cyclic unless otherwise specified.

Examples of the “halogen atom” include a fluorine atom, a chlorine atom, a bromine atom, and an iodine atom.

The term “constitutional unit” means a monomer unit (a monomeric unit) that contributes to the formation of a polymeric compound (a resin, a polymer, or a copolymer).

In a case where the phrase “may have a substituent” is described, both of a case where a hydrogen atom (—H) is substituted with a monovalent group and a case where a methylene group (—CH₂—) is substituted with a divalent group are included.

The term “exposure” is used as a general concept that includes irradiation with active energy rays such as an ultraviolet ray, a radiation, and an electron beam.

The term “acid decomposable group” is a group having acid decomposability, in which at least part of bonds in the structure of the acid decomposable group can be cleaved under action of acid.

Examples of the acid decomposable group having a polarity that is increased under action of acid include groups that are decomposed under action of acid to generate a polar group.

Examples of the polar group include a carboxy group, a hydroxyl group, an amino group, and a sulfo group (—SO₃H).

More specific examples of the acid decomposable group include a group (for example, a group obtained by protecting a hydrogen atom of the OH-containing polar group with an acid dissociable group) obtained by protecting the above-described polar group with an acid dissociable group.

The term “acid dissociable group” refers to any one of (i) a group having acid decomposability, in which a bond between the acid dissociable group and an atom adjacent to the acid dissociable group can be cleaved under action of acid; and (ii) a group in which part of bonds are cleaved under action of acid, and then a decarboxylation reaction occurs, thereby cleaving the bond between the acid dissociable group and the atom adjacent to the acid dissociable group.

It is necessary that the acid dissociable group that constitutes the acid decomposable group be a group that exhibits a lower polarity than the polar group generated by the dissociation of the acid dissociable group. Thus, in a case where the acid dissociable group is dissociated under action of acid, a polar group that exhibits a higher polarity than the acid dissociable group is generated, thereby increasing the polarity. As a result of the above, the polarity of the total components having this acid dissociable group is increased. With the increase in the polarity, the solubility in a developing solution relatively changes. The solubility in a developing solution is increased in a case where the developing solution is an alkali developing solution, whereas the solubility in a developing solution is decreased in a case where the developing solution is an organic developing solution.

The term “base material component” is an organic compound having a film-forming ability. The organic compounds used as the base material component are roughly classified into a non-polymer and a polymer. As the non-polymer, those having a molecular weight of 500 or more and less than 4,000 are generally used. Hereinafter, a “low molecular weight compound” refers to a non-polymer having a molecular weight of 500 or more and less than 4,000. As the polymer, those having a molecular weight of 1,000 or more are generally used. Hereinafter, a “resin”, a “polymeric compound”, or a “polymer” refers to a polymer having a molecular weight of 1,000 or more. As the molecular weight of the polymer, a weight average molecular weight in terms of the polystyrene equivalent value determined by gel permeation chromatography (GPC) is used.

The term “constitutional unit derived from” means a constitutional unit that is formed by the cleavage of a multiple bond between carbon atoms, for example, an ethylenic double bond.

The term “derivative” is used as a concept that includes a compound obtained by substituting a hydrogen atom at the α-position of an object compound with another substituent such as an alkyl group or a halogenated alkyl group; and a derivative thereof. Examples of the derivatives thereof include a derivative in which the hydrogen atom of the hydroxyl group of the object compound in which the hydrogen atom at the α-position may be substituted with a substituent is substituted with an organic group; and a derivative in which a substituent other than a hydroxyl group is bonded to the object compound in which the hydrogen atom at the α-position may be substituted with a substituent. It is noted that the α-position refers to the first carbon atom adjacent to the functional group unless otherwise specified.

In the present specification and the scope of the present patent claims, asymmetric carbon atoms may be present, and thus enantiomers or diastereomers may be present depending on the structures represented by the chemical formula. In that case, these isomers are represented by one chemical formula. These isomers may be used alone or in the form of a mixture.

(Resist Composition)

The resist composition according to the first aspect of the present invention contains a silicon-containing resin (A) (hereinafter, also referred to as a “component (A)”) and an acid generator component (B) that generates acid upon exposure (hereinafter, also referred to as a “component (B)”).

In the resist composition according to the present aspect, the component (B) includes an onium salt (B0) consisting of an anion moiety having an iodine atom and a cation moiety.

The resist composition according to the present embodiment may be used for an alkali developing process in which an alkali developing solution is used in the developing treatment in the formation of a resist pattern, or may be used for a solvent developing process in which a developing solution containing an organic solvent (organic developing solution) used in the developing treatment. Among the above, the resist composition of the present embodiment is particularly useful for an alkali developing process.

That is, in a case where the resist composition according to the present embodiment is a “negative-tone resist composition for an alkali developing process” that forms a negative-tone resist pattern in an alkali developing process or a “positive-tone resist composition for a solvent developing process” that forms a positive-tone resist pattern in a solvent developing process, a base material component soluble in an alkali developing solution is used as the preferred component (A), and a crosslinking agent component is further blended thereto. In such a resist composition, in a case where acid is generated from the component (B) upon exposure, the acid acts to cause crosslinking between the base material component soluble in an alkali developing solution and the crosslinking agent component, and as a result, the solubility in an alkali developing solution is decreased (the solubility in an organic developing solution is increased).

Therefore, in the resist pattern formation, by conducting selective exposure of a resist film formed by applying the resist composition onto a support, the exposed portions of the resist film change to an insoluble state in an alkali developing solution (a soluble state in an organic developing solution), whereas the unexposed portions of the resist film remain soluble in an alkali developing solution (an insoluble state in an organic developing solution), and thus a negative-tone resist pattern is formed by carrying out development with the alkali developing solution. Further, in this case, a positive-tone resist pattern is formed by developing with the organic developing solution.

That is, in a case where the resist composition according to the present embodiment is a “positive-tone resist composition for an alkali developing process” that forms a positive-tone resist pattern in an alkali developing process or a “negative-tone resist composition for a solvent developing process” that forms a negative-tone resist pattern in a solvent developing process, a base material component having a polarity that is increased under action of acid is used as the preferred component (A). In a case of using a base material component having a polarity that is increased under action of acid, the polarity of the base material component changes before and after the exposure, and thus it is possible to obtain a favorable development contrast not only in the alkali developing process but also in the solvent developing process.

In a case of applying an alkali developing process, a base material component having a polarity that is increased under action of acid is substantially insoluble in an alkali developing solution prior to exposure. However, in a case where acid is generated from the component (B) upon exposure, the action of this acid causes an increase in the polarity, thereby increasing the solubility in an alkali developing solution.

Therefore, in the resist pattern formation, in a case of carrying out selective exposure of a resist film formed by applying the resist composition onto a support, exposed portions of the resist film change from an insoluble state to a soluble state in an alkali developing solution, whereas unexposed portions of the resist film remain insoluble in an alkali developing solution, and thus, a positive-tone resist pattern is formed by alkali developing. Alternatively, in this case, a negative-tone resist pattern is formed in a case where development is carried out with an organic developing solution.

<Silicon-Containing Resin (A)>

Examples of the silicon-containing resin (the component (A)) that is used in the resist composition of the present embodiment include a resin that is soluble in an alkali developing solution and has a crosslinkable group, or a resin having a polarity that is increased under action of acid, thereby having increased solubility in an alkali developing solution.

In the resist composition of the present embodiment, the silicon content proportion in the component (A) is preferably 10% by mass or more and 30% by mass or less, more preferably 10% by mass or more and 25% by mass or less, and still more preferably 12% by mass or more and 24% by mass or less, with respect to the total mass of all the atoms constituting the component (A).

In a case where the silicon content proportion in the component (A) is equal to or larger than the lower limit value of the above-described preferred range, the etching resistance is further enhanced, whereas in a case where it is equal to or smaller than the upper limit value of the above-described preferred range, a resist pattern having favorable lithography characteristics is easily formed.

The silicon content proportion in the component (A) can be calculated according to the following expression.

The silicon content proportion (%)=(the number of silicon atoms present in the silicon-containing resin×the atomic weight of silicon)/(the total atomic weight calculated by multiplying the number of atoms of each atom constituting the silicon-containing resin by each atomic weight and summing up each value obtained)×100

For example, in a case of a polysiloxane consisting of a repeating structure of a constitutional unit represented by —[Si(H)O_{3/2}]—, the silicon content proportion is, {(28×1)×100)}/[{(28×1)+(16×1.5)+(1×1)}×100]≈52.8%.

In a case of a polysiloxane consisting of 30% by mole of a constitutional unit represented by —[Si(H)O_{3/2}]— and 70% by mole of a constitutional unit represented by —[Si(CH₃)O_{3/2}]—, the silicon content proportion is, {(28×1)×100}/<[{(28×1)+(16×1.5)+(1×1)}×30]+[{(28×1)+(16×1.5)+(12×1)+(1×3)}×70]>≈44.6%.

The silicon content proportion can be adjusted, for example, by changing the structure or compositional ratio of each constitutional unit constituting the silicon-containing resin.

The component (A) may be any resin containing silicon and is preferably a polysiloxane. Among the above, a silsesquioxane resin is more preferably contained.

<<Silsesquioxane Resin>>

Examples of the silsesquioxane resin in the present embodiment include a silicon-containing polymer (A0) in which the polymer main chain consists of a repeating structure of Si—O bonds and preferably has a constitutional unit represented by General Formula (a0-1).

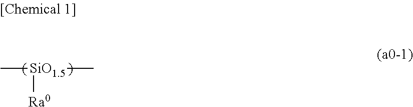

[In the formula, Ra⁰ represents an organic group having 1 to 40 carbon atoms or a hydrogen atom.]

In General Formula (a0-1), examples of the organic group having 1 to 40 carbon atoms as Ra⁰ include a hydrocarbon group which may have a substituent.

Examples of the hydrocarbon group which may have a substituent include a cyclic group which may have a substituent, a chain-like aliphatic hydrocarbon group which may have a substituent, and a group obtained by combining these.

The cyclic group as Ra⁰ is preferably a cyclic hydrocarbon group, and the cyclic hydrocarbon group may be an aromatic hydrocarbon group or may be a cyclic aliphatic hydrocarbon group. In addition, the aliphatic hydrocarbon group may be saturated or may be unsaturated.

The aromatic hydrocarbon group referred to here is a hydrocarbon group having an aromatic ring. Specific examples of the aromatic ring contained in the aromatic hydrocarbon group include benzene, fluorene, naphthalene, anthracene, phenanthrene, biphenyl, and an aromatic heterocyclic ring obtained by substituting part of carbon atoms constituting one of these aromatic rings with a hetero atom. Examples of the hetero atom in the aromatic heterocyclic rings include an oxygen atom, a sulfur atom, and a nitrogen atom.

Specific examples of the aromatic hydrocarbon group include a group (an aryl group such as a phenyl group or a naphthyl group) obtained by removing one hydrogen atom from the above-described aromatic ring and a group (an arylalkyl group such as a benzyl group, a phenethyl group, a 1-naphthylmethyl group, a 2-naphthylmethyl group, 1-naphthylethyl group, or a 2-naphthylethyl group) obtained by substituting one hydrogen atom in the aromatic ring with an alkylene group. The alkylene group (an alkyl chain in the arylalkyl group) preferably has 1 to 4 carbon atoms, more preferably 1 or 2 carbon atoms, and particularly preferably 1 carbon atom.

Examples of the cyclic aliphatic hydrocarbon group referred to here include aliphatic hydrocarbon groups containing a ring in the structure thereof.

Examples of the aliphatic hydrocarbon group containing a ring in the structure thereof include an alicyclic hydrocarbon group (a group obtained by removing one hydrogen atom from an aliphatic hydrocarbon ring), a group in which the alicyclic hydrocarbon group is bonded to the terminal of a linear or branched aliphatic hydrocarbon group, and a group in which the alicyclic hydrocarbon group is interposed in a linear or branched aliphatic hydrocarbon group.

The alicyclic hydrocarbon group preferably has 3 to 20 carbon atoms and more preferably 3 to 12 carbon atoms.

The alicyclic hydrocarbon group may be a polycyclic group or a monocyclic group. The monocyclic alicyclic hydrocarbon group is preferably a group obtained by removing one or more hydrogen atoms from a monocycloalkane. The monocycloalkane preferably has 3 to 8 carbon atoms, and specific examples thereof include cyclopentane and cyclohexane. The polycyclic alicyclic hydrocarbon group is preferably a group obtained by removing one or more hydrogen atoms from a polycycloalkane, and the polycycloalkane preferably has 7 to 30 carbon atoms.

The chain-like aliphatic hydrocarbon group as Ra⁰ may be a chain-like saturated aliphatic hydrocarbon group or may be a chain-like unsaturated aliphatic hydrocarbon group; where the chain-like aliphatic hydrocarbon group may be linear or may be branched.

The substituent which may be contained in the hydrocarbon group as Ra⁰ may be monovalent or divalent.

Examples of the monovalent substituent include a carboxy group, a hydroxy group, an amino group, a sulfo group, a halogen atom, a halogenated alkyl group, an alkoxy group, an alkyloxycarbonyl group, and a nitro group.

Examples of the divalent substituent include —O—, —C(═O)—O—, —C(═O)—, —O—C(═O)—O—, —C(═O)—NH—, —NH—, ═N—, —NH—C(═NH)—, —S—, —S(═O)₂—, and —S(═O)₂—O—. It is noted that H in the divalent substituent may be substituted with an alkyl group or an acyl group.

Examples of the constitutional unit represented by General Formula (a0-1) include a constitutional unit represented by General Formula (a0-1-1) described later, a constitutional unit represented by General Formula (a0-1-2) described later, a constitutional unit represented by General Formula (a0-1-3) described later, and other constitutional units.

Constitutional unit represented by General Formula (a0-1-1) The silicon-containing polymer (A0) is preferably a polymer having a constitutional unit represented by General Formula (a0-1-1).

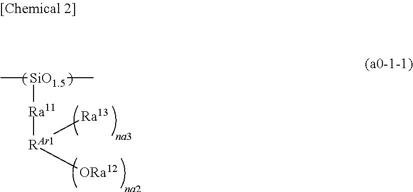

[In the formula, R^{Ar1} represents an aromatic hydrocarbon group. Ra¹¹ represents a divalent linking group or a single bond. Ra¹² represents a hydrocarbon group having 1 to 6 carbon atoms or a hydrogen atom. Ra¹³ represents a hydrocarbon group having 1 to 6 carbon atoms. na2 is 1 or 2. na3 represents an integer in a range of 0 to 4.]

In General Formula (a0-1-1), the aromatic hydrocarbon group as R^{Ar1} is a hydrocarbon group having at least one aromatic ring. The aromatic ring is not particularly limited as long as it is a cyclic conjugated system having (4n+2)π electrons, and the aromatic ring may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms. Here, the number of carbon atoms in a substituent is not included in the number of carbon atoms.

Specific examples of the aromatic ring include benzene, naphthalene, anthracene, and phenanthrene, where benzene or naphthalene is preferable, and benzene is more preferable.

In the aromatic hydrocarbon group as R^{Ar1}, the hydrogen atom bonded to the aromatic ring may be substituted with a substituent. Examples of the substituent include a halogen atom, a halogenated alkyl group, and a hydroxyl group. The halogen atom as the substituent is preferably a fluorine atom. Examples of the halogenated alkyl group as the substituent include a group obtained by substituting part or all of hydrogen atoms in the above-described alkyl group having 1 to 5 carbon atoms with a halogen atom.

In General Formula (a0-1-1), examples of the divalent linking group as Ra¹¹ include a divalent hydrocarbon group which may have a substituent.

The hydrocarbon group as Ra¹¹ may be an aliphatic hydrocarbon group or may be an aromatic hydrocarbon group.

The aliphatic hydrocarbon group as Ra¹¹ may be saturated or may be unsaturated. In general, it is preferable that the aliphatic hydrocarbon group is saturated.

Examples of the aliphatic hydrocarbon group as Ra¹¹ include a linear or branched aliphatic hydrocarbon group, and an aliphatic hydrocarbon group containing a ring in the structure thereof.

Linear or Branched Aliphatic Hydrocarbon Group

The linear aliphatic hydrocarbon group described above preferably has 1 to 10 carbon atoms, more preferably 1 to 6 carbon atoms, still more preferably 1 to 4 carbon atoms, and most preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group described above preferably has 2 to 10 carbon atoms, more preferably 3 to 6 carbon atoms, still more preferably 3 or 4 carbon atoms, and most preferably 3 carbon atoms.

The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The linear or branched aliphatic hydrocarbon group may have or may not have a substituent. Examples of the substituent include a fluorine atom, a fluorinated alkyl group having 1 to 5 carbon atoms, which has been substituted with a fluorine atom, and a carbonyl group.

Aliphatic Hydrocarbon Group Containing Ring in Structure Thereof

Examples of the aliphatic hydrocarbon group containing a ring in the structure thereof include a cyclic aliphatic hydrocarbon group which may have a substituent containing a hetero atom in the ring structure thereof (a group obtained by removing two hydrogen atoms from an aliphatic hydrocarbon ring), a group in which the cyclic aliphatic hydrocarbon group is bonded to the terminal of a linear or branched aliphatic hydrocarbon group, and a group in which the cyclic aliphatic hydrocarbon group is interposed in a linear or branched aliphatic hydrocarbon group. Examples of the linear or branched aliphatic hydrocarbon group include the same ones as those described above.

The cyclic aliphatic hydrocarbon group preferably has 3 to 20 carbon atoms and more preferably 3 to 12 carbon atoms.

The cyclic aliphatic hydrocarbon group may be a polycyclic group or a monocyclic group. The monocyclic alicyclic hydrocarbon group is preferably a group obtained by removing two hydrogen atoms from a monocycloalkane. The monocycloalkane is preferably a monocycloalkane having 3 to 6 carbon atoms, and specific examples thereof include cyclopentane and cyclohexane. The polycyclic alicyclic hydrocarbon group is preferably a group obtained by removing two hydrogen atoms from a polycycloalkane, and the polycycloalkane preferably has 7 to 12 carbon atoms. Specific examples of the polycycloalkane include adamantane, norbornane, isobornane, tricyclodecane, and tetracyclododecane.

The cyclic aliphatic hydrocarbon group may have or may not have a substituent. Examples of the substituent include an alkyl group, an alkoxy group, a halogen atom, a halogenated alkyl group, a hydroxyl group, and a carbonyl group.

The alkyl group as the substituent is preferably an alkyl group having 1 to 5 carbon atoms, and a methyl group, an ethyl group, a propyl group, an n-butyl group, or a tert-butyl group is most preferable.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and still more preferably a methoxy group or an ethoxy group.

The halogen atom as the substituent is preferably a fluorine atom.

Examples of the halogenated alkyl group as the substituent include groups in which part or all of hydrogen atoms in the above-described alkyl groups have been substituted with the above-described halogen atoms.

In the cyclic aliphatic hydrocarbon group, a part of carbon atoms constituting the ring structure thereof may be substituted with a substituent containing a hetero atom. The substituent containing a hetero atom is preferably —O—, —C(═O)—O—, —S—, —S(═O)₂—, or —S(═O)₂—O—.

The aromatic hydrocarbon group as Ra¹¹ is a hydrocarbon group which has at least one aromatic ring.

The aromatic ring is not particularly limited as long as it is a cyclic conjugated system having (4n+2) π electrons, and the aromatic ring may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms. Here, the number of carbon atoms in a substituent is not included in the number of carbon atoms.

Specific examples of the aromatic ring include aromatic hydrocarbon rings such as benzene, naphthalene, anthracene, and phenanthrene; and an aromatic heterocyclic ring obtained by substituting a part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group include a group obtained by removing two hydrogen atoms from the above-described aromatic hydrocarbon ring or aromatic heterocyclic ring (an arylene group or a heteroarylene group); a group obtained by removing two hydrogen atoms from an aromatic compound having two or more aromatic rings (for example, biphenyl or fluorene); and a group in which one hydrogen atom of a group (an aryl group or a heteroaryl group) obtained by removing one hydrogen atom from the above-described aromatic hydrocarbon ring or aromatic heterocyclic ring has been substituted with an alkylene group (for example, a group in which one hydrogen atom further has been removed from an aryl group in arylalkyl groups such as a benzyl group, a phenethyl group, a 1-naphthylmethyl group, a 2-naphthylmethyl group, a 1-naphthylethyl group, or a 2-naphthylethyl group). The alkylene group bonded to the aryl group or the heteroaryl group preferably has 1 to 4 carbon atoms, more preferably 1 or 2 carbon atoms, and particularly preferably 1 carbon atom.

In the aromatic hydrocarbon group, the hydrogen atom contained in the aromatic hydrocarbon group may be substituted with a substituent. For example, the hydrogen atom bonded to the aromatic ring in the aromatic hydrocarbon group may be substituted with a substituent. Examples of the substituent include an alkyl group, an alkoxy group, a halogen atom, a halogenated alkyl group, and a hydroxyl group.

The alkyl group as the substituent is preferably an alkyl group having 1 to 5 carbon atoms, and a methyl group, an ethyl group, a propyl group, an n-butyl group, or a tert-butyl group is most preferable.

Examples of the alkoxy group, the halogen atom, and the halogenated alkyl group, as the substituent, include those exemplified as the substituent that is substituted for a hydrogen atom contained in the cyclic aliphatic hydrocarbon group.

Among the above, Ra¹¹ is preferably a linear or branched aliphatic hydrocarbon group or a single bond, and more preferably a linear or branched aliphatic hydrocarbon group. The linear or branched aliphatic hydrocarbon group is preferably an alkylene group having 1 to 6 carbon atoms, more preferably an alkylene group having 1 to 5 carbon atoms, still more preferably a methylene group, an ethylene group, a propylene group, or an isopropylene group, particularly preferably a methylene group or an ethylene group, and most preferably a methylene group.

In General Formula (a0-1-1), the hydrocarbon group as Ra¹² may be linear, branched, or cyclic, and it is preferably linear or branched. The hydrocarbon group as Ra¹² may be a saturated hydrocarbon group or may be an unsaturated hydrocarbon group, and it is preferably a saturated hydrocarbon group.

The hydrocarbon group as Ra¹² has 1 to 6 carbon atoms and preferably has 1 to 5 carbon atoms, among which a methyl group, an ethyl group, a propyl group, or an isopropyl group is more preferable, a methyl group or an ethyl group is still more preferable, and a methyl group is particularly preferable.

Among the above, Ra¹² is preferably a hydrogen atom, that is, —ORa¹² is preferably a phenolic hydroxyl group.

In General Formula (a0-1-1), Ra³ represents a hydrocarbon group having 1 to 6 carbon atoms, and examples thereof include the same one as the hydrocarbon group as Ra¹².

In General Formula (a0-1-1), na2 is preferably 1.

In General Formula (a0-1-1), na3 is preferably an integer in a range of 0 to 3, more preferably 0 or 1, and particularly preferably 0.

Specific examples of the constitutional unit represented by General Formula (a0-1-1) are shown below.

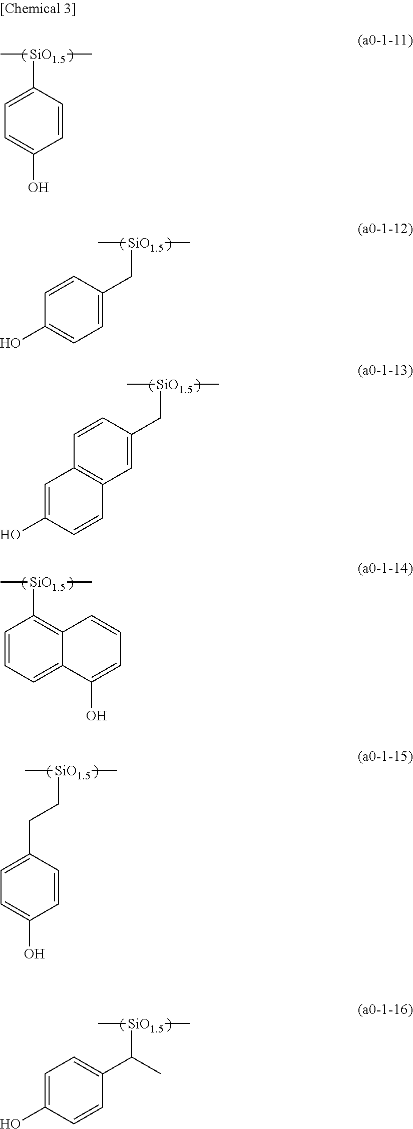

The constitutional unit represented by General Formula (a0-1-1), which is contained in the silicon-containing polymer (A0), may be one kind or may be two or more kinds.

In the silicon-containing polymer (A0), the proportion of the constitutional unit represented by General Formula (a0-1-1) is preferably 40% by mole or more and 80% by mole or less, more preferably 45% by mole or more and 75% by mole or less, and still more preferably 50% by mole or more and 70% by mole or less, with respect to the total (100% by mole) of all constitutional units constituting the silicon-containing polymer (A0).

In a case where the proportion of the constitutional unit represented by General Formula (a0-1-1) is equal to or larger than the lower limit value of the above-described preferred range, a resist pattern having favorable lithography characteristics is easily formed, whereas in a case of being equal to or smaller than the upper limit value of the above-described preferred range, etching resistance is easily increased.

Constitutional Unit Represented by General Formula (a0-1-2)

The silicon-containing polymer (A0) is preferably a polymer having a constitutional unit represented by General Formula (a0-1-2).

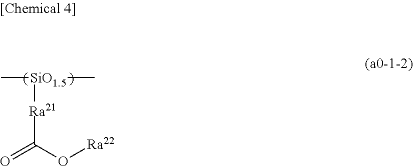

[In the formula, Ra²¹ represents a divalent linking group or a single bond. Ra²² represents an acid dissociable group.]

In General Formula (a0-1-2), examples of the divalent linking group as Ra²¹ include a divalent hydrocarbon group which may have a substituent.

The hydrocarbon group as Ra²¹ may be an aliphatic hydrocarbon group or may be an aromatic hydrocarbon group.

Examples of the aliphatic hydrocarbon group and the aromatic hydrocarbon group as Ra²¹, and examples of the substituent which may be contained in the aliphatic hydrocarbon group and the aromatic hydrocarbon group include the same ones as the above-described aliphatic hydrocarbon group and aromatic hydrocarbon group as Ra¹¹, and the same one as the above-described substituent which may be contained in the aliphatic hydrocarbon group and the aromatic hydrocarbon group.

Among them, Ra²¹ is;
preferably an aliphatic hydrocarbon group having a ring in the structure thereof or a single bond,
more preferably an aliphatic hydrocarbon group having a ring in the structure thereof,
still more preferably a monocyclic alicyclic hydrocarbon group or a polycyclic alicyclic hydrocarbon group, and
particularly preferably a polycyclic alicyclic hydrocarbon group.

The polycyclic alicyclic hydrocarbon group is preferably a group obtained by removing two hydrogen atoms from a polycycloalkane, and the polycycloalkane is preferably a polycycloalkane having 7 to 12 carbon atoms, more preferably adamantane, norbornane, isobornane, tricyclodecane, or tetracyclododecane, and most preferably norbornane.

In General Formula (a0-1-2), examples of the acid dissociable group as Ra²² include those which have proposed so far as the acid dissociable group of a base resin for a chemical amplification-type resist composition, for example, a “tertiary alkyl ester-type acid dissociable group”, and a “tertiary alkyloxycarbonyl acid dissociable group”, which will be described below.

Tertiary alkyl ester-type acid dissociable group:

Among the above polar groups, examples of the acid dissociable group for protecting the carboxy group include the acid dissociable group represented by General Formula (a1-r-2) shown below.

It is noted that among the acid dissociable groups represented by General Formula (a1-r-2), a group which is composed of alkyl groups is referred to, for convenience, as a “tertiary alkyl ester-type acid dissociable group”.

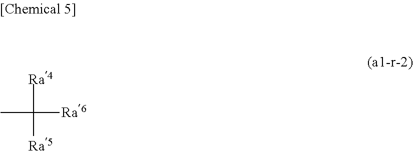

[In the formula, Ra′⁴ to Ra′⁶ each represents a hydrocarbon group, and Ra′⁵ and Ra′⁶ may be bonded to each other to form a ring.]

In General Formula (a1-r-2), examples of the hydrocarbon group as Ra′⁴ include a linear or branched alkyl group, a chain-like or cyclic alkenyl group, and a cyclic hydrocarbon group.

The linear alkyl group as Ra′⁴ has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group as Ra′⁴ has preferably 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group. Among these, an isopropyl group is preferable.

In a case where Ra′⁴ represents a cyclic hydrocarbon group, the cyclic hydrocarbon group may be an aliphatic hydrocarbon group or an aromatic hydrocarbon group and may be a polycyclic group or a monocyclic group.

The aliphatic hydrocarbon group which is a monocyclic group is preferably a group obtained by removing one hydrogen atom from a monocycloalkane. The monocycloalkane is preferably a monocycloalkane having 3 to 6 carbon atoms, and specific examples thereof include cyclopentane and cyclohexane.

The aliphatic hydrocarbon group which is a polycyclic group is preferably a group obtained by removing one hydrogen atom from a polycycloalkane. The polycycloalkane preferably has 7 to 12 carbon atoms, and specific examples thereof include adamantane, norbornane, isobornane, tricyclodecane, and tetracyclododecane.

In a case where the cyclic hydrocarbon group as Ra′⁴ is an aromatic hydrocarbon group, the aromatic hydrocarbon group is a hydrocarbon group having at least one aromatic ring.

The aromatic ring is not particularly limited as long as it is a cyclic conjugated system having (4n+2) π electrons, and the aromatic ring may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms.

Specific examples of the aromatic ring include aromatic hydrocarbon rings such as benzene, naphthalene, anthracene, and phenanthrene; and an aromatic heterocyclic ring obtained by substituting a part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group as Ra′⁴ include a group obtained by removing one hydrogen atom from the above-described aromatic hydrocarbon ring or aromatic heterocyclic ring (an aryl group or a heteroaryl group); a group obtained by removing one hydrogen atom from an aromatic compound having two or more aromatic rings (for example, biphenyl or fluorene); and a group in which one hydrogen atom of the above-described aromatic hydrocarbon ring or aromatic heterocyclic ring has been substituted with an alkylene group (for example, an arylalkyl group such as a benzyl group, a phenethyl group, a 1-naphthylmethyl group, a 2-naphthylmethyl group, a 1-naphthylethyl group, or a 2-naphthylethyl group). The alkylene group bonded to the aromatic hydrocarbon ring or aromatic heterocyclic ring preferably has 1 to 4 carbon atoms, more preferably 1 or 2 carbon atoms, and particularly preferably 1 carbon atom.

The cyclic hydrocarbon group as Ra′⁴ may have a substituent. Examples of the substituent include, —R^{P1}, —R^{P2}—O—R^{P1}, —R^{P2}—CO—R^{P1}, —R^{P2}—CO—OR^{P1}, —R^{P2}—O—CO—R^{P1}, —R^{P2}—OH, —R^{P2}—CN, and —R^{P2}—COOH (hereinafter, these substituents are also collectively referred to as “Ra′⁵”).

Here, R^{P1} represents a monovalent chain-like saturated hydrocarbon group having 1 to 10 carbon atoms, a monovalent aliphatic cyclic saturated hydrocarbon group having 3 to 20 carbon atoms, or a monovalent aromatic hydrocarbon group having 6 to 30 carbon atoms. In addition, R^{P2} represents a single bond, a divalent chain-like saturated hydrocarbon group having 1 to 10 carbon atoms, a divalent aliphatic cyclic saturated hydrocarbon group having 3 to 20 carbon atoms, or a divalent aromatic hydrocarbon group having 6 to 30 carbon atoms. However, part or all of hydrogen atoms contained in the chain-like saturated hydrocarbon group, the aliphatic cyclic saturated hydrocarbon group, and the aromatic hydrocarbon group of R^{P1} and R^{P2} may be substituted with a fluorine atom. In the aliphatic cyclic hydrocarbon group, one or more of the above-described substituents may be included as a single kind, or one or more of the above-described substituents may be included as a plurality of kinds.

Examples of the monovalent chain-like saturated hydrocarbon group having 1 to 10 carbon atoms include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms include monocyclic aliphatic saturated hydrocarbon groups such as a cyclopropyl group, a cyclobutyl group, a cyclopentyl group, a cyclohexyl group, a cycloheptyl group, a cyclooctyl group, a cyclodecyl group, and cyclododecyl group; and polycyclic aliphatic saturated hydrocarbon groups such as a bicyclo[2.2.2]octanyl group, a tricyclo[5.2.1.02,6]decanyl group, a tricyclo [3.3.1.13,7]decanyl group, a tetracyclo[6.2.1.13,6.02,7] dodecanyl group, and an adamantyl group.

Examples of the monovalent aromatic hydrocarbon group having 6 to 30 carbon atoms include a group obtained by removing one hydrogen atom from an aromatic hydrocarbon ring such as benzene, biphenyl, fluorene, naphthalene, anthracene, or phenanthrene.

The chain-like or cyclic alkenyl group as Ra′⁴ is preferably an alkenyl group having 2 to 10 carbon atoms.

Examples of the hydrocarbon group as Ra′⁵ or Ra′⁶ include the same one as Ra′⁴ described above.

Suitable examples thereof include groups represented by General Formula (a1-r2-1), General Formula (a1-r2-2), and General Formula (a1-r2-3) in a case where Ra′⁵ to Ra′⁶ are bonded to each other to form a ring.

On the other hand, suitable examples thereof include a group represented by General Formula (a1-r2-4) in a case where Ra′⁴ to Ra′⁶ are not bonded to each other and represent an independent hydrocarbon group.

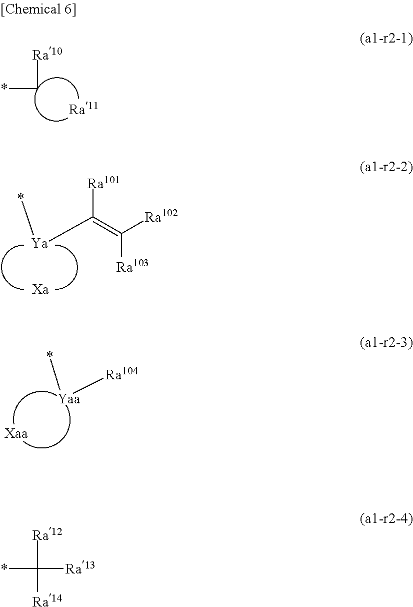

[In General Formula (a1-r2-1), Ra′¹⁰ represents a linear or branched alkyl group having 1 to 12 carbon atoms, a part of which may be substituted with a halogen atom or a hetero atom-containing group. Ra′¹¹ represents a group that forms an aliphatic cyclic group together with a carbon atom to which Ra′¹⁰ is bonded. In General Formula (a1-r2-2), Ya represents a carbon atom. Xa represents a group that forms a cyclic hydrocarbon group together with Ya. Part or all of hydrogen atoms contained in the cyclic hydrocarbon group may be substituted. Ra¹⁰¹ to Ra¹⁰³ each independently represent a hydrogen atom, a monovalent chain-like saturated hydrocarbon group having 1 to 10 carbon atoms, or a monovalent aliphatic cyclic saturated hydrocarbon group having 3 to 20 carbon atoms. Part or all of hydrogen atoms contained in the chain-like saturated hydrocarbon group and the aliphatic cyclic saturated hydrocarbon group may be substituted. Two or more of Ra¹⁰¹ to Ra¹⁰³ may be bonded to each other to form a cyclic structure. In General Formula (a1-r2-3), Yaa represents a carbon atom. Xaa is a group that forms an aliphatic cyclic group together with Yaa. Ra¹⁰⁴ represents an aromatic hydrocarbon group which may have a substituent. In General Formula (a1-r2-4), Ra′¹² and Ra′¹³ each independently represent a monovalent chain-like saturated hydrocarbon group having 1 to 10 carbon atoms. Part or all of hydrogen atoms contained in the chain-like saturated hydrocarbon group may be substituted. Ra′¹⁴ represents a hydrocarbon group which may have a substituent. * represents a bonding site.]

In General Formula (a1-r2-1) described above, Ra′¹⁰ represents a linear or branched alkyl group having 1 to 12 carbon atoms, a part of which may be substituted with a halogen atom or a hetero atom-containing group.

The linear alkyl group as Ra′¹⁰ has 1 to 12 carbon atoms, and preferably has 1 to 10 carbon atoms and particularly preferably 1 to 5 carbon atoms.

Examples of the branched alkyl group as Ra′¹⁰ include the same one as Ra′⁴ in General Formula (a1-r-2).

A part of the alkyl group as Ra′¹⁰ may be substituted with a halogen atom or a hetero atom-containing group. For example, a part of hydrogen atoms constituting the alkyl group may be substituted with a halogen atom or a hetero atom-containing group. In addition, a part of carbon atoms (such as a methylene group) constituting the alkyl group may be substituted with a hetero atom-containing group.

Examples of the hetero atom referred to here include an oxygen atom, a sulfur atom, and a nitrogen atom. Examples of the hetero atom-containing group include —O—, —C(═O)—O—, —O—C(═O)—, —C(═O)—, —O—C(═O)—O—, —C(═O)—NH—, —NH—, —S—, —S(═O)₂—, and —S(═O)₂—O—.

In General Formula (a1-r2-1), Ra′¹¹ (a group that forms an aliphatic cyclic group together with a carbon atom to which Ra′¹⁰ is bonded) is preferably the group mentioned as the aliphatic hydrocarbon group (the alicyclic hydrocarbon group) which is a monocyclic group or a polycyclic group as Ra′⁴ in General Formula (a1-r-2). Among the above, a monocyclic alicyclic hydrocarbon group is preferable, specifically, a cyclopentyl group or a cyclohexyl group is more preferable, and a cyclopentyl group is still more preferable.

In General Formula (a1-r2-2), examples of the cyclic hydrocarbon group that is formed by Xa together with Ya include a group in which one or more hydrogen atoms are further removed from a cyclic monovalent hydrocarbon group (an aliphatic hydrocarbon group) as Ra¹¹ in General Formula (a1-r-2).

The cyclic hydrocarbon group that is formed by Xa together with Ya may have a substituent. Examples of this substituent include the same one as the substituent which may be contained in the cyclic hydrocarbon group as Ra′⁴.

In General Formula (a1-r2-2), as Ra¹⁰¹ to Ra¹⁰³, examples of the monovalent chain-like saturated hydrocarbon group having 1 to 10 carbon atoms include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms, as Ra¹⁰¹ to Ra¹⁰³, include monocyclic aliphatic saturated hydrocarbon groups such as a cyclopropyl group, a cyclobutyl group, a cyclopentyl group, a cyclohexyl group, a cycloheptyl group, a cyclooctyl group, a cyclodecyl group, and cyclododecyl group; and polycyclic aliphatic saturated hydrocarbon groups such as a bicyclo[2.2.2]octanyl group, a tricyclo[5.2.1.02,6]decanyl group, a tricyclo[3.3.1.13,7]decanyl group, a tetracyclo[6.2.1.13,6.02,7] dodecanyl group, and an adamantyl group.

Among them, Ra¹⁰¹ to Ra¹⁰³ are preferably a hydrogen atom or a monovalent chain-like saturated hydrocarbon group having 1 to 10 carbon atoms, and among them, a hydrogen atom, a methyl group, and an ethyl group are more preferable, and a hydrogen atom is particularly preferable from the viewpoint of easy synthesis.

Examples of the substituent contained in the chain-like saturated hydrocarbon group represented by Ra¹⁰¹ to Ra¹⁰³ or the aliphatic cyclic saturated hydrocarbon group include the same groups as Ra^{x5} described above.

Examples of the group containing a carbon-carbon double bond generated by forming a cyclic structure, in which two or more of Ra¹⁰¹ to Ra¹⁰³ are bonded to each other, include a cyclopentenyl group, a cyclohexenyl group, a methylcyclopentenyl group, a methylcyclohexenyl group, a cyclopentylideneethenyl group, and a cyclohexylideneethenyl group. Among these, a cyclopentenyl group, a cyclohexenyl group, and a cyclopentylideneethenyl group are preferable from the viewpoint of easy synthesis.

In General Formula (a1-r2-3), an aliphatic cyclic group that is formed by Xaa together with Yaa is preferably the group mentioned as the aliphatic hydrocarbon group which is a monocyclic group or a polycyclic group as Ra′⁴ in General Formula (a1-r-2).

In General Formula (a1-r2-3), examples of the aromatic hydrocarbon group as Ra¹⁰⁴ include a group obtained by removing one or more hydrogen atoms from an aromatic hydrocarbon ring having 5 to 30 carbon atoms. Among them, Ra¹⁰⁴ is preferably a group obtained by removing one or more hydrogen atoms from an aromatic hydrocarbon ring having 6 to 15 carbon atoms, more preferably a group obtained by removing one or more hydrogen atoms from benzene, naphthalene, anthracene, or phenanthrene, still more preferably a group obtained by removing one or more hydrogen atoms from benzene, naphthalene, or anthracene, particularly preferably a group obtained by removing one or more hydrogen atoms from benzene or naphthalene, and most preferably a group obtained by removing one or more hydrogen atoms from benzene.

Examples of the substituent which may be contained in Ra¹⁰⁴ in General Formula (a1-r2-3) include a methyl group, an ethyl group, propyl group, a hydroxy group, a carboxy group, a halogen atom, an alkoxy group (a methoxy group, an ethoxy group, a propoxy group, a butoxy group, and the like), and an alkyloxycarbonyl group.

In General Formula (a1-r2-4), Ra′¹² and Ra′¹³ each independently represent a monovalent chain-like saturated hydrocarbon group having 1 to 10 carbon atoms. Examples of the monovalent chain-like saturated hydrocarbon group having 1 to 10 carbon atoms as Ra′¹² and Ra′¹³ include the same one as the monovalent chain-like saturated hydrocarbon group having 1 to 10 carbon atoms as Ra¹⁰¹ to Ra¹⁰³ as described above. Part or all of hydrogen atoms contained in the chain-like saturated hydrocarbon group may be substituted.

Among the above, Ra′¹² and Ra′¹³ are preferably an alkyl group having 1 to 5 carbon atoms, more preferably a methyl group or an ethyl group, and still more preferably a methyl group.

In a case where the chain-like saturated hydrocarbon groups represented by Ra′¹² and Ra′¹³ are substituted, examples of the substituent include the same group as Ra^{x5} described above.

In General Formula (a1-r2-4), Ra′¹⁴ represents a hydrocarbon group which may have a substituent. Examples of the hydrocarbon group as Ra′¹⁴ include a linear or branched alkyl group and a cyclic hydrocarbon group.

The linear alkyl group as Ra′¹⁴ has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group as Ra′¹⁴ has preferably 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group. Among these, an isopropyl group is preferable.

In a case where Ra′¹⁴ represents a cyclic hydrocarbon group, the cyclic hydrocarbon group may be an aliphatic hydrocarbon group or an aromatic hydrocarbon group and may be a polycyclic group or a monocyclic group.

The aliphatic hydrocarbon group which is a monocyclic group is preferably a group obtained by removing one hydrogen atom from a monocycloalkane. The monocycloalkane is preferably a monocycloalkane having 3 to 6 carbon atoms, and specific examples thereof include cyclopentane and cyclohexane.

The aliphatic hydrocarbon group which is a polycyclic group is preferably a group obtained by removing one hydrogen atom from a polycycloalkane. The polycycloalkane preferably has 7 to 12 carbon atoms, and specific examples thereof include adamantane, norbornane, isobornane, tricyclodecane, and tetracyclododecane.

Examples of the aromatic hydrocarbon group as Ra′¹⁴ include the same one as the aromatic hydrocarbon group as Ra¹⁰⁴. Among them, Ra′¹⁴ is preferably a group obtained by removing one or more hydrogen atoms from an aromatic hydrocarbon ring having 6 to 15 carbon atoms, more preferably a group obtained by removing one or more hydrogen atoms from benzene, naphthalene, anthracene, or phenanthrene, still more preferably a group obtained by removing one or more hydrogen atoms from benzene, naphthalene, or anthracene, particularly preferably a group obtained by removing one or more hydrogen atoms from naphthalene or anthracene, and most preferably a group obtained by removing one or more hydrogen atoms from naphthalene.

Examples of the substituent which may be contained in Ra′¹⁴ include the same one as the substituent which may be contained in Ra¹⁰⁴.

In a case where Ra′¹⁴ in General Formula (a1-r2-4) is a naphthyl group, the position at which the tertiary carbon atom in General Formula (a1-r2-4) is bonded may be any of the 1-position and the 2-position of the naphthyl group.

In a case where Ra′¹⁴ in General Formula (a1-r2-4) is an anthryl group, the position at which the tertiary carbon atom in General Formula (a1-r2-4) is bonded may be any of the 1-position, the 2-position, and 9-position of the anthryl group.

Specific examples of the group represented by General Formula (a1-r2-1) are shown below.

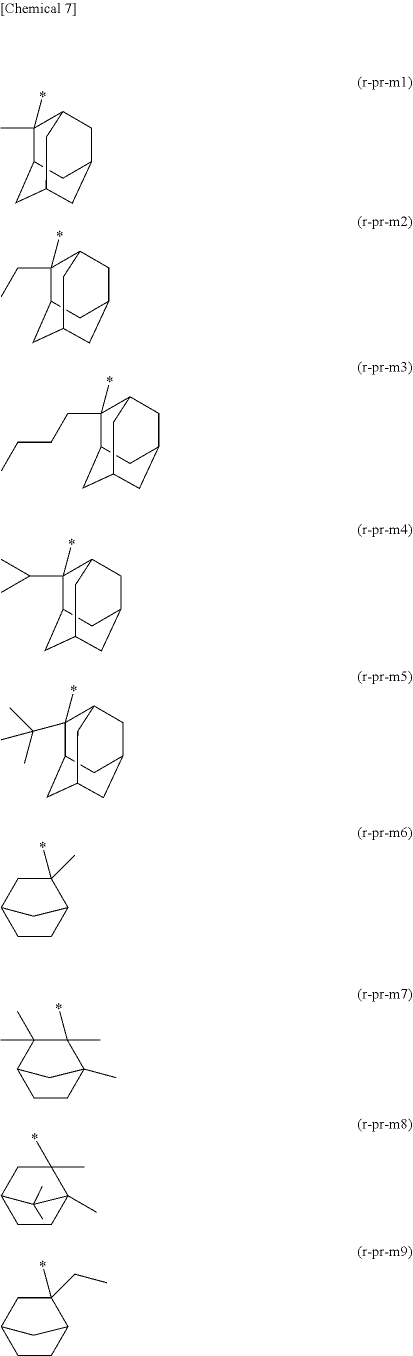

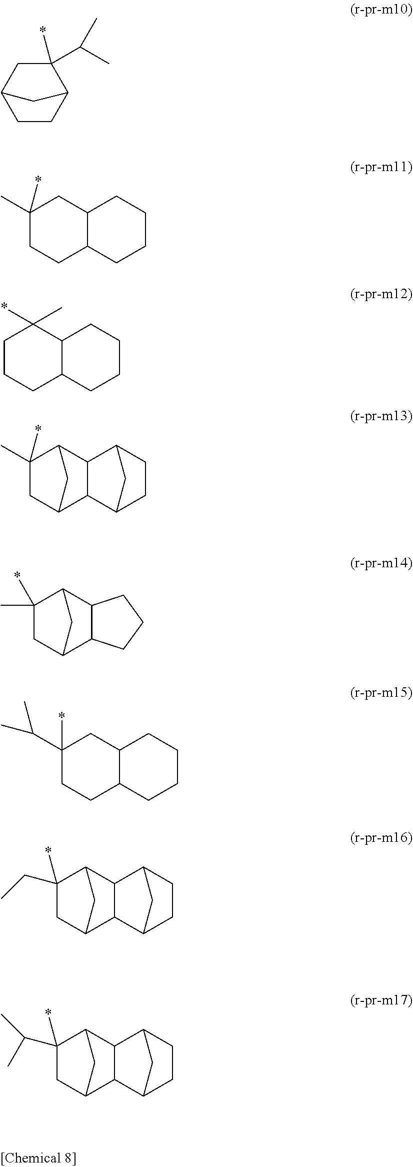

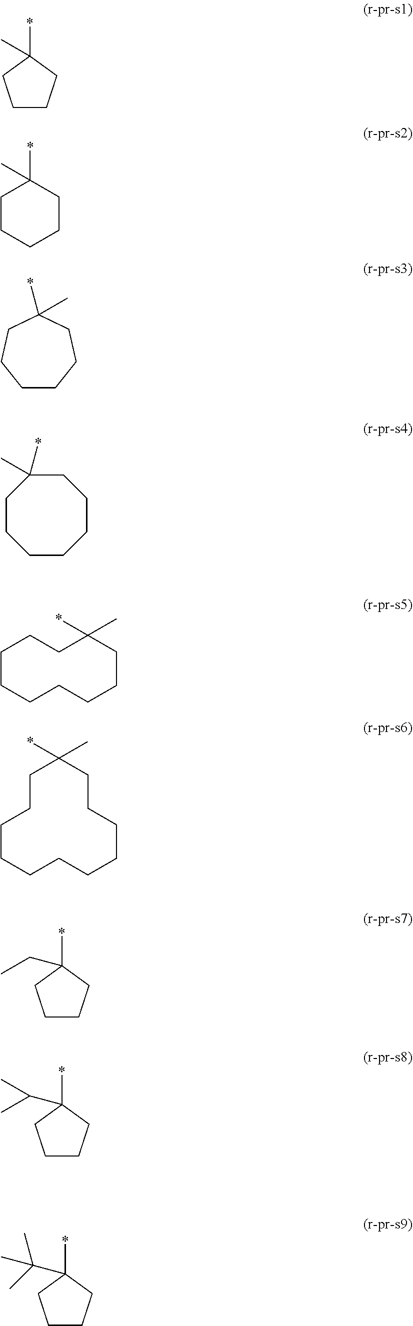

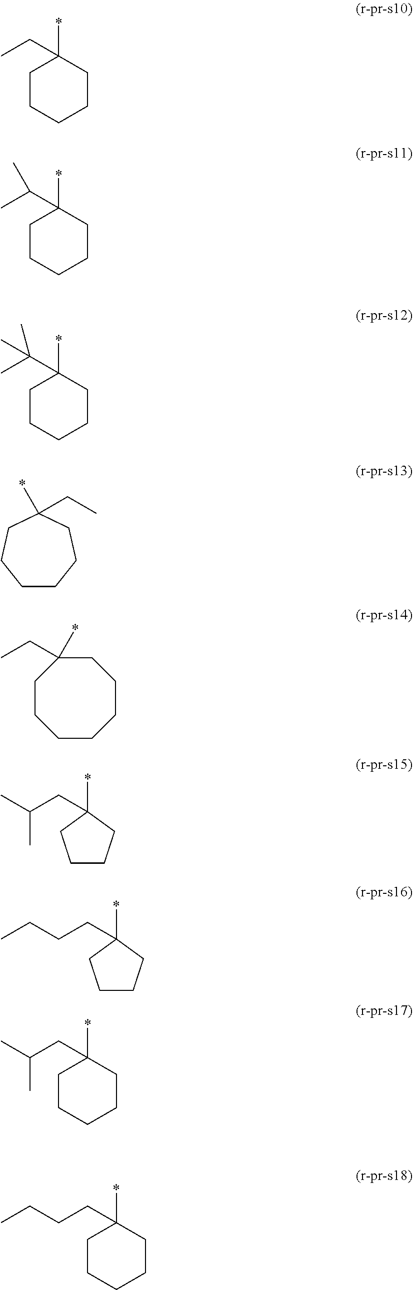

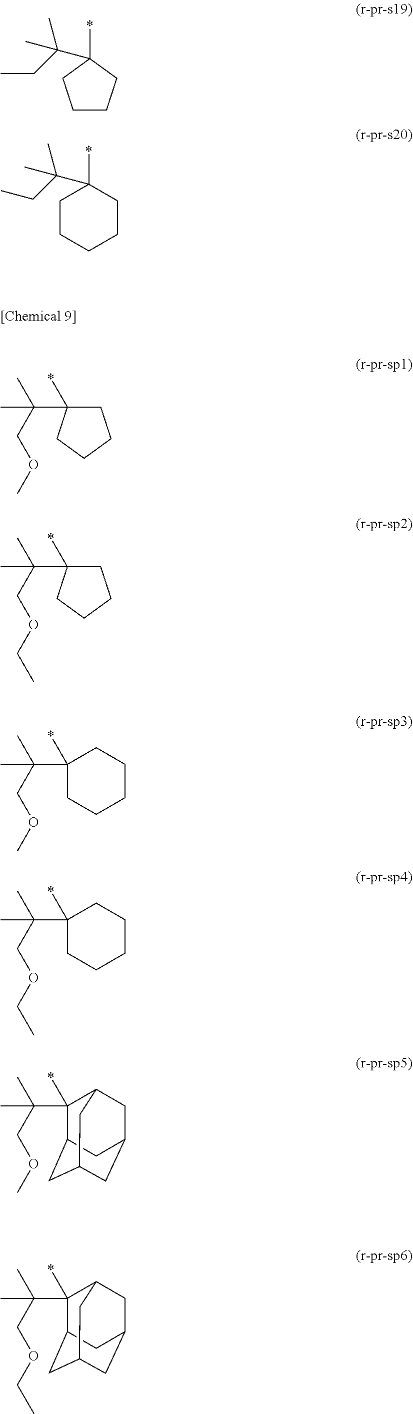

Specific examples of the group represented by General Formula (a1-r2-2) are shown below.

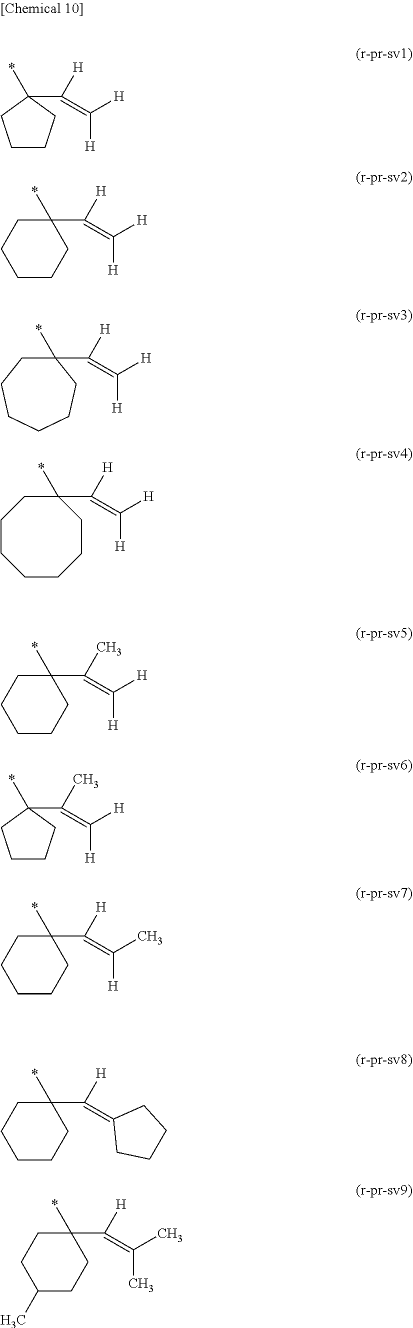

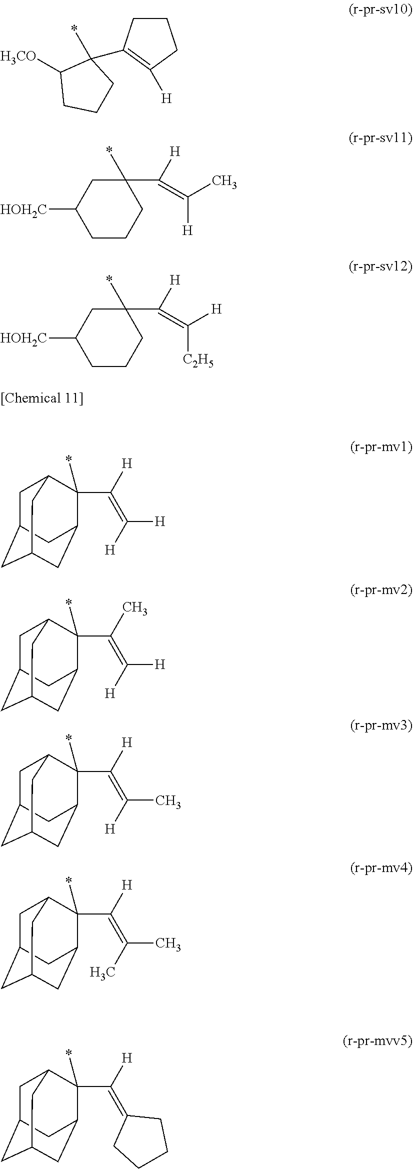

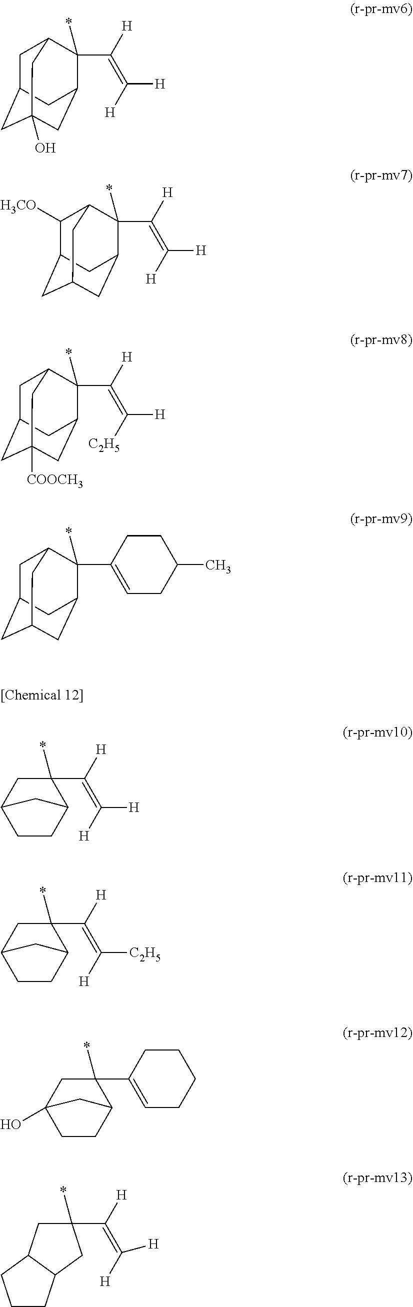

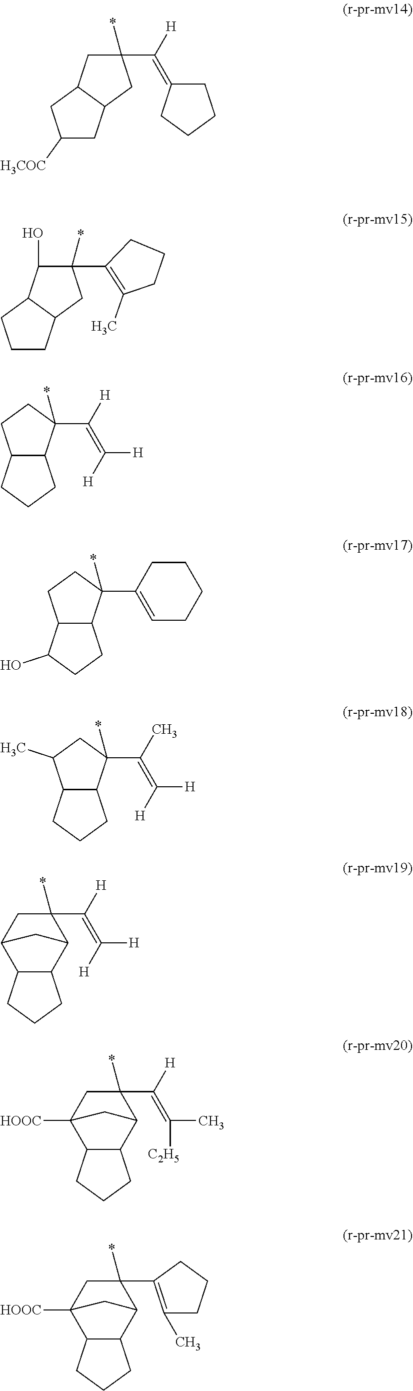

Specific examples of the group represented by General Formula (a1-r2-3) are shown below.

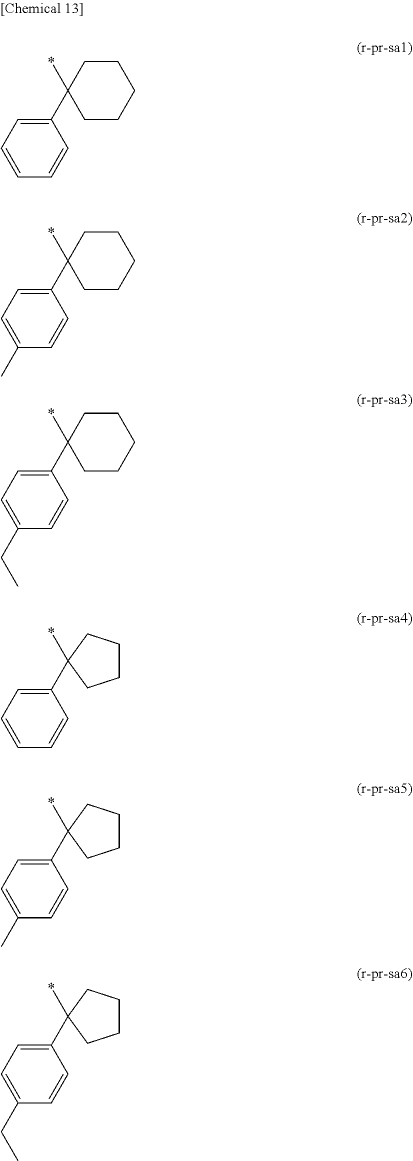

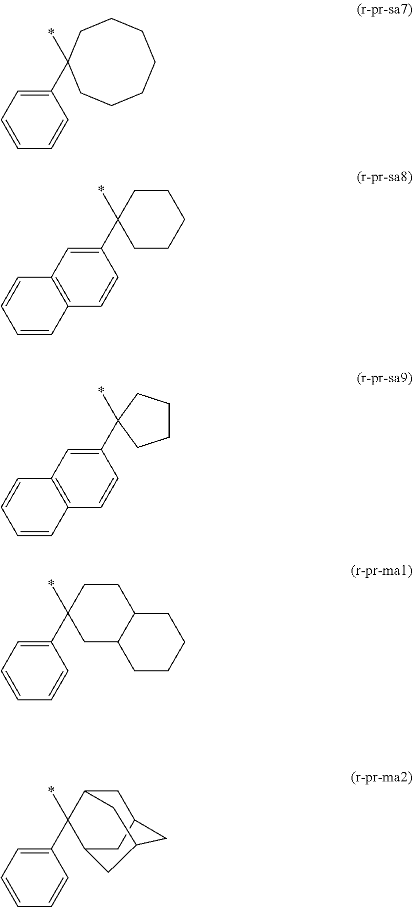

Specific examples of the group represented by General Formula (a1-r2-4) are shown below.

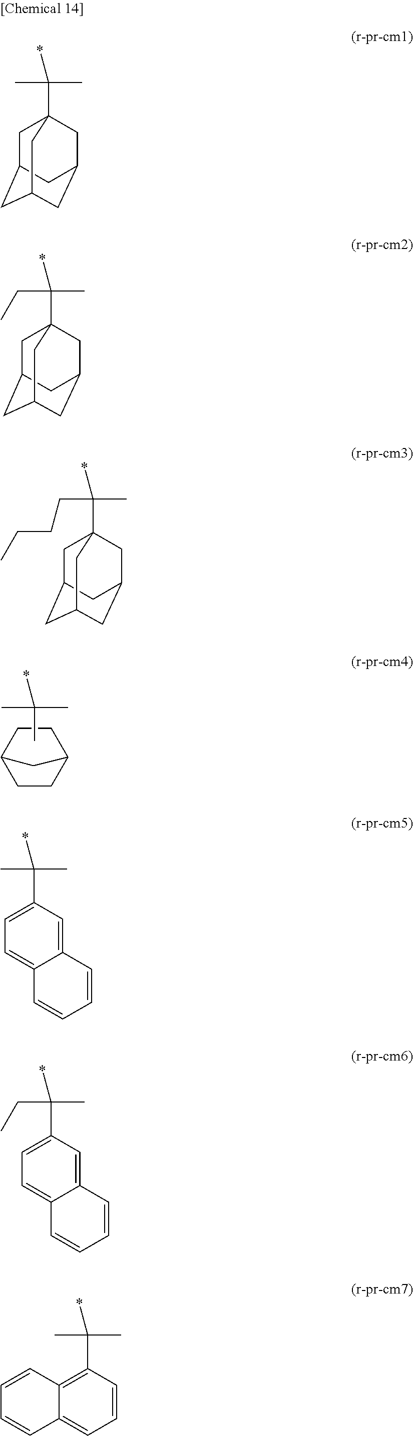

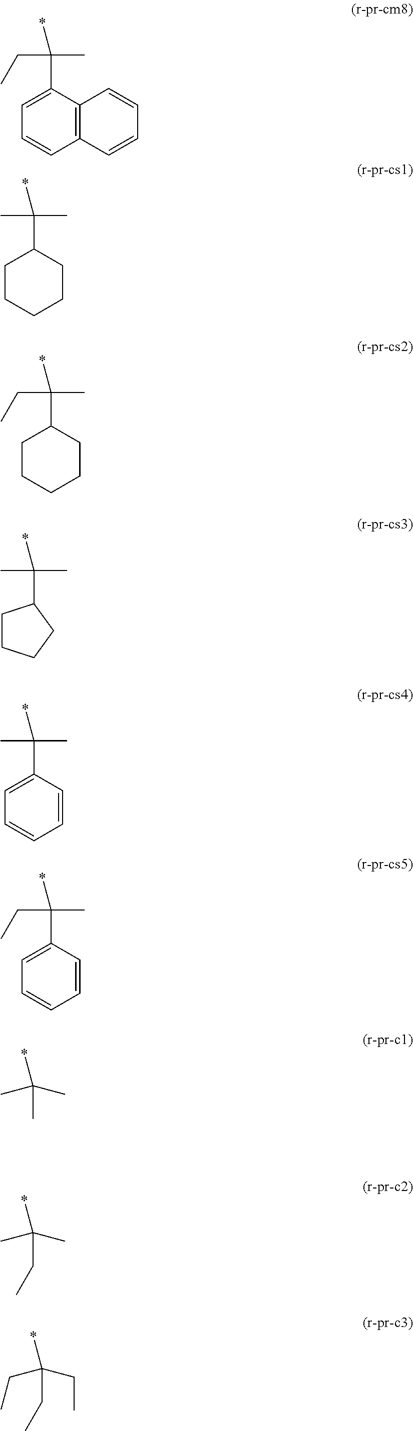

Tertiary Alkyloxycarbonyl Acid Dissociable Group:

Among the polar groups, examples of the acid dissociable group for protecting a hydroxyl group include an acid dissociable group (hereinafter, for convenience, also referred to as a “tertiary alkyloxycarbonyl acid dissociable group”) represented by General Formula (a1-r-3) shown below.

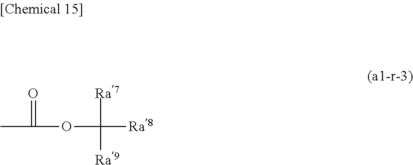

[In the formula, Ra′⁷ to Ra′⁹ each represents an alkyl group.]

In General Formula (a1-r-3), Ra′⁷ to Ra′⁹ are each preferably an alkyl group having 1 to 5 carbon atoms and more preferably an alkyl group having 1 to 3 carbon atoms.

In addition, the total number of carbon atoms in each of the alkyl groups is preferably in a range of 3 to 7, more preferably in a range of 3 to 5, and most preferably 3 or 4.

Specific examples of the constitutional unit represented by General Formula (a0-1-2) are shown below.

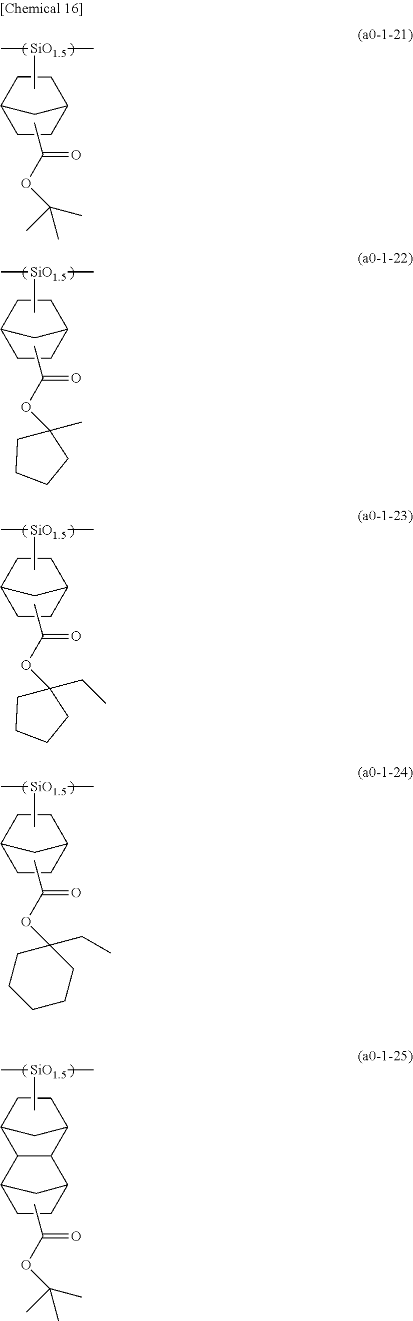

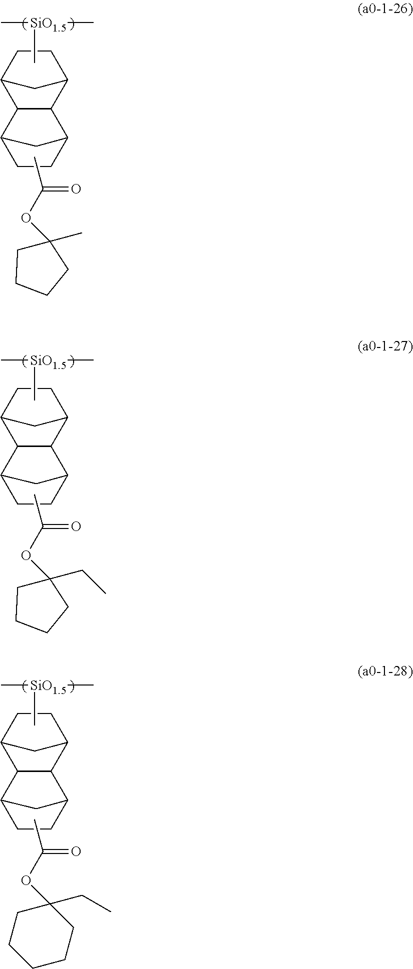

The constitutional unit represented by General Formula (a0-1-2), which is contained in the silicon-containing polymer (A0), may be one kind or may be two or more kinds.

In the silicon-containing polymer (A0), the proportion of the constitutional unit represented by General Formula (a0-1-2) is preferably 10% by mole or more and 45% by mole or less, more preferably 15% by mole or more and 40% by mole or less, and still more preferably 20% by mole or more and 35% by mole or less, with respect to the total (100% by mole) of all constitutional units constituting the silicon-containing polymer (A0).

In a case where the proportion of the constitutional unit represented by General Formula (a0-1-2) is equal to or larger than the lower limit value of the above-described preferred range, a resist pattern is easily formed, whereas in a case of being equal to or smaller than the upper limit value of the above-described preferred range, etching resistance is easily increased.

Constitutional Unit Represented by General Formula (a0-1-3)

The silicon-containing polymer (A0) is preferably a polymer having a constitutional unit represented by General Formula (a0-1-3). A partial structure represented by “—C(Ra³²)—O—Ra³³” in General Formula (a0-1-3) can be an acid dissociable group (acetal-type acid dissociable group).

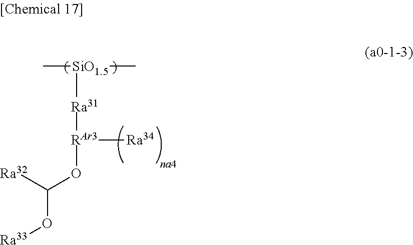

[In the formula, R^{Ar3} represents an aromatic hydrocarbon group. Ra³¹ represents a divalent linking group or a single bond. Ra³² and Ra³³ each independently represent a hydrocarbon group having 1 to 20 carbon atoms or a hydrogen atom. Ra³² and Ra³³ may be bonded to each other to form a ring. Ra³⁴ represents a hydrocarbon group having 1 to 6 carbon atoms. na4 represents an integer in a range of 0 to 4.]

In General Formula (a0-1-3), examples of the aromatic hydrocarbon group as R^{Ar3} include the same one as the aromatic hydrocarbon group as R^{Ar1} in General Formula (a0-1-1). In R^{Ar3}, preferred examples of the aromatic ring include benzene, naphthalene, anthracene, and phenanthrene, where benzene or naphthalene is more preferable, and benzene is still more preferable.

In the aromatic hydrocarbon group as R^{Ar3}, the hydrogen atom bonded to the aromatic ring may be substituted with a substituent. Examples of the substituent include a halogen atom, a halogenated alkyl group, and a hydroxyl group. The halogen atom as the substituent is preferably a fluorine atom. Examples of the halogenated alkyl group as the substituent include a group obtained by substituting part or all of hydrogen atoms in the above-described alkyl group having 1 to 5 carbon atoms with a halogen atom.

In General Formula (a0-1-3), examples of the divalent linking group as Ra³¹ include a divalent hydrocarbon group which may have a substituent.

The hydrocarbon group as Ra³¹ may be an aliphatic hydrocarbon group or may be an aromatic hydrocarbon group.

Examples of the aliphatic hydrocarbon group and the aromatic hydrocarbon group as Ra³¹, and examples of the substituent which may be contained in the aliphatic hydrocarbon group and the aromatic hydrocarbon group include the same ones as the above-described aliphatic hydrocarbon group and aromatic hydrocarbon group as Ra¹¹, and the same one as the above-described substituent which may be contained in the aliphatic hydrocarbon group and the aromatic hydrocarbon group.

Among the above, Ra³¹ is preferably a linear or branched aliphatic hydrocarbon group or a single bond, and more preferably a linear or branched aliphatic hydrocarbon group. The linear or branched aliphatic hydrocarbon group is preferably an alkylene group having 1 to 6 carbon atoms, more preferably an alkylene group having 1 to 5 carbon atoms, still more preferably a methylene group, an ethylene group, a propylene group, or an isopropylene group, particularly preferably a methylene group or an ethylene group, and most preferably a methylene group.

In General Formula (a0-1-3), the hydrocarbon group as Ra³² is preferably a chain-like aliphatic hydrocarbon group and more preferably a chain-like saturated aliphatic hydrocarbon group (an alkyl group). This alkyl group preferably has 1 to 10 carbon atoms and more preferably has 1 to 5 carbon atoms. Examples thereof include a methyl group, an ethyl group, a propyl group, an isopropyl group, an n-butyl group, an isobutyl group, a tert-butyl group, a pentyl group, an isopentyl group, and a neopentyl group, where a methyl group or an ethyl group is preferable, and a methyl group is particularly preferable.

Among the above, Ra³² is preferably a hydrocarbon group having 1 to 20 carbon atoms and more preferably an alkyl group having 1 to 5 carbon atoms.

In General Formula (a0-1-3), examples of the hydrocarbon group as Ra³³ include a linear or branched alkyl group and a cyclic hydrocarbon group.

The linear alkyl group has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group has preferably 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group. Among these, an isopropyl group is preferable.

In a case where Ra³³ represents a cyclic hydrocarbon group, the hydrocarbon group may be an aliphatic hydrocarbon group or an aromatic hydrocarbon group and may be a polycyclic group or a monocyclic group.

The aliphatic hydrocarbon group which is a monocyclic group is preferably a group obtained by removing one hydrogen atom from a monocycloalkane. The monocycloalkane is preferably a monocycloalkane having 3 to 6 carbon atoms, and specific examples thereof include cyclopentane and cyclohexane.

The aliphatic hydrocarbon group which is a polycyclic group is preferably a group obtained by removing one hydrogen atom from a polycycloalkane. The polycycloalkane preferably has 7 to 12 carbon atoms, and specific examples thereof include adamantane, norbornane, isobornane, tricyclodecane, and tetracyclododecane.

In a case where the cyclic hydrocarbon group as Ra³³ is an aromatic hydrocarbon group, the aromatic hydrocarbon group is a hydrocarbon group having at least one aromatic ring.

The aromatic ring is not particularly limited as long as it is a cyclic conjugated system having (4n+2) π electrons, and the aromatic ring may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms.

Specific examples of the aromatic ring include aromatic hydrocarbon rings such as benzene, naphthalene, anthracene, and phenanthrene; and an aromatic heterocyclic ring obtained by substituting a part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group as Ra³³ include a group obtained by removing one hydrogen atom from the above-described aromatic hydrocarbon ring or aromatic heterocyclic ring (an aryl group or a heteroaryl group); a group obtained by removing one hydrogen atom from an aromatic compound having two or more aromatic rings (for example, biphenyl, fluorene); and a group obtained by substituting one hydrogen atom of the above-described aromatic hydrocarbon ring or aromatic heterocyclic ring with an alkylene group (for example, an arylalkyl group such as a benzyl group, a phenethyl group, a 1-naphthylmethyl group, a 2-naphthylmethyl group, a 1-naphthylethyl group, or a 2-naphthylethyl group). The alkylene group bonded to the aromatic hydrocarbon ring or aromatic heterocyclic ring preferably has 1 to 4 carbon atoms, more preferably 1 or 2 carbon atoms, and particularly preferably 1 carbon atom.

The cyclic hydrocarbon group as Ra³³ may have a substituent. Examples of the substituent include, —R^{P1}, —R^{P2}—O—R^{P1}, —R^{P2}—CO—R^{P1}, —R^{P2}—CO—OR^{P1}, —R^{P2}—O—CO—R^{P1}, —R^{P2}—OH, —R^{P2}—CN, and —R^{P2}—COOH (hereinafter. these substituents are also collectively referred to as “Ra^{x5}”).

Here, R^{P1} represents a monovalent chain-like saturated hydrocarbon group having 1 to 10 carbon atoms, a monovalent aliphatic cyclic saturated hydrocarbon group having 3 to 20 carbon atoms, or a monovalent aromatic hydrocarbon group having 6 to 30 carbon atoms. In addition, R^{P2} represents a single bond, a divalent chain-like saturated hydrocarbon group having 1 to 10 carbon atoms, a divalent aliphatic cyclic saturated hydrocarbon group having 3 to 20 carbon atoms, or a divalent aromatic hydrocarbon group having 6 to 30 carbon atoms. However, part or all of hydrogen atoms contained in the chain-like saturated hydrocarbon group, the aliphatic cyclic saturated hydrocarbon group, and the aromatic hydrocarbon group of R^{P1} and R^{P2} may be substituted with a fluorine atom. In the aliphatic cyclic hydrocarbon group, one or more of the above-described substituents may be included as a single kind, or one or more of the above-described substituents may be included as a plurality of kinds.

Examples of the monovalent chain-like saturated hydrocarbon group having 1 to 10 carbon atoms include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms include monocyclic aliphatic saturated hydrocarbon groups such as a cyclopropyl group, a cyclobutyl group, a cyclopentyl group, a cyclohexyl group, a cycloheptyl group, a cyclooctyl group, a cyclodecyl group, and cyclododecyl group; and polycyclic aliphatic saturated hydrocarbon groups such as a bicyclo[2.2.2]octanyl group, a tricyclo[5.2.1.02,6]decanyl group, a tricyclo [3.3.1.13,7]decanyl group, a tetracyclo[6.2.1.13,6.02,7] dodecanyl group, and an adamantyl group.

Examples of the monovalent aromatic hydrocarbon group having 6 to 30 carbon atoms include a group obtained by removing one hydrogen atom from an aromatic hydrocarbon ring such as benzene, biphenyl, fluorene, naphthalene, anthracene, or phenanthrene.

In a case where Ra³² and Ra³³ are bonded to each other to form a ring, the cyclic group is preferably a 4-membered to 7-membered ring, and more preferably a 4-membered to 6-membered ring. Specific examples of the cyclic group include a tetrahydropyranyl group and a tetrahydrofuranyl group.

In General Formula (a0-1-3), the hydrocarbon group as Ra³⁴ may be linear, branched, or cyclic, and it is preferably linear or branched. The hydrocarbon group as Ram may be a saturated hydrocarbon group or may be an unsaturated hydrocarbon group, and it is preferably a saturated hydrocarbon group.

The hydrocarbon group as Ram has 1 to 6 carbon atoms and preferably has 1 to 5 carbon atoms, among which a methyl group, an ethyl group, a propyl group, or an isopropyl group is more preferable, a methyl group or an ethyl group is still more preferable, and a methyl group is particularly preferable.

In General Formula (a0-1-3), na4 is preferably an integer in a range of 0 to 2, more preferably 0 or 1, and particularly preferably 0.

Specific examples of the constitutional unit represented by General Formula (a0-1-3) are shown below.

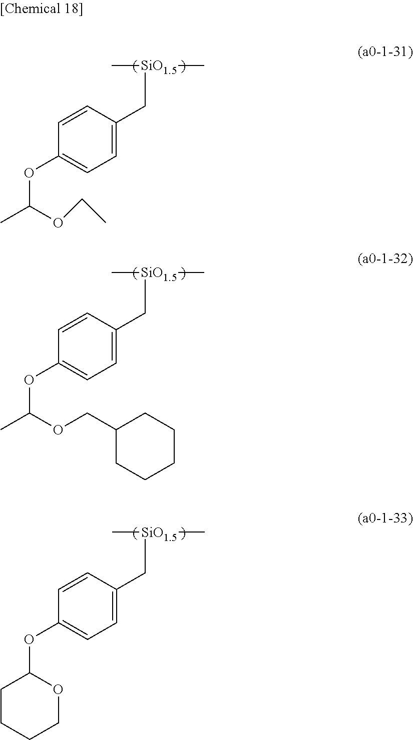

The constitutional unit represented by General Formula (a0-1-3), which is contained in the silicon-containing polymer (A0), may be one kind or may be two or more kinds.

In the silicon-containing polymer (A0), the proportion of the constitutional unit represented by General Formula (a0-1-3) is preferably 35% by mole or more and 65% by mole or less, more preferably 40% by mole or more and 60% by mole or less, and still more preferably 45% by mole or more and 55% by mole or less, with respect to the total (100% by mole) of all constitutional units constituting the silicon-containing polymer (A0).

In a case where the proportion of the constitutional unit represented by General Formula (a0-1-3) is equal to or larger than the lower limit value of the above-described preferred range, a resist pattern is easily formed, whereas in a case of being equal to or smaller than the upper limit value of the above-described preferred range, etching resistance is easily increased.

Other Constitutional Units

Examples of the constitutional unit represented by General Formula (a0-1) include the constitutional unit represented by General Formula (a0-1-1), the constitutional unit represented by General Formula (a0-1-2), and the constitutional unit represented by General Formula (a0-1-3), which are described above, as well as constitutional units other than these.

Examples of the constitutional units other than these include a constitutional unit (a2), a constitutional unit (a3), a constitutional unit (a4), a constitutional unit (a5), and a constitutional unit (a6), which will be described later.

Constitutional Unit (a2)

The constitutional unit (a2) is a constitutional unit containing an alkyl group.

Examples of the constitutional unit (a2) include those in which the main chain moiety is an Si—O bond and the side chain moiety that is bonded to the Si atom of the Si—O bond is an alkyl group.

In a case where the constitutional unit (a2) is contained, it is possible to easily control the characteristics of a resist film that is formed by using the resist composition.

Preferred examples of the constitutional unit (a2) include a constitutional unit represented by General Formula (a2-1) and a constitutional unit represented by General Formula (a2-2).

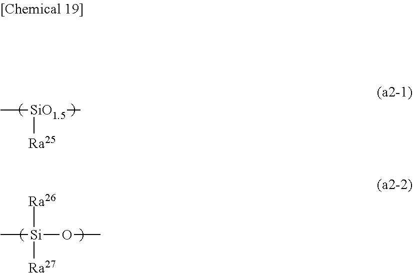

[In the formulae, Ra²⁵, Ra²⁶, and Ra²⁷ each independently represent an alkyl group having 1 to 10 carbon atoms.]

In General Formulae (a2-1) and (a2-2) described above, the alkyl group as Ra²⁵, Ra²⁶, and Ra²⁷ may be linear, branched, or cyclic, and it is preferably linear or branched.

The alkyl group as Ra²⁵, Ra²⁶, and Ra²⁷ has 1 to 10 carbon atoms, preferably 1 to 5 carbon atoms, and more preferably 1 to 3 carbon atoms.

Examples of the alkyl group as Ra²⁵, Ra²⁶, and Ra²⁷ include a methyl group, an ethyl group, a propyl group, a butyl group, a pentyl group, a hexyl group, an octyl group, a decyl group, an isopropyl group, an isobutyl group, a sec-butyl group, a tert-butyl group, and a 2-ethylhexyl group. Among these, a methyl group, an ethyl group, a propyl group, a butyl group, a pentyl group, an isopropyl group, an isobutyl group, a sec-butyl group, or a tert-butyl group is preferable, a methyl group, an ethyl group, a propyl group, or an isopropyl group is more preferable, a methyl group or an ethyl group is still more preferable, and a methyl group is particularly preferable.

The constitutional unit (a2) contained in the silicon-containing polymer (A0) may be one kind or two or more kinds.

In a case where the silicon-containing polymer (A0) further has the constitutional unit (a2), the proportion of the constitutional unit (a2) in the silicon-containing polymer (A0) is preferably in a range of 10% to 60% by mole, more preferably in a range of 10% to 55% by mole, and still more preferably in a range of 15% to 50% by mole, with respect to the total (100% by mole) of all constitutional units constituting the silicon-containing polymer (A0).

The proportion of the constitutional unit represented by General Formula (a2-1) is preferably in a range of 20% to 60% by mole, more preferably in a range of 25% to 55% by mole, and still more preferably in a range of 30% to 50% by mole, with respect to the total (100% by mole) of all constitutional units constituting the silicon-containing polymer (A0).

The proportion of the constitutional unit represented by General Formula (a2-2) is preferably in a range of 10% to 40% by mole, more preferably in a range of 10% to 30% by mole, and still more preferably in a range of 15% to 25% by mole, with respect to the total (100% by mole) of all constitutional units constituting the silicon-containing polymer (A0).

In a case where the proportion of the constitutional unit (a2) is equal to or larger than the lower limit value of the above-described preferred range, etching resistance is easily enhanced, whereas in a case of being equal to or smaller than the upper limit value of the above-described preferred range, a resist pattern having favorable lithography characteristics is easily formed.

Constitutional Unit (a3)

The constitutional unit (a3) is a constitutional unit represented by General Formula (a3-1).

This constitutional unit (a3) is useful for enhancing the lithography characteristics. The introduction of the constitutional unit (a3) facilitates the control of the dissolution rate.

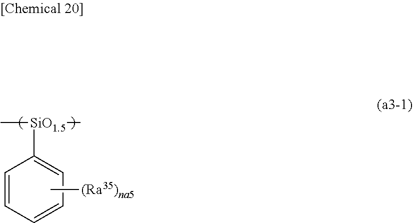

[In the formula, Ra³⁵ represents a hydrocarbon group having 1 to 6 carbon atoms. na5 represents an integer in a range of 0 to 5.1

In General Formula (a3-1), the hydrocarbon group as Ra³⁵ may be linear, branched, or cyclic, and it is preferably linear or branched. The hydrocarbon group as Ra³⁵ may be a saturated hydrocarbon group or may be an unsaturated hydrocarbon group, and it is preferably a saturated hydrocarbon group.

The hydrocarbon group as Ra³⁵ has 1 to 6 carbon atoms, preferably 1 to 5 carbon atoms, and more preferably 1 to 3 carbon atoms. The hydrocarbon group as Ra³⁵ is preferably an alkyl group. Examples thereof include a methyl group, an ethyl group, a propyl group, an isopropyl group, an n-butyl group, an isobutyl group, a tert-butyl group, a pentyl group, an isopentyl group, and a neopentyl group, among which a methyl group, an ethyl group, a propyl group, or an isopropyl group is preferable, a methyl group or an ethyl group is more preferable, and a methyl group is still more preferable.

In General Formula (a3-1), na5 represents an integer in a range of 0 to 5, preferably an integer in a range of 0 to 3, more preferably 0 or 1, and particularly preferably 0.

The constitutional unit (a3) contained in the silicon-containing polymer (A0) may be one kind or two or more kinds.

In a case where the silicon-containing polymer (A0) further has the constitutional unit (a3), the proportion of the constitutional unit (a3) in the silicon-containing polymer (A0) is preferably 30% by mole or less, more preferably in a range of 5% to 30% by mole, and particularly preferably in a range of 5% to 25% by mole, with respect to the total (100% by mole) of all constitutional units constituting the silicon-containing polymer (A0).

Constitutional Unit (a4)

The constitutional unit (a4) is a constitutional unit represented by Chemical Formula (a4-1).

This constitutional unit (a4) is useful for enhancing the lithography characteristics. The introduction of the constitutional unit (a4) facilitates the control of the dissolution rate.

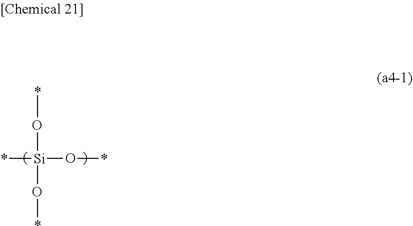

The constitutional unit (a4) contained in the silicon-containing polymer (A0) may be one kind or two or more kinds.

In a case where the silicon-containing polymer (A0) further has the constitutional unit (a4), the proportion of the constitutional unit (a4) in the silicon-containing polymer (A0) is preferably 30% by mole or less, more preferably in a range of 5% to 30% by mole, and particularly preferably in a range of 10% to 25% by mole, with respect to the total (100% by mole) of all constitutional units constituting the silicon-containing polymer (A0).

Constitutional Unit (a5)

The constitutional unit (a5) is a constitutional unit represented by General Formula (a5-1).

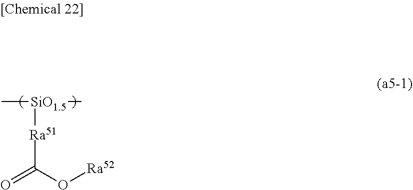

[In the formula, Ra⁵¹ represents a divalent linking group or a single bond. Ra⁵² represents an acid non-dissociable chain-like or cyclic aliphatic hydrocarbon group.]

In General Formula (a5-1), examples of the divalent linking group as Ra⁵¹ include a divalent hydrocarbon group which may have a substituent.

The hydrocarbon group as Ra⁵¹ may be an aliphatic hydrocarbon group or may be an aromatic hydrocarbon group.

Examples of the aliphatic hydrocarbon group and the aromatic hydrocarbon group as Ra⁵¹, and examples of the substituent which may be contained in the aliphatic hydrocarbon group and the aromatic hydrocarbon group include the same ones as the above-described aliphatic hydrocarbon group and aromatic hydrocarbon group as Ra¹¹, and the same one as the above-described substituent which may be contained in the aliphatic hydrocarbon group and the aromatic hydrocarbon group.

Among them, Ra⁵¹ is preferably an aliphatic hydrocarbon group having a ring in the structure thereof or a single bond, more preferably an aliphatic hydrocarbon group having a ring in the structure thereof, still more preferably a monocyclic alicyclic hydrocarbon group or a polycyclic alicyclic hydrocarbon group, and particularly preferably a polycyclic alicyclic hydrocarbon group.

The polycyclic alicyclic hydrocarbon group is preferably a group obtained by removing two hydrogen atoms from a polycycloalkane, and the polycycloalkane is preferably a polycycloalkane having 7 to 12 carbon atoms, more preferably adamantane, norbornane, isobornane, tricyclodecane, or tetracyclododecane, and most preferably norbornane.

In General Formula (a5-1), the acid non-dissociable chain-like aliphatic hydrocarbon group as Ra⁵² may be linear or may be branched.

The linear alkyl group preferably has 1 to 5 carbon atoms, and specific examples thereof include a methyl group, an ethyl group, an n-propyl group, an n-butyl group, and an n-pentyl group. Among these, a methyl group, an ethyl group, or an n-butyl group is preferable, a methyl group or an ethyl group is more preferable, and a methyl group is still more preferable.

The branched alkyl group has preferably 3 to 10 carbon atoms and more preferably 3 to 5 carbon atoms. Specific examples thereof include an isopropyl group, an isobutyl group, an isopentyl group, a neopentyl group a 1,1-diethylpropyl group, and a 2,2-dimethylbutyl group.

In General Formula (a5-1), the acid non-dissociable cyclic aliphatic hydrocarbon group as Ra⁵² may be a polycyclic group or may be a monocyclic group.

The aliphatic hydrocarbon group which is a monocyclic group is preferably a group obtained by removing one hydrogen atom from a monocycloalkane. The monocycloalkane is preferably a monocycloalkane having 3 to 6 carbon atoms, and specific examples thereof include cyclopentane and cyclohexane.

The aliphatic hydrocarbon group which is a polycyclic group is preferably a group obtained by removing one hydrogen atom from a polycycloalkane. The polycycloalkane preferably has 7 to 12 carbon atoms, and specific examples thereof include adamantane, norbornane, isobornane, tricyclodecane, and tetracyclododecane.

The constitutional unit (a5) contained in the silicon-containing polymer (A0) may be one kind or two or more kinds.

In a case where the silicon-containing polymer (A0) further has the constitutional unit (a5), the proportion of the constitutional unit (a5) in the silicon-containing polymer (A0) is preferably in a range of 45% to 75% by mole, more preferably in a range of 50% to 70% by mole, and still more preferably in a range of 55% to 65% by mole, with respect to the total (100% by mole) of all constitutional units constituting the silicon-containing polymer (A0).

Constitutional Unit (a6)

The constitutional unit (a6) is a constitutional unit represented by General Formula (a6-1).

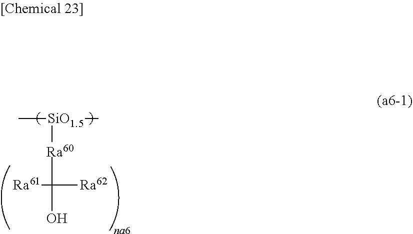

[In the formula, Ra⁶⁰ represents a divalent linking group or a single bond. Ra⁶¹ represents a fluorinated alkyl group having 1 to 12 carbon atoms. Ra⁶² represents an alkyl group having 1 to 12 carbon atoms, which may have a fluorine atom, or a hydrogen atom. Ra⁶⁰ and Ra⁶² may be bonded to each other to form a ring structure. na6 represents an integer of 1 or more.]

In General Formula (a6-1), examples of the divalent linking group as Ra⁶⁰ include a divalent hydrocarbon group which may have a substituent.

The hydrocarbon group as Ra⁶⁰ may be an aliphatic hydrocarbon group or may be an aromatic hydrocarbon group.

Examples of the aliphatic hydrocarbon group and the aromatic hydrocarbon group as Ra⁶⁰, and examples of the substituent which may be contained in the aliphatic hydrocarbon group and the aromatic hydrocarbon group include the same ones as the above-described aliphatic hydrocarbon group and aromatic hydrocarbon group as Ra¹¹, and the same one as the above-described substituent which may be contained in the aliphatic hydrocarbon group and the aromatic hydrocarbon group.

Among them, Ra⁶⁰ is preferably an aliphatic hydrocarbon group having a ring in the structure thereof or a single bond, more preferably an aliphatic hydrocarbon group having a ring in the structure thereof, still more preferably a monocyclic alicyclic hydrocarbon group or a polycyclic alicyclic hydrocarbon group, and particularly preferably a polycyclic alicyclic hydrocarbon group.

The polycyclic alicyclic hydrocarbon group is preferably a group obtained by removing two hydrogen atoms from a polycycloalkane, and the polycycloalkane is preferably a polycycloalkane having 7 to 12 carbon atoms, more preferably adamantane, norbornane, isobornane, tricyclodecane, or tetracyclododecane, and most preferably norbornane.

In General Formula (a6-1), Ra⁶¹ preferably has 1 to 6 carbon atoms, more preferably 1 to 3 carbon atoms, and still more preferably 1 carbon atom. It is particularly preferable that Ra⁶′ is a trifluoromethyl group.

Ra⁶² preferably has 0 to 6 carbon atoms, more preferably 0 to 3 carbon atoms, and still more preferably 1 carbon atom. Ra⁶² is preferably a hydrogen atom, a methyl group, or a trifluoromethyl group, and particularly preferably a trifluoromethyl group.

na6 is appropriately determined depending on the structure of Ra⁶⁰ and is preferably an integer in a range of 1 to 3 and more preferably 1.

The constitutional unit (a6) contained in the silicon-containing polymer (A0) may be one kind or two or more kinds.

In a case where the silicon-containing polymer (A0) further has the constitutional unit (a6), the proportion of the constitutional unit (a6) in the silicon-containing polymer (A0) is preferably in a range of 10% to 40% by mole, more preferably in a range of 10% to 30% by mole, and still more preferably in a range of 15% to 25% by mole, with respect to the total (100% by mole) of all constitutional units constituting the silicon-containing polymer (A0).

In a case where the silicon-containing resin (the component (A)) that is used in the resist composition of the present embodiment is a resin that is soluble in an alkali developing solution and has a crosslinkable group, examples of the preferred component (A0) include a silsesquioxane resin having a repeating structure of a constitutional unit represented by General Formula (a0-1-1) and a constitutional unit (a2); a silsesquioxane resin having a repeating structure of a constitutional unit represented by General Formula (a0-1-1) and a constitutional unit (a3); and a silsesquioxane resin having a repeating structure of a constitutional unit represented by General Formula (a0-1-1), a constitutional unit (a2), and a constitutional unit (a3).

In a case where it is a resin that is soluble in an alkali developing solution and has a crosslinkable group, examples of the more preferred component (A0) include a silsesquioxane resin having a repeating structure of a constitutional unit represented by General Formula (a0-1-1) and a constitutional unit represented by General Formula (a2-1); and a silsesquioxane resin having a repeating structure of a constitutional unit represented by General Formula (a0-1-1), a constitutional unit represented by General Formula (a3-1), and a constitutional unit represented by General Formula (a2-2).

In a case where the silicon-containing resin (the component (A)) that is used in the resist composition of the present embodiment is a resin having a polarity that is increased under action of acid, thereby having increased solubility in an alkali developing solution, examples of the preferred component (A0) include a silsesquioxane resin having a repeating structure of a constitutional unit represented by General Formula (a0-1-1) and a constitutional unit represented by General Formula (a0-1-2); a silsesquioxane resin having a repeating structure of a constitutional unit represented by General Formula (a0-1-1) and a constitutional unit represented by General Formula (a0-1-3); a silsesquioxane resin having a repeating structure of a constitutional unit represented by General Formula (a0-1-2) and a constitutional unit represented by General Formula (a5-1); and a silsesquioxane resin having a repeating structure of a constitutional unit represented by General Formula (a0-1-2), a constitutional unit represented by General Formula (a5-1), and a constitutional unit represented by General Formula (a6-1).

The weight average molecular weight (Mw) (based on the polystyrene equivalent value determined by gel permeation chromatography (GPC)) of the component (A0) is not particularly limited, and it is, for example, 1,000 or more, preferably in a range of 1,000 to 10,000, more preferably in a range of 1,500 to 7,500, and still more preferably in a range of 2,000 to 5,000.

In a case where the Mw of the component (A0) is equal to or smaller than the upper limit value of the above-described preferred range, the solubility in an organic solvent is further improved. On the other hand, in a case where it is equal to or larger than the lower limit value of the above-described preferred range, the patterning properties of the resist film become better, and the lithography characteristics and etching resistance of the formed resist pattern are further improved.

<Acid Generator Component (B)>

The acid generator component (the component (B)) that is used in the resist composition according to the present embodiment includes an onium salt (B0) (hereinafter, also referred to as a “component (B0)”) consisting of an anion moiety having an iodine atom and a cation moiety.

Since the resist composition according to the present embodiment contains the component (B0), the usability particularly for EUV is increased.

<<Onium Salt (B0)>>

The component (B0) is not particularly limited as long as it has an iodine atom in the anion moiety, and those which have been proposed so far as an acid generator for a chemical amplification-type resist composition can be used.

This component (B0) acts, in the resist composition, as an acid component that causes crosslinking between the above-described component (A) and a crosslinking agent component described later or as an acid component that increases the solubility of the above-described component (A) in an alkali developing solution, or alternatively as a base component that controls the diffusion of acid generated upon exposure.

Whether the component (B0) acts as the acid component or the base component in the resist composition is determined by the relative strength of the acid generated upon exposure.

Therefore, this component (B0) can be used as the acid component, can be used as the base component, or two or more kinds thereof can be used in combination as the acid component and the base component.

Preferred examples of such a component (B0) include at least one onium salt selected from the group consisting of a sulfonic acid salt represented by General Formula (b0-1) and a carboxylic acid salt represented by General Formula (b0-2).

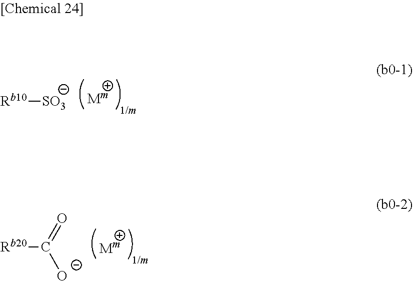

[In the formulae, R^{b10} and R^{b20} each independently represent an organic group having an iodine atom, which has 1 to 40 carbon atoms. M^{m+} represents an m-valent onium cation. m represents an integer of 1 or more.]

Sulfonic acid salt represented by General Formula (b0-1) In General Formula (b0-1), examples of the organic group as R^{b10} include a hydrocarbon group which may have a substituent, a divalent linking group containing an oxygen atom, or a combination thereof.

Preferred examples of this sulfonic acid salt include a sulfonic acid salt represented by General Formula (b0-1b) and a sulfonic acid salt represented by General Formula (b0-1d).

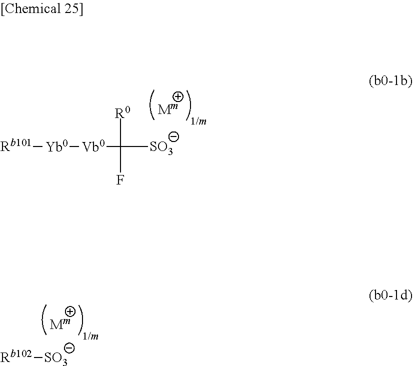

[In General Formula (b0-1b), R^{b101} represents a cyclic group having an iodine atom, a chain-like alkyl group having an iodine atom, or a chain-like alkenyl group having an iodine atom. Yb⁰ represents a divalent linking group or a single bond. Vb⁰ represents a single bond, an alkylene group, or a fluorinated alkylene group. R⁰ represents a hydrogen atom, a fluorinated alkyl group having 1 to 5 carbon atoms, or a fluorine atom. In General Formula (b0-1d), R^{b102} represents a cyclic group having an iodine atom, a chain-like alkyl group having an iodine atom, or a chain-like alkenyl group having an iodine atom. M^{m+} represents an m-valent onium cation. m represents an integer of 1 or more.]

Cyclic Group Having Iodine Atom:

The cyclic group as R^{b101} is preferably a cyclic hydrocarbon group, and the cyclic hydrocarbon group may be an aromatic hydrocarbon group or an aliphatic hydrocarbon group. The aliphatic hydrocarbon group indicates a hydrocarbon group that has no aromaticity. The aliphatic hydrocarbon group may be saturated or unsaturated. In general, it is preferable that the aliphatic hydrocarbon group is saturated.

The aromatic hydrocarbon group as R^{b101} is a hydrocarbon group having an aromatic ring. The aromatic hydrocarbon group preferably has 3 to 30 carbon atoms, more preferably 5 to 30, still more preferably 5 to 20, particularly preferably 6 to 15, and most preferably 6 to 10. However, the number of carbon atoms in a substituent is not included in the number of carbon atoms.

Specific examples of the aromatic ring contained in the aromatic hydrocarbon group as R^{b101} include benzene, fluorene, naphthalene, anthracene, phenanthrene, biphenyl, or an aromatic heterocyclic ring obtained by substituting part of carbon atoms constituting this aromatic ring with a hetero atom. Examples of the hetero atom in the aromatic heterocyclic rings include an oxygen atom, a sulfur atom, and a nitrogen atom.

Specific examples of the aromatic hydrocarbon group as R^{b101} include a group in which one hydrogen atom has been removed from the above-described aromatic ring (an aryl group such as a phenyl group or a naphthyl group), and a group in which one hydrogen atom in the aromatic ring has been substituted with an alkylene group (for example, an arylalkyl group such as a benzyl group, a phenethyl group, a 1-naphthylmethyl group, a 2-naphthylmethyl group, 1-naphthylethyl group, or a 2-naphthylethyl group). The alkylene group (the alkyl chain in the arylalkyl group) preferably has 1 to 4 carbon atoms, more preferably 1 or 2 carbon atoms, and particularly preferably 1 carbon atom.

Examples of the cyclic aliphatic hydrocarbon group as R^{b101} include aliphatic hydrocarbon groups containing a ring in the structure thereof.

Examples of the aliphatic hydrocarbon group containing a ring in the structure thereof include an alicyclic hydrocarbon group (a group obtained by removing one hydrogen atom from an aliphatic hydrocarbon ring), a group in which the alicyclic hydrocarbon group is bonded to the terminal of a linear or branched aliphatic hydrocarbon group, and a group in which the alicyclic hydrocarbon group is interposed in a linear or branched aliphatic hydrocarbon group.

The alicyclic hydrocarbon group preferably has 3 to 20 carbon atoms and more preferably 3 to 12 carbon atoms.

The alicyclic hydrocarbon group may be a polycyclic group or a monocyclic group. The monocyclic alicyclic hydrocarbon group is preferably a group obtained by removing one or more hydrogen atoms from a monocycloalkane. The monocycloalkane preferably has 3 to 6 carbon atoms, and specific examples thereof include cyclopentane and cyclohexane. The polycyclic alicyclic hydrocarbon group is preferably a group obtained by removing one or more hydrogen atoms from a polycycloalkane, and the polycycloalkane preferably has 7 to 30 carbon atoms. Among the above, the polycycloalkane is more preferably a polycycloalkane having a bridged ring-based polycyclic skeleton, such as adamantane, norbornane, isobornane, tricyclodecane, or tetracyclododecane; or a polycycloalkane having a condensed ring-based polycyclic skeleton, such as a cyclic group having a steroid skeleton.

Among these examples, as the cyclic aliphatic hydrocarbon group as R^{b101}, a group in which one or more hydrogen atoms have been removed from a monocycloalkane or a polycycloalkane is preferable, a group in which one hydrogen atom has been removed from a polycycloalkane is more preferable, an adamantyl group or a norbornyl group is particularly preferable, and an adamantyl group is most preferable.

The linear aliphatic hydrocarbon group which may be bonded to the alicyclic hydrocarbon group preferably has 1 to 10 carbon atoms, more preferably 1 to 6 carbon atoms, still more preferably 1 to 4 carbon atoms, and most preferably 1 to 3 carbon atoms. The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group which may be bonded to the alicyclic hydrocarbon group preferably has 2 to 10 carbon atoms, more preferably 3 to 6 carbon atoms, still more preferably 3 or 4 carbon atoms, and most preferably 3 carbon atoms. The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The cyclic hydrocarbon group as R^{b101} may contain a hetero atom such as a heterocyclic ring.

The cyclic hydrocarbon group as R^{b101} may be a condensed ring-type group containing a condensed ring in which an aliphatic hydrocarbon ring and an aromatic ring are condensed. Examples of the condensed ring include a condensed ring in which one or more aromatic rings are condensed with a polycycloalkane having a bridged ring-based polycyclic skeleton. Specific examples of the bridged ring-based polycycloalkane include bicycloalkanes such as bicyclo[2.2.1]heptane (norbornane) and bicyclo[2.2.2]octane. The condensed ring type is preferably a group containing a condensed ring, in which two or three aromatic rings are condensed with a bicycloalkane, and more preferably a group containing a condensed ring, in which two or three aromatic rings are condensed with bicyclo[2.2.2]octane. Specific examples of the condensed ring-type group as R^{b101} include groups represented by Chemical Formulae (r-br-1) and (r-br-2). In the formulae, * represents a bonding site for bonding to Yb⁰ in General Formula (b0-1b).

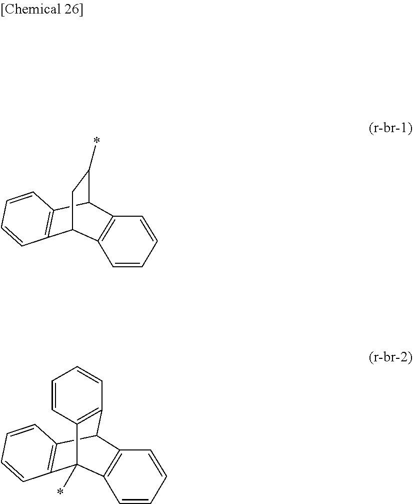

The cyclic group as R^{b101} has an iodine atom as a substituent. The number of iodine atoms bonded to the cyclic group is preferably 1 to 3 and more preferably 2 or 3.

R^{b101} may have a substituent other than the iodine atom. Examples of the substituent other than the iodine atom include an alkyl group, an alkoxy group, a halogen atom other than the iodine atom, a halogenated alkyl group, a hydroxyl group, a carbonyl group, and a nitro group.

Chain-Like Alkyl Group Having Iodine Atom:

The chain-like alkyl group as R^{b101} may be linear or branched.

The linear alkyl group preferably has 1 to 20 carbon atoms, more preferably 1 to 15 carbon atoms, and most preferably 1 to 10 carbon atoms.

The branched alkyl group preferably has 3 to 20 carbon atoms, more preferably 3 to 15, and most preferably 3 to 10. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-Like Alkenyl Group Having Iodine Atom:

Such a chain-like alkenyl group R^{b101} may be linear or branched, and the number of carbon atoms thereof is preferably in a range of 2 to 10, more preferably in a range of 2 to 5, still more preferably in a range of 2 to 4, and particularly preferably 3. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the above, the chain-like alkenyl group is preferably a linear alkenyl group, more preferably a vinyl group or a propenyl group, and particularly preferably a vinyl group.

The chain-like alkyl group or chain-like alkenyl group as R^{b101} has an iodine atom as a substituent. The number of iodine atoms bonded to each of the chain-like alkyl group or the chain-like alkenyl group is preferably 1 to 3 and more preferably 2 or 3.

The chain-like alkyl group or chain-like alkenyl group as R^{b101} may have a substituent other than the iodine atom. Examples of the substituent other than the iodine atom include an alkoxy group, a halogen atom other than the iodine atom, a halogenated alkyl group, a hydroxyl group, a carbonyl group, and a nitro group.

Among the above, R^{b101} is preferably a cyclic group having an iodine atom, more preferably an aromatic hydrocarbon group having an iodine atom, and still more preferably a phenyl group having an iodine atom or a naphthyl group having an iodine atom.

Examples of the preferred R^{b101} include a group represented by General Formula (b0-r-1p).

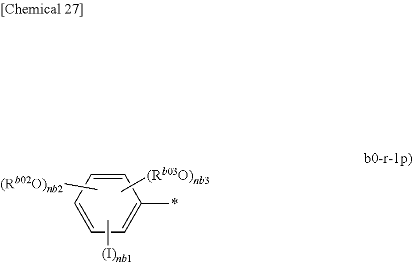

[In the formula, I is an iodine atom. R^{b02} represents a hydrocarbon group having 1 to 6 carbon atoms or a hydrogen atom. R^{b03} represents a hydrocarbon group having 1 to 6 carbon atoms. nb1 represents an integer in a range of 1 to 5. nb2 represents an integer in a range of 0 to 4. nb3 represents an integer in a range of 0 to 4. Here, 1≤nb1+nb2+nb3≤5 is satisfied. * represents a bonding site for bonding to Yb⁰ in General Formula (b0-1b).]

In General Formula (b0-r-1p), the hydrocarbon group as R^{b02} has 1 to 6 carbon atoms and preferably has 1 to 5 carbon atoms, among which a methyl group, an ethyl group, a propyl group, or an isopropyl group is more preferable, a methyl group or an ethyl group is still more preferable, and a methyl group is particularly preferable.

Among the above, R^{b02} is preferably a hydrogen atom, that is, —OR^{b02} is preferably a phenolic hydroxyl group.

In General Formula (b0-r-1p), the hydrocarbon group as R^{b03} has 1 to 6 carbon atoms and preferably has 1 to 5 carbon atoms, among which a methyl group, an ethyl group, a propyl group, or an isopropyl group is more preferable, and a methyl group or an ethyl group is still more preferable.
nb1 is an integer in a range of 1 to 5, preferably an integer in a range of 1 to 3, more preferably 2 or 3, and still more preferably 3.
nb2 is an integer in a range of 0 to 4, preferably an integer in a range of 0 to 2, more preferably 0 or 1, and still more preferably 0.
nb3 is an integer in a range of 0 to 4, preferably an integer in a range of 0 to 2, more preferably 0 or 1, and still more preferably 0.

In General Formula (b0-1b), Yb⁰ represents a divalent linking group or a single bond. Suitable examples of the divalent linking group as Yb⁰ include a divalent linking group containing an oxygen atom.

In a case where Yb⁰ represents a divalent linking group containing an oxygen atom, Yb⁰ may contain an atom other than the oxygen atom. Examples of the atom other than the oxygen atom include a carbon atom, a hydrogen atom, a sulfur atom, and a nitrogen atom.

Examples of divalent linking groups containing an oxygen atom include non-hydrocarbon-based oxygen atom-containing linking groups such as an oxygen atom (an ether bond; —O—), an ester bond (—C(═O)—O—), an oxycarbonyl group (—O—C(═O)—), an amide bond (—C(═O)—NH—), a carbonyl group (—C(═O)—), or a carbonate bond (—O—C(═O)—O—); and combinations of the above-described non-hydrocarbon-based oxygen atom-containing linking groups with an alkylene group. A sulfonyl group (—SO₂—) may be further linked to this combination. Among the divalent linking groups containing an oxygen atom, an ester bond (—C(═O)—O—) or an oxycarbonyl group (—O—C(═O)—) is more preferable.

Among the above, Yb⁰ is preferably a divalent linking group, more preferably a divalent linking group containing an oxygen atom, and still more preferably an ester bond (—C(═O)—O—) or an oxycarbonyl group (—O—C(═O)—).

In General Formula (b0-1b), Vb⁰ represents a single bond, an alkylene group, or a fluorinated alkylene group.

The alkylene group and the fluorinated alkylene group as Vb⁰ each preferably have 1 to 4 carbon atoms and more preferably 1 to 3 carbon atoms. Examples of the fluorinated alkylene group as Vb⁰ include a group obtained by substituting part or all of hydrogen atoms in the alkylene group with a fluorine atom. Among them, Vb⁰ is preferably an alkylene group having 1 to 4 carbon atoms, a fluorinated alkylene group having 1 to 4 carbon atoms, or a single bond, and more preferably a group obtained by substituting part of hydrogen atoms of an alkylene group having 1 to 3 carbon atoms with a fluorine atom, or a single bond, and still more preferably —CH(CF₃)— or —CH₂—.

In General Formula (b0-1b), R⁰ represents a hydrogen atom, a fluorinated alkyl group having 1 to 5 carbon atoms, or a fluorine atom. R⁰ is preferably a fluorine atom or a perfluoroalkyl group having 1 to 5 carbon atoms and more preferably a fluorine atom.

Hereinafter, specific examples of the anion moiety of the sulfonic acid salt, which is represented by General Formula (b0-1b), are shown.

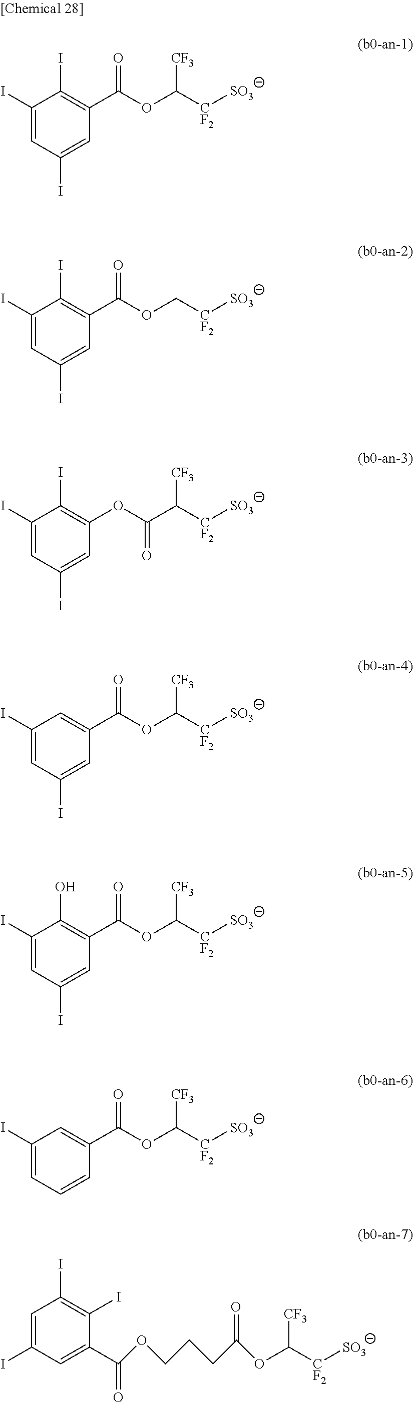

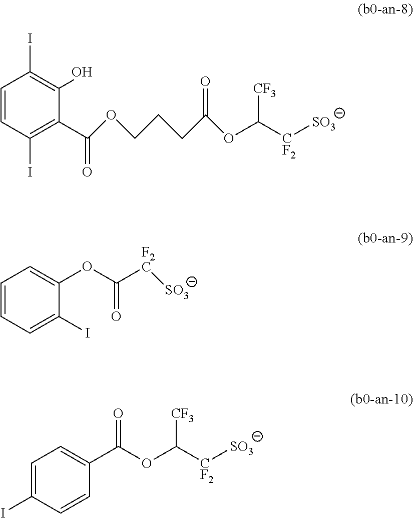

In General Formula (b0-1d), R^{b102} represents a cyclic group having an iodine atom, a chain-like alkyl group having an iodine atom, or a chain-like alkenyl group having an iodine atom, and the description therefor is the same as that for R^{b101} in General Formula (b0-1b).

Among the above, R^{b102} is preferably a chain-like alkyl group having an iodine atom or an aliphatic cyclic group having an iodine atom. The chain-like alkyl group preferably has 1 to 10 carbon atoms and more preferably 3 to 10 carbon atoms. The aliphatic cyclic group is more preferably a group (which may have a substituent) obtained by removing one or more hydrogen atoms from adamantane, norbornane, isobornane, tricyclodecane, tetracyclododecane, or the like; and a group obtained by removing one or more hydrogen atoms from camphor or the like.

However, the carbon atom adjacent to the S atom in R^{b102} has no fluorine atom bonded thereto (the carbon atom adjacent to the S atom in R^{b102} is not substituted with a fluorine atom). As a result, the anion moiety of the sulfonic acid salt represented by General Formula (b0-1d) becomes an appropriate weak acid anion, thereby improving the quenching ability.

In General Formula (b0-1), General Formula (b0-1b), and General Formula (b0-1d), M^{m+} represents an m-valent onium cation, and among the above, a sulfonium cation or an iodonium cation is more preferable. m represents an integer of 1 or more.

Examples of the onium cation as M^{m+} include organic cations each represented by General Formulae (ca-1) to (ca-3).

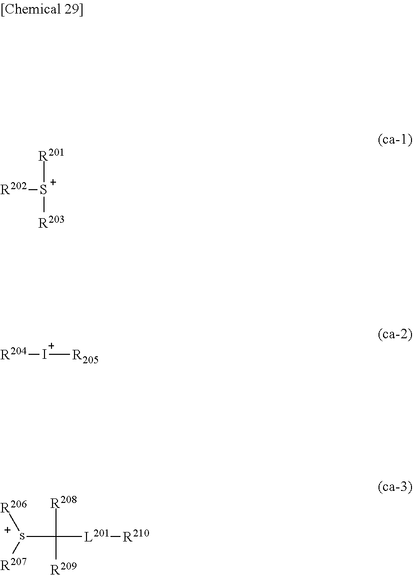

[In the formulae, R²⁰¹ to R²⁰⁷ each independently represent an aryl group, an alkyl group, or an alkenyl group, each of which may have a substituent. R²⁰¹ to R²⁰³, and R²⁰⁶ and R²⁰⁷ may be bonded to each other to form a ring together with the sulfur atoms in the formulae. R²⁰⁸ and R²⁰⁹ each independently represent a hydrogen atom or an alkyl group having 1 to 5 carbon atoms. R²¹⁰ represents an aryl group which may have a substituent, an alkyl group which may have a substituent, an alkenyl group which may have a substituent, or a —SO₂—-containing cyclic group which may have a substituent. L²⁰¹ represents —C(═O)— or —C(═O)—O—.]

In General Formulae (ca-1) to (ca-3), examples of the aryl group as R²⁰¹ to R²⁰⁷ include an unsubstituted aryl group having 6 to 20 carbon atoms, and a phenyl group or a naphthyl group is preferable.

The alkyl group as R²⁰¹ to R²⁰⁷ is preferably a chain-like or cyclic alkyl group which has 1 to 30 carbon atoms.

The alkenyl group as R²⁰¹ to R²⁰⁷ preferably has 2 to 10 carbon atoms.

Examples of the substituent which may be contained in R²⁰¹ to R²⁰⁷ and R²¹⁰ include an alkyl group, a halogen atom, a halogenated alkyl group, a carbonyl group, a cyano group, an amino group, an aryl group, and groups each represented by General Formulae (ca-r-1) to (ca-r-7).

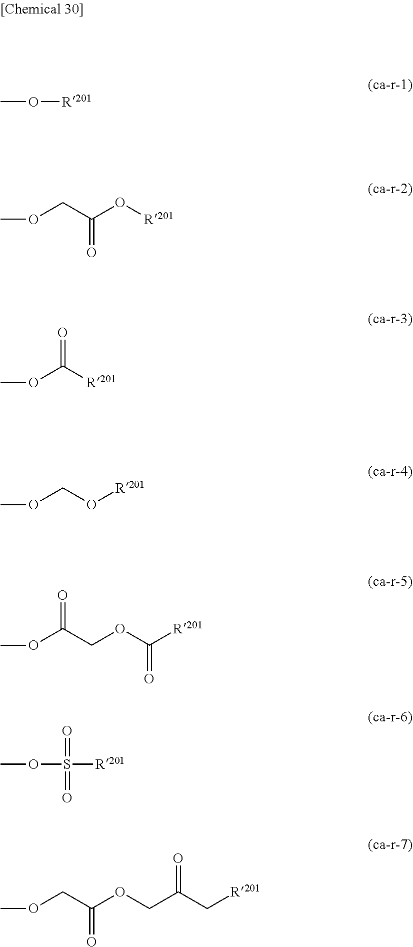

[In the formulae, each R′²⁰¹ independently represents a hydrogen atom, a cyclic group which may have a substituent, a chain-like alkyl group which may have a substituent, or a chain-like alkenyl group which may have a substituent.]

Cyclic Group which May have Substituent:

The cyclic group is preferably a cyclic hydrocarbon group, and the cyclic hydrocarbon group may be an aromatic hydrocarbon group or an aliphatic hydrocarbon group. The aliphatic hydrocarbon group indicates a hydrocarbon group that has no aromaticity. The aliphatic hydrocarbon group may be saturated or unsaturated. In general, it is preferable that the aliphatic hydrocarbon group is saturated.

The aromatic hydrocarbon group as R′²⁰¹ is a hydrocarbon group having an aromatic ring. The aromatic hydrocarbon group preferably has 3 to 30 carbon atoms, more preferably 5 to 30 carbon atoms, still more preferably 5 to 20 carbon atoms, particularly preferably 6 to 15 carbon atoms, and most preferably 6 to 10 carbon atoms. Here, the number of carbon atoms in a substituent is not included in the number of carbon atoms.

Specific examples of the aromatic ring contained in the aromatic hydrocarbon group as R′²⁰¹ include benzene, fluorene, naphthalene, anthracene, phenanthrene, biphenyl, or an aromatic heterocyclic ring obtained by substituting a part of carbon atoms constituting these aromatic rings with a hetero atom. Examples of the hetero atom in the aromatic heterocyclic rings include an oxygen atom, a sulfur atom, and a nitrogen atom.

Specific examples of the aromatic hydrocarbon group as R′²⁰¹ include a group obtained by removing one hydrogen atom from the above-described aromatic ring (an aryl group; for example, a phenyl group or a naphthyl group) and a group in which one hydrogen atom in the aromatic ring has been substituted with an alkylene group (for example, an arylalkyl group such as a benzyl group, a phenethyl group, a 1-naphthylmethyl group, a 2-naphthylmethyl group, 1-naphthylethyl group, or a 2-naphthylethyl group). The alkylene group (an alkyl chain in the arylalkyl group) preferably has 1 to 4 carbon atoms, more preferably 1 or 2 carbon atoms, and particularly preferably 1 carbon atom.

Examples of the cyclic aliphatic hydrocarbon group as R′²⁰¹ include aliphatic hydrocarbon groups containing a ring in the structure thereof.

Examples of the aliphatic hydrocarbon group containing a ring in the structure thereof include an alicyclic hydrocarbon group (a group obtained by removing one hydrogen atom from an aliphatic hydrocarbon ring), a group in which the alicyclic hydrocarbon group is bonded to the terminal of a linear or branched aliphatic hydrocarbon group, and a group in which the alicyclic hydrocarbon group is interposed in a linear or branched aliphatic hydrocarbon group.

The alicyclic hydrocarbon group preferably has 3 to 20 carbon atoms and more preferably 3 to 12 carbon atoms.

The alicyclic hydrocarbon group may be a polycyclic group or a monocyclic group. The monocyclic alicyclic hydrocarbon group is preferably a group obtained by removing one or more hydrogen atoms from a monocycloalkane. The monocycloalkane is preferably a monocycloalkane having 3 to 6 carbon atoms, and specific examples thereof include cyclopentane and cyclohexane. The polycyclic alicyclic hydrocarbon group is preferably a group obtained by removing one or more hydrogen atoms from a polycycloalkane, and the polycycloalkane preferably has 7 to 30 carbon atoms. Among the above, the polycycloalkane is more preferably a polycycloalkane having a bridged ring-based polycyclic skeleton, such as adamantane, norbornane, isobornane, tricyclodecane, or tetracyclododecane; or a polycycloalkane having a condensed ring-based polycyclic skeleton, such as a cyclic group having a steroid skeleton.

Among them, the cyclic aliphatic hydrocarbon group as R′²⁰¹ is preferably a group obtained by removing one or more hydrogen atoms from a monocycloalkane or a polycycloalkane, more preferably a group obtained by removing one hydrogen atom from a polycycloalkane, particularly preferably an adamantyl group or a norbornyl group, and most preferably an adamantyl group.

The linear or branched aliphatic hydrocarbon group which may be bonded to the alicyclic hydrocarbon group preferably has 1 to 10 carbon atoms, more preferably 1 to 6 carbon atoms, still more preferably 1 to 4 carbon atoms, and particularly preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The cyclic hydrocarbon group as R′²⁰¹ may contain a hetero atom such as a heterocyclic ring.

Examples of the substituent of the cyclic group as R′²⁰¹ include an alkyl group, an alkoxy group, a halogen atom, a halogenated alkyl group, a hydroxyl group, a carbonyl group, and a nitro group.

The alkyl group as the substituent is preferably an alkyl group having 1 to 5 carbon atoms, and a methyl group, an ethyl group, a propyl group, an n-butyl group, or a tert-butyl group is most preferable.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

The halogen atom as the substituent is preferably a fluorine atom.

Examples of the above-described halogenated alkyl group as the substituent include a group in which part or all of hydrogen atoms in an alkyl group having 1 to 5 carbon atoms such as a methyl group, an ethyl group, a propyl group, an n-butyl group, or a tert-butyl group have been substituted with the above-described halogen atom.

The carbonyl group as the substituent is a group that is substituted for a methylene group (—CH₂—) constituting the cyclic hydrocarbon group.

Chain-Like Alkyl Group which May have Substituent:

The chain-like alkyl group as R′²⁰¹ may be linear or branched.

The linear alkyl group preferably has 1 to 20 carbon atoms, more preferably 1 to 15 carbon atoms, and most preferably 1 to 10 carbon atoms.

The branched alkyl group preferably has 3 to 20 carbon atoms, more preferably 3 to 15 carbon atoms, and most preferably 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-Like Alkenyl Group which May have Substituent:

Such a chain-like alkenyl group as R′²⁰¹ may be linear or branched, preferably has 2 to 10 carbon atoms, more preferably 2 to 5 carbon atoms, still more preferably 2 to 4 carbon atoms, and particularly preferably 3 carbon atoms. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the above, the chain-like alkenyl group is preferably a linear alkenyl group, more preferably a vinyl group or a propenyl group, and particularly preferably a vinyl group.

Examples of the substituent in the chain-like alkyl group or alkenyl group as R′²¹⁰ include an alkoxy group, a halogen atom, a halogenated alkyl group, a hydroxyl group, a carbonyl group, a nitro group, an amino group, and a cyclic group as R′²⁰¹.

As the cyclic group which may have a substituent, the chain-like alkyl group which may have a substituent, or the chain-like alkenyl group which may have a substituent, as R′²⁰¹, a group that is the same as the acid dissociable group represented by above-described General Formula (a1-r-2) can be mentioned as the same one as the cyclic group which may have a substituent or the chain-like alkyl group which may have a substituent, in addition to the groups described above.

Among them, R′²⁰¹ is preferably a cyclic group which may have a substituent and more preferably a cyclic hydrocarbon group which may have a substituent. More specifically, it is, for example, preferably a group obtained by removing one or more hydrogen atoms from a phenyl group, a naphthyl group, or a polycycloalkane.

In General Formulae (ca-1) to (ca-3), in a case where R²⁰¹ to R²⁰³ and R²⁰⁶ and R²⁰⁷ are bonded to each other to form a ring with a sulfur atom in the formula, these groups may be bonded to each other via a hetero atom such as a sulfur atom, an oxygen atom, or a nitrogen atom, or a functional group such as a carbonyl group, —SO—, —SO₂—, —SO₃—, —COO—, —CONH—, or —N(R_{N})— (here, R_{N} represents an alkyl group having 1 to 5 carbon atoms). Regarding the ring to be formed, it is preferable that a ring containing the sulfur atom in the formula in the ring skeleton thereof is a 3-membered to 10-membered ring and it is particularly preferable that it is a 5-membered to 7-membered ring, in a case where the sulfur atom is included. Specific examples of the ring to be formed include a thiophene ring, a thiazole ring, a benzothiophene ring, a dibenzothiophene ring, a 9H-thioxanthene ring, a thioxanthone ring, a thianthrene ring, a phenoxathiin ring, a tetrahydrothiophenium ring, and a tetrahydrothiopyranium ring.

R²⁰⁸ and R²⁰⁹ each independently represent a hydrogen atom or an alkyl group having 1 to 5 carbon atoms and are preferably a hydrogen atom or an alkyl group having 1 to 3 carbon atoms. In a case of representing an alkyl group, R²⁰⁸ and R²⁰⁹ may be bonded to each other to form a ring.

R²¹⁰ represents an aryl group which may have a substituent, an alkyl group which may have a substituent, an alkenyl group which may have a substituent, or a —SO₂—-containing cyclic group which may have a substituent.

Examples of the aryl group as R²¹⁰ include an unsubstituted aryl group having 6 to 20 carbon atoms, and a phenyl group or a naphthyl group is preferable.

The alkyl group as R²¹⁰ is preferably a chain-like or cyclic alkyl group which has 1 to 30 carbon atoms.

The alkenyl group as R²¹⁰ preferably has 2 to 10 carbon atoms.

The —SO₂—-containing cyclic group which may have a substituent, as R²¹⁰, is preferably a “—SO₂—-containing polycyclic group”.

Specific examples of the suitable cation represented by General Formula (ca-1) include cations each represented by the following chemical formulae.

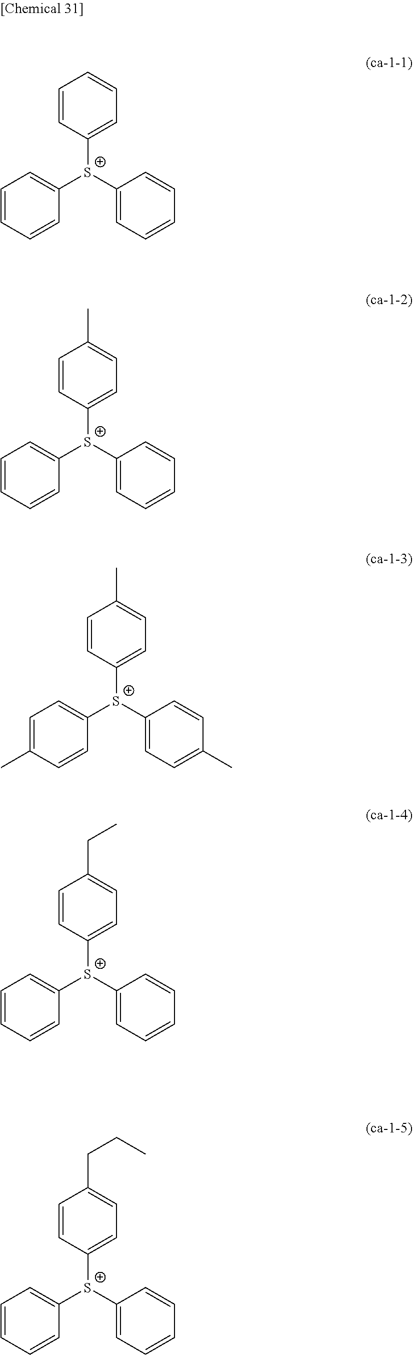

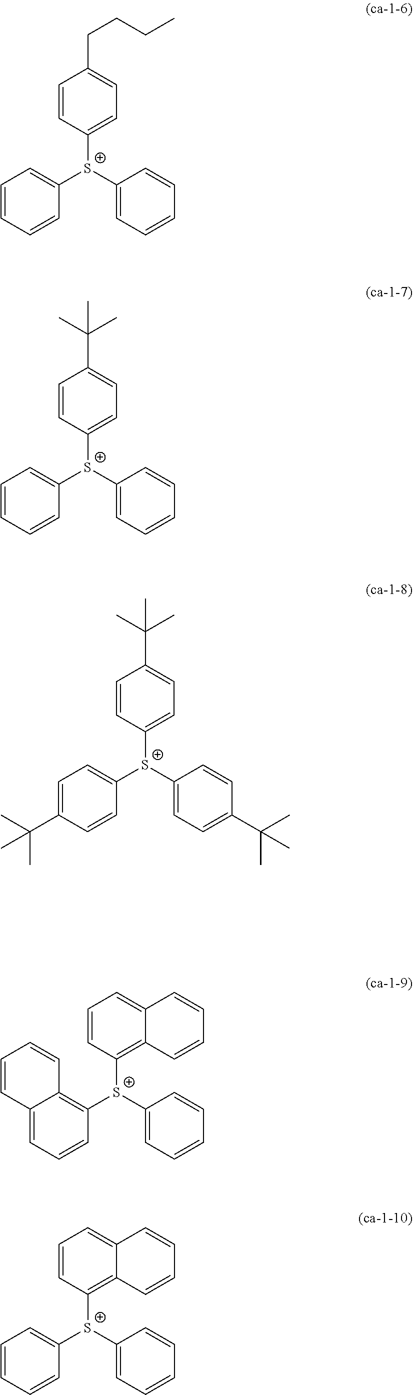

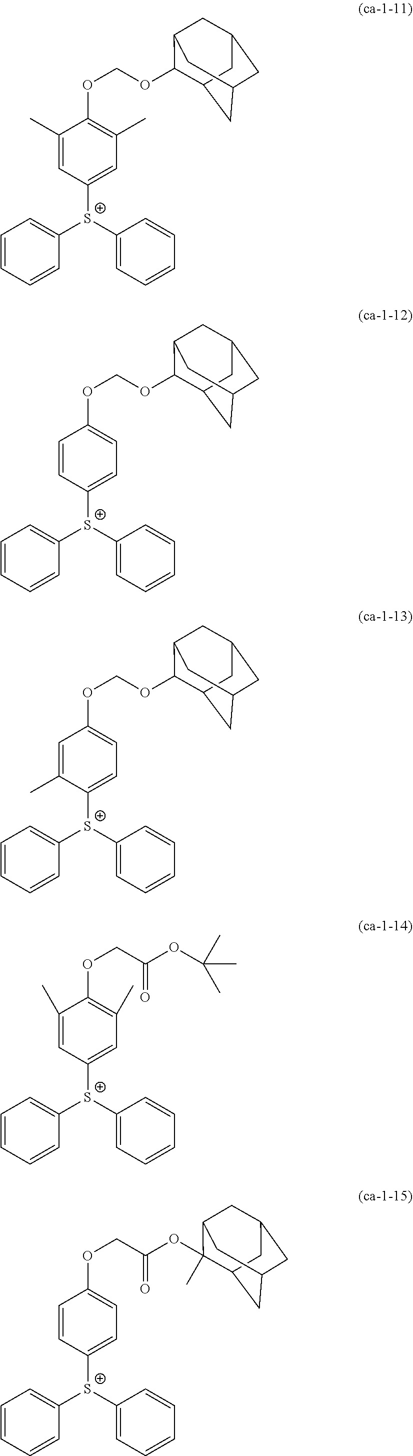

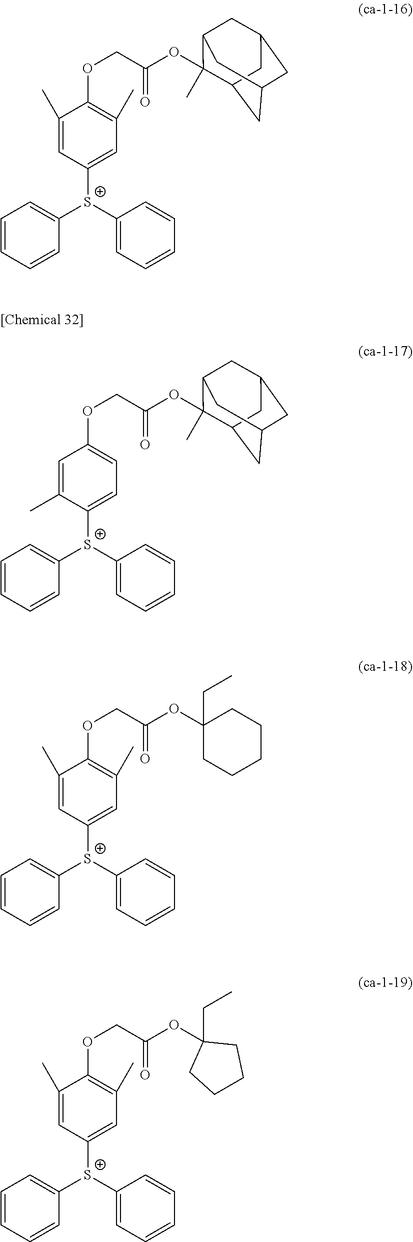

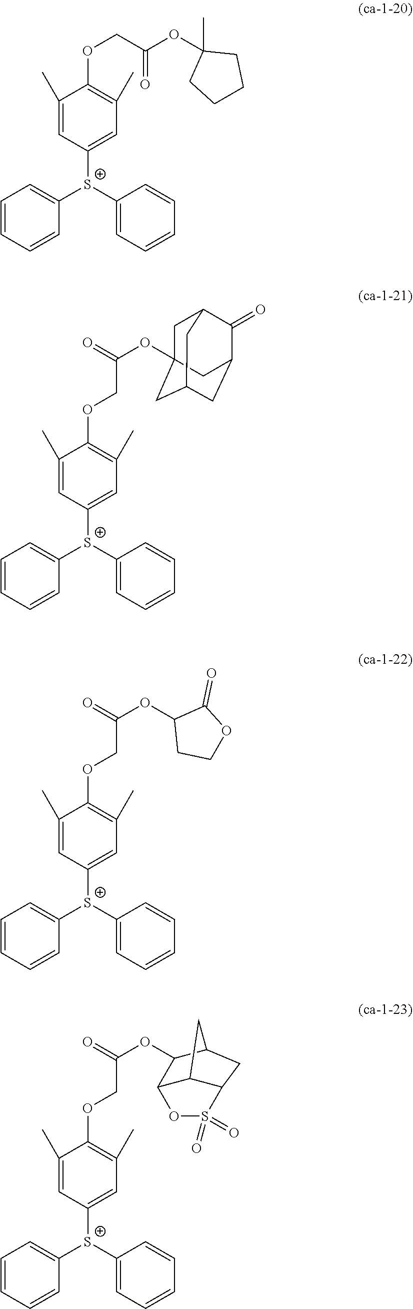

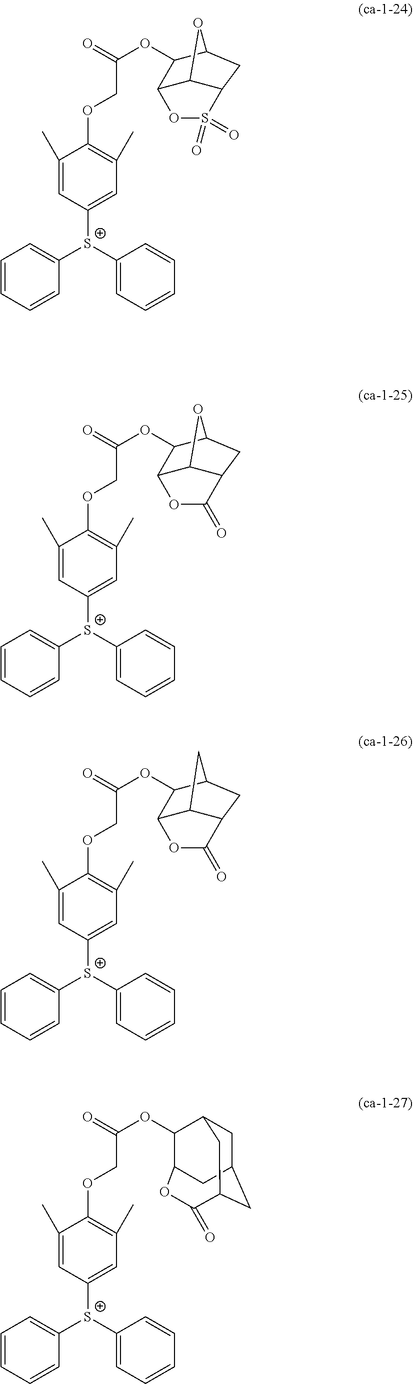

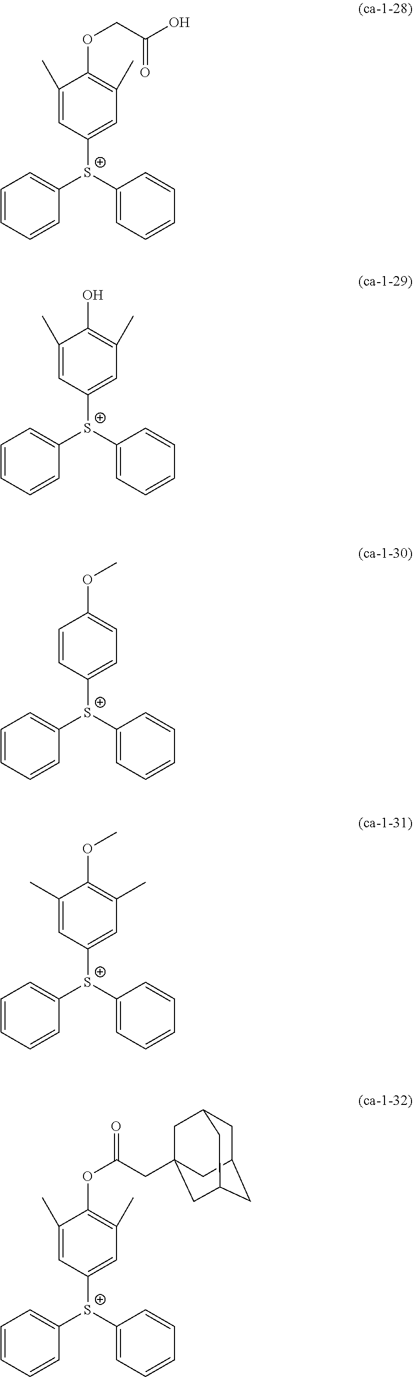

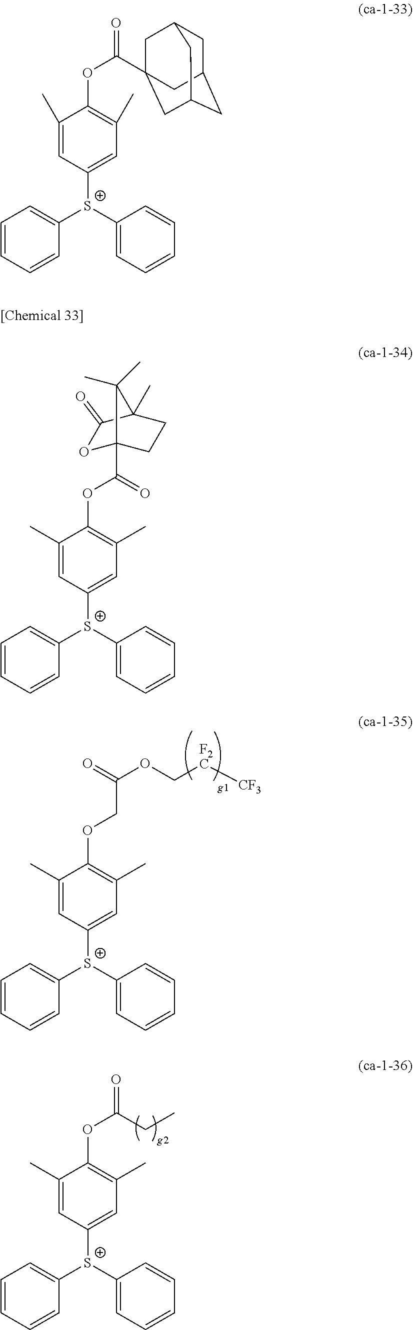

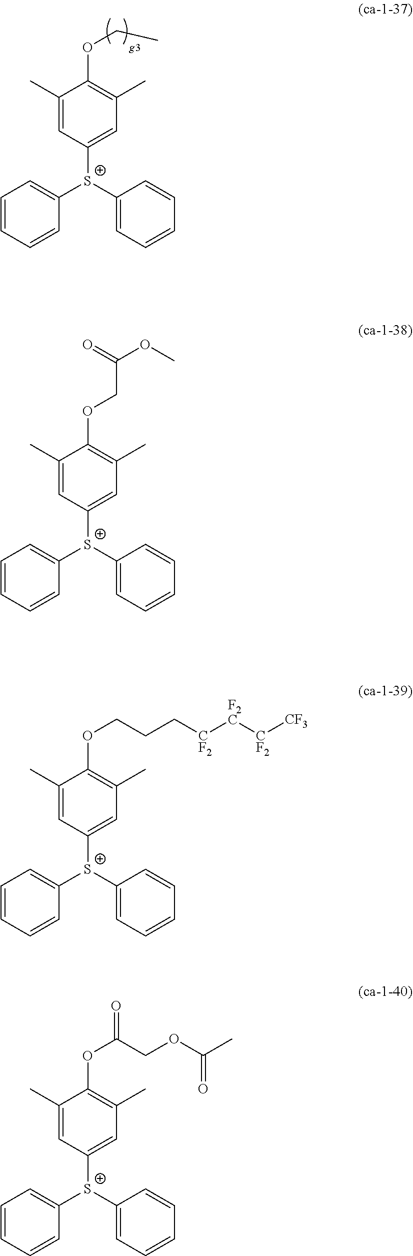

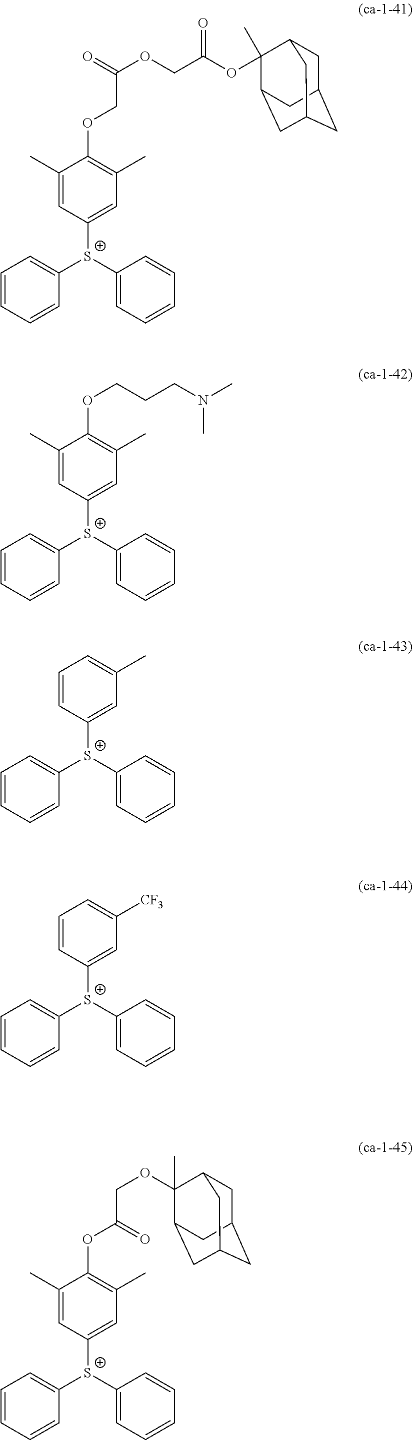

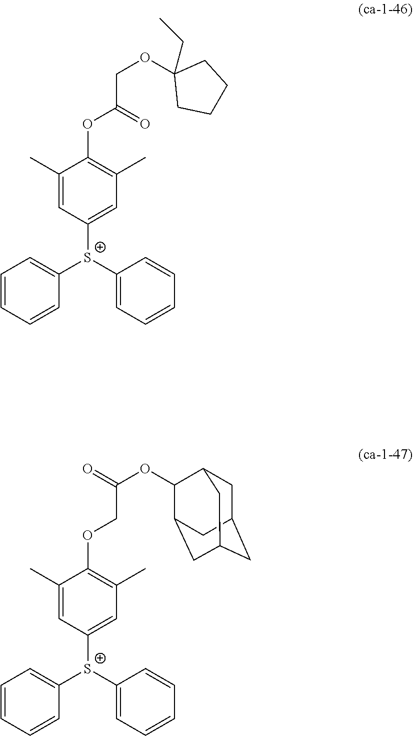

[In the formulae, g1, g2, and g3 represent the numbers of repetitions, g1 is an integer in a range of 1 to 5, g2 is an integer in a range of 0 to 20, and g3 is an integer in a range of 0 to 20.]

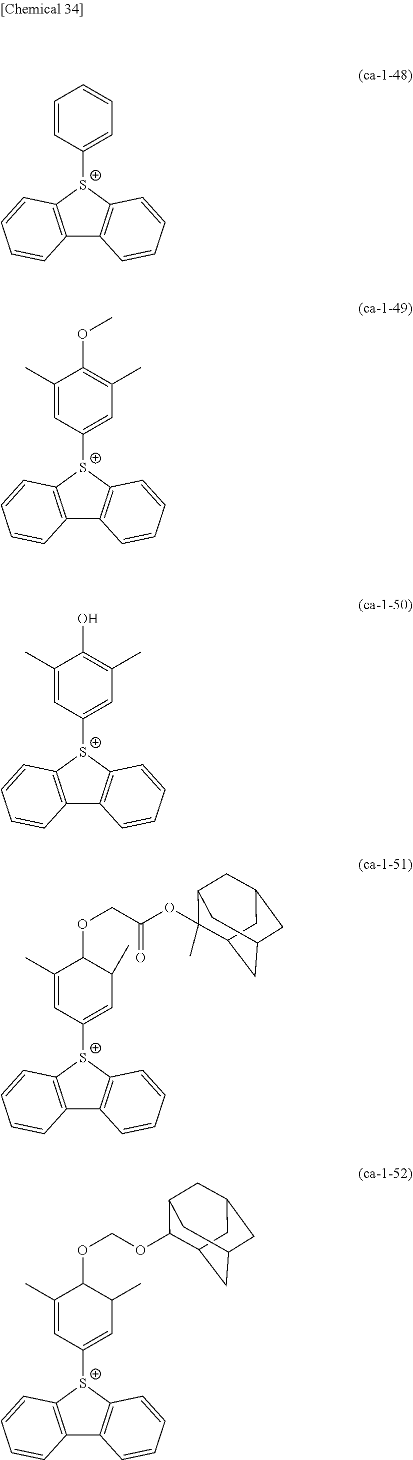 [SMILES: c1ccc(-[s+]2c3ccccc3c3ccccc32)cc1 ; COc1c(C)cc(-[s+]2c3ccccc3c3ccccc32)cc1C ; Cc1cc(-[s+]2c3ccccc3c3ccccc32)cc(C)c1O ; CC1=CC([s+]2c3ccccc3c3ccccc32)=CC(C)C1OCC(=O)OC1(C)C2CC3CC(C2)CC1C3 ; CC1=CC([s+]2c3ccccc3c3ccccc32)=CC(C)C1OCOC1C2CC3CC(C2)CC1C3]

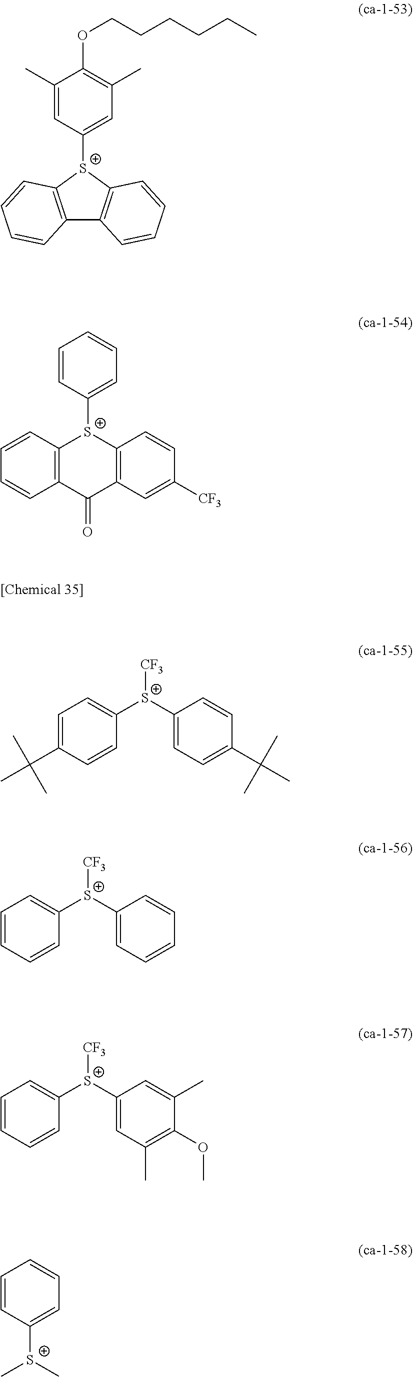

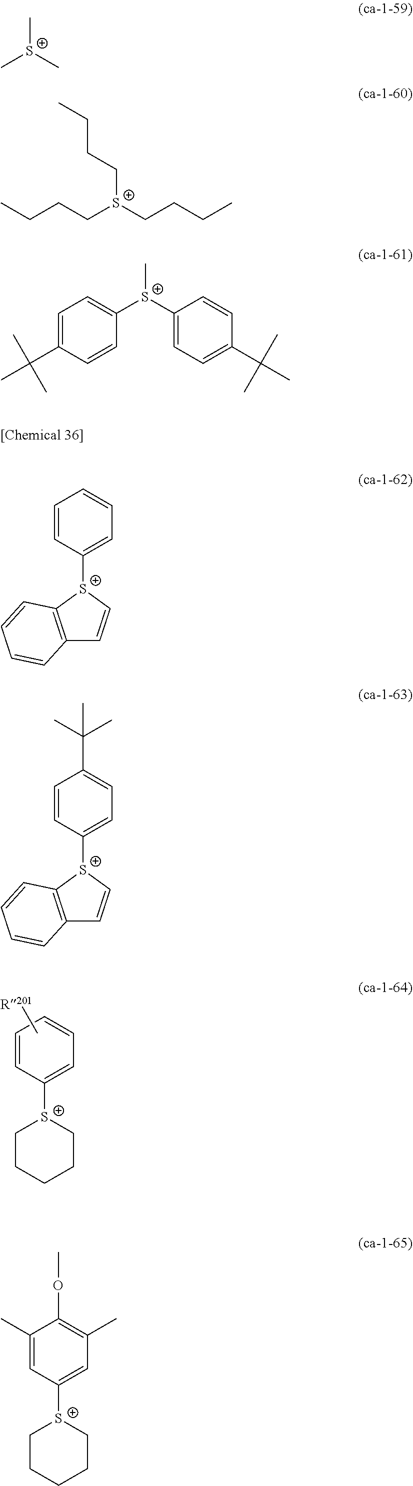

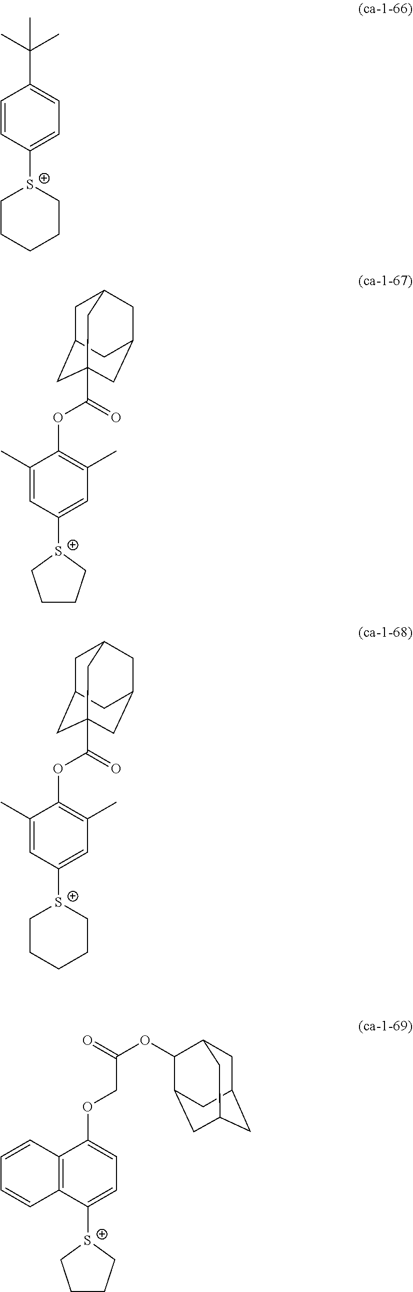 [SMILES: CC(C)(C)c1ccc([S+]2CCCCC2)cc1 ; Cc1cc([S+]2CCCC2)cc(C)c1OC(=O)C12CC3CC(CC(C3)C1)C2 ; Cc1cc([S+]2CCCCC2)cc(C)c1OC(=O)C12CC3CC(CC(C3)C1)C2 ; O=C(COc1ccc([S+]2CCCC2)c2ccccc12)OC1C2CC3CC(C2)CC1C3]

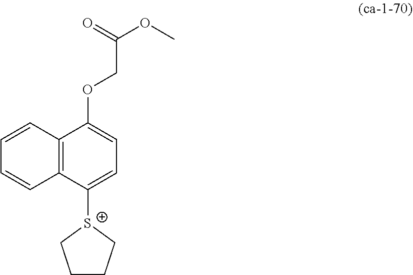 [SMILES: COC(=O)COc1ccc([S+]2CCCC2)c2ccccc12]

[In the formulae, R″²⁰¹ represents a hydrogen atom or a substituent, and examples of the substituent include the same ones as those exemplified as the substituent which may be contained in R²⁰¹ to R²⁰⁷ and R²¹⁰ to R²¹².]

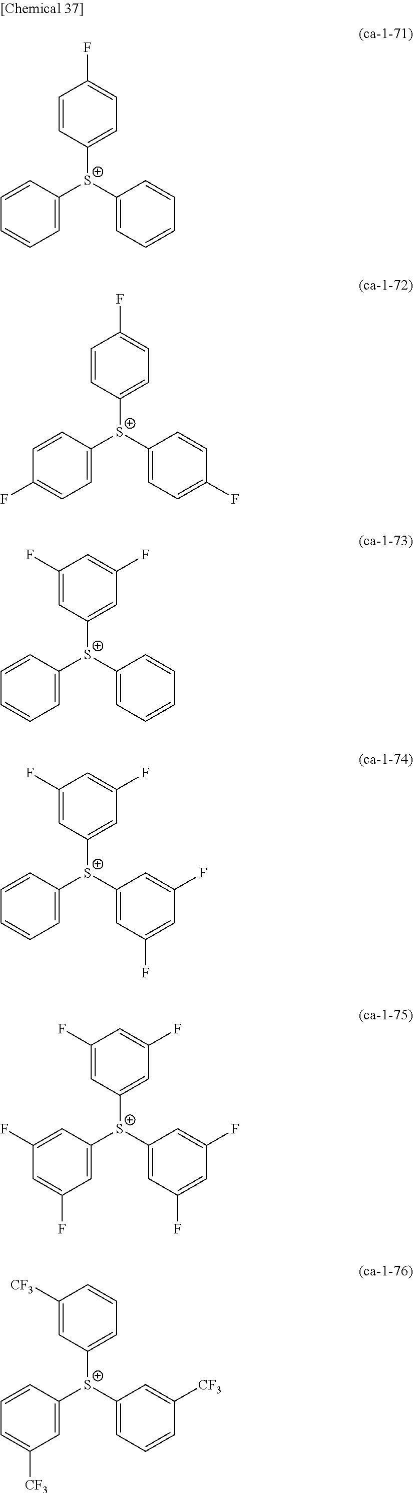 [SMILES: Fc1ccc([S+](c2ccccc2)c2ccccc2)cc1 ; Fc1ccc([S+](c2ccc(F)cc2)c2ccc(F)cc2)cc1 ; Fc1cc(F)cc([S+](c2ccccc2)c2ccccc2)c1 ; Fc1cc(F)cc([S+](c2ccccc2)c2cc(F)cc(F)c2)c1 ; Fc1cc(F)cc([S+](c2cc(F)cc(F)c2)c2cc(F)cc(F)c2)c1 ; FC(F)(F)c1cccc([S+](c2cccc(C(F)(F)F)c2)c2cccc(C(F)(F)F)c2)c1]

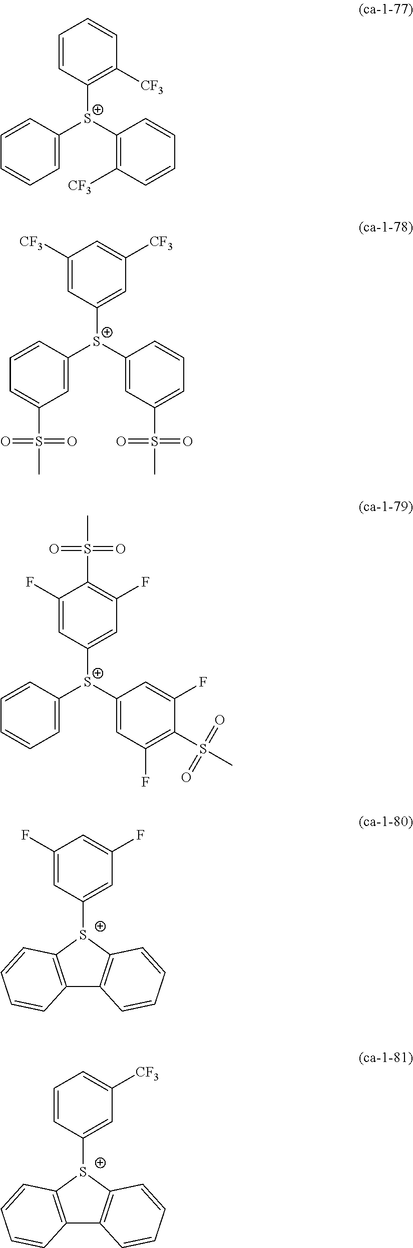 [SMILES: FC(F)(F)c1ccccc1[S+](c1ccccc1)c1ccccc1C(F)(F)F ; CS(=O)(=O)c1cccc([S+](c2cc(C(F)(F)F)cc(C(F)(F)F)c2)c2cccc(S(C)(=O)=O)c2)c1 ; CS(=O)(=O)c1c(F)cc([S+](c2ccccc2)c2cc(F)c(S(C)(=O)=O)c(F)c2)cc1F ; Fc1cc(F)cc(-[s+]2c3ccccc3c3ccccc32)c1 ; FC(F)(F)c1cccc(-[s+]2c3ccccc3c3ccccc32)c1]

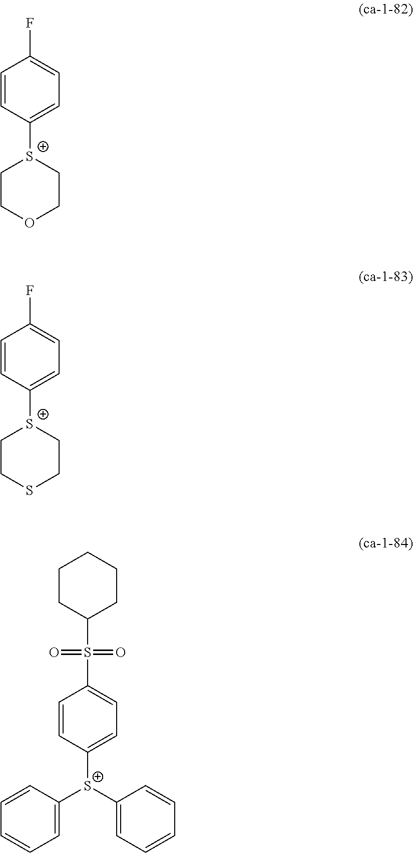 [SMILES: Fc1ccc([S+]2CCOCC2)cc1 ; Fc1ccc([S+]2CCSCC2)cc1 ; O=S(=O)(c1ccc([S+](c2ccccc2)c2ccccc2)cc1)C1CCCCC1]

Specific examples of the suitable cation represented by General Formula (ca-2) include a diphenyliodonium cation and a bis(4-tert-butylphenyl)iodonium cation.

Specific examples of the suitable cation represented by General Formula (ca-3) include cations each represented by General Formulae (ca-3-1) to (ca-3-6).

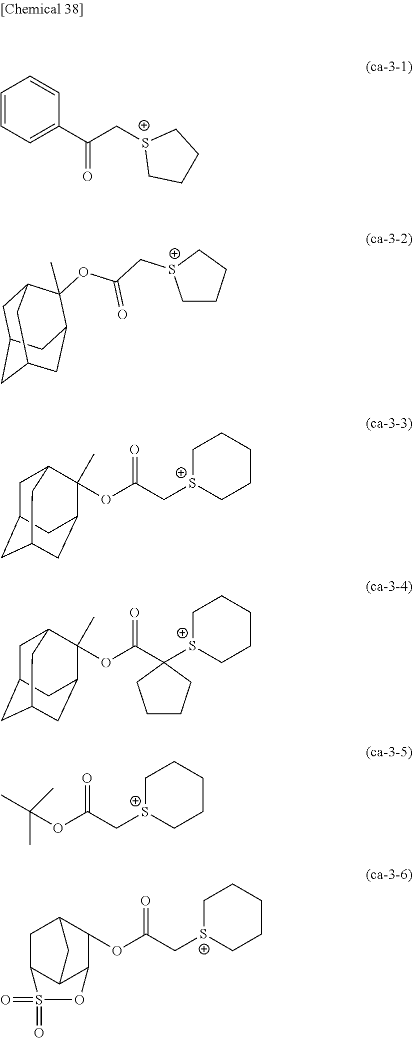

The onium cation as M^{m+} is preferably at least one selected from the group consisting of cations each represented by General Formulae (ca-1) to (ca-3), among which a cation represented by General Formula (ca-1) is more preferable. Among the above, a cation represented by General Formula (b0-ca) is still more preferable.

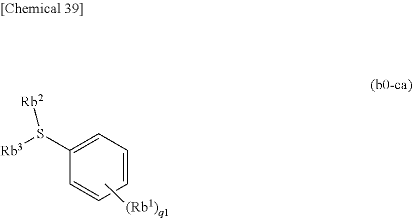

[In the formula, Rb¹ represents a fluorinated alkyl group or a fluorine atom. q1 represents an integer in a range of 1 to 5. Rb² and Rb³ each independently represent an aryl group, an alkyl group, or an alkenyl group, each of which may have a substituent. Rb² and Rb³ may be bonded to each other to form a ring together with a sulfur atom in the formula. Rb² or Rb³ may form a condensed ring together with a sulfur atom and a benzene ring in the formula.]

In General Formula (b0-ca), the fluorinated alkyl group as Rb¹ is preferably a linear or branched fluorinated alkyl group having 1 to 5 carbon atoms, more preferably a linear fluorinated alkyl group having 1 to 5 carbon atoms, and particularly preferably a trifluoromethyl group.

In General Formula (b0-ca), q1 represents an integer in a range of 1 to 5, preferably an integer in a range of 1 to 4, and more preferably 2 or 3.

In General Formula (b0-ca), Rb¹ is preferably bonded to the ortho-position or meta-position of the benzene ring from the viewpoint of photolysis efficiency.

In General Formula (b0-ca), Rb² and Rb³ are the same as R²⁰¹ to R²⁰³ in General Formula (ca-1).

In particular, from the viewpoint of increasing sensitivity, the suitable cation represented by General Formula (ca-1) preferably has, as a substituent, an electron-withdrawing group such as a fluorine atom, a fluorinated alkyl group, or a sulfonyl group and is, for example, particularly preferably a cation selected from the group consisting of cations each represented by Chemical Formulae (ca-1-44), (ca-1-71) to (ca-1-77), (ca-1-80), and (ca-1-81).

Carboxylic Acid Salt Represented by General Formula (b0-2)

In General Formula (b0-2), the organic group as R^{b20} is the same as the organic group as R^{b10} in General Formula (b0-1).

Preferred examples of the carboxylic acid salt include a carboxylic acid salt represented by General Formula (b0-2d).

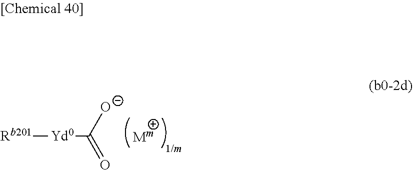

[In the formula, R^{b201} represents a cyclic group having an iodine atom, a chain-like alkyl group having an iodine atom, or a chain-like alkenyl group having an iodine atom. Yd⁰ represents a divalent linking group or a single bond. M^{m+} represents an m-valent onium cation. m represents an integer of 1 or more.]

In General Formula (b0-2d), R^{b201} represents a cyclic group having an iodine atom, a chain-like alkyl group having an iodine atom, or a chain-like alkenyl group having an iodine atom, and the description therefor is the same as that for R^{b101} in General Formula (b0-1b). Among the above, R^{b201} is preferably a cyclic group having an iodine atom, more preferably an aromatic hydrocarbon group having an iodine atom, and still more preferably a phenyl group having an iodine atom or a naphthyl group having an iodine atom.

Examples of the preferred R^{b201} include a group represented by General Formula (b0-r-1p). nb1 in General Formula (b0-r-1p) represents an integer in a range of 1 to 5, preferably an integer in a range of 1 to 3, more preferably 2 or 3, and still more preferably 2.

In General Formula (b0-2d), suitable examples of the divalent linking group as Yd⁰ include a divalent linking group containing an oxygen atom.

In a case where Yd⁰ represents a divalent linking group containing an oxygen atom, Yd⁰ may contain an atom other than the oxygen atom. Examples of the atom other than the oxygen atom include a carbon atom, a hydrogen atom, a sulfur atom, and a nitrogen atom.

Examples of the divalent linking group containing an oxygen atom include a non-hydrocarbon-based oxygen atom-containing linking group such as an oxygen atom (an ether bond; —O—), an ester bond (—C(═O)—O—), an oxycarbonyl group (—O—C(═O)—), an amide bond (—C(═O)—NH—), a carbonyl group (—C(═O)—), or a carbonate bond (—O—C(═O)—O—); a combination of the above-described non-hydrocarbon-based oxygen atom-containing linking group with an alkylene group; and a combination of a non-hydrocarbon-based oxygen atom-containing linking group with an arylene group. A sulfonyl group (—SO₂—) may be further linked to this combination. Examples of the arylene group include a phenylene group and a naphthylene group. The arylene group may have a substituent such as a halogen atom.

Among the above, Yd⁰ is preferably a single bond, a combination of the non-hydrocarbon-based oxygen atom-containing linking group with an alkylene group, or a combination of the non-hydrocarbon-based oxygen atom-containing linking group with an arylene group.

Hereinafter, specific examples of the anion moiety of the carboxylic acid salt, which is represented by General Formula (b0-2d), are shown.

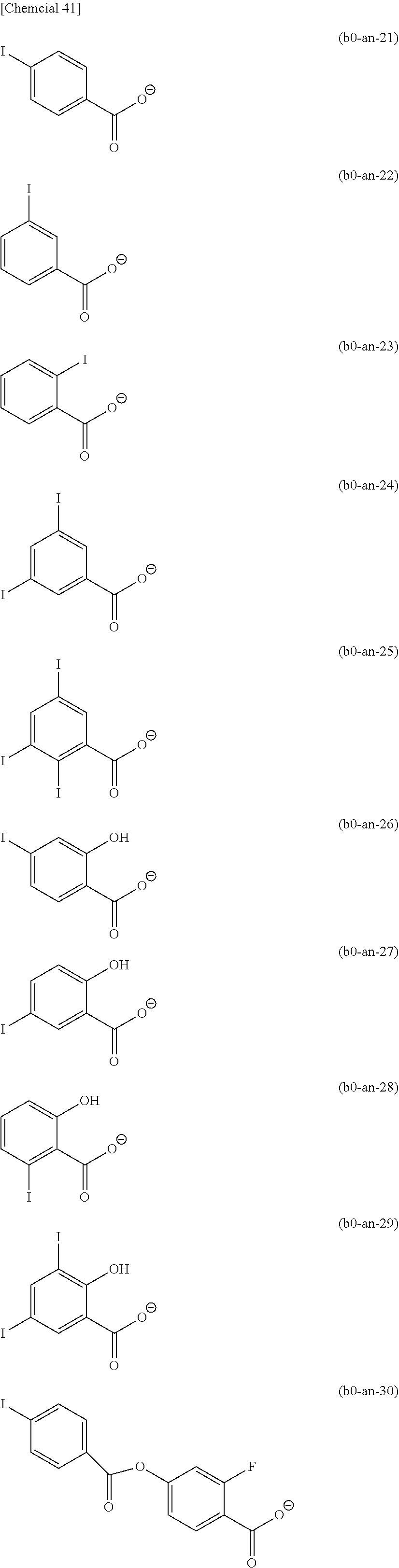

In General Formula (b0-2) and General Formula (b0-2d), M^{m+} represents an m-valent onium cation, and among the above, a sulfonium cation or an iodonium cation is more preferable. m represents an integer of 1 or more.

The onium cation as M^{m+} is preferably at least one selected from the group consisting of the above-described organic cations each represented by General Formulae (ca-1) to (ca-3), among which the cation represented by General Formula (ca-1) is more preferable. Among the above, the cation represented by General Formula (b0-ca) is still more preferable.

In the resist composition according to the present embodiment, the component (B0) may be used alone or in a combination of two or more kinds thereof.

As the component (B0), it is preferable that at least one onium salt selected from the group consisting of a sulfonic acid salt represented by General Formula (b0-1) and a carboxylic acid salt represented by General Formula (b0-2) is used, and it is more preferable that a sulfonic acid salt represented by General Formula (b0-1) and a carboxylic acid salt represented by General Formula (b0-2) are used in combination.

In particular, as described above, it is still more preferable that the sulfonic acid salt represented by General Formula (b0-1), which acts as the acid component, and the carboxylic acid salt represented by General Formula (b0-2), which acts as the base component, are used in combination.

In a case where a sulfonic acid salt represented by General Formula (b0-1) is used as the component (B0), the content of the sulfonic acid salt represented by General Formula (b0-1) in the resist composition according to the present embodiment is preferably 10 to 50 parts by mass, more preferably 10 to 40 parts by mass, and still more preferably 15 to 35 parts by mass, with respect to 100 parts by mass of the component (A).

In a case where the content of the sulfonic acid salt represented by General Formula (b0-1) is equal to or larger than the lower limit value of the above-described preferred range, the lithography characteristics such as sensitivity, a linewise roughness (LWR) reduction property, and a shape are further improved in the resist pattern formation. On the other hand, in a case where it is equal to or smaller than the upper limit value of the above-described preferred range, a homogeneous solution is easily obtained when each component of the resist composition is dissolved in an organic solvent, and the storage stability as a resist composition is further improved.

In a case where a carboxylic acid salt represented by General Formula (b0-2) is used as the component (B0), the content of the carboxylic acid salt represented by General Formula (b0-2) in the resist composition according to the present embodiment is preferably 10 to 60 parts by mass, more preferably 20 to 55 parts by mass, and still more preferably 30 to 55 parts by mass, with respect to 100 parts by mass of the component (A).

In a case where the content of the carboxylic acid salt represented by General Formula (b0-2) is equal to or larger than the lower limit value of the above-described preferred range, the lithography characteristics such as sensitivity, a linewise roughness (LWR) reduction property, and a shape are further improved in the resist pattern formation. On the other hand, in a case where it is equal to or smaller than the upper limit value of the above-described preferred range, a homogeneous solution is easily obtained when each component of the resist composition is dissolved in an organic solvent, and the storage stability as a resist composition is further improved.

<<Acid Generator Component Other than Component (B0)>

The resist composition according to the present embodiment may contain an acid generator component (hereinafter, referred to as a “component (B1)”) other than the above-described component (B0) as long as the effects of the present invention are not impaired.

The component (B1) is not particularly limited, and those which have been proposed so far as an acid generator for a chemical amplification-type resist composition or a photodecomposable base that loses acid diffusion controllability by being decomposed upon exposure can be used.

Examples of such a component (B1) are numerous and include onium salt-based acid generators such as iodonium salts and sulfonium salts; oxime sulfonate-based acid generators; diazomethane-based acid generators such as bisalkyl or bisaryl sulfonyl diazomethanes and poly(bis-sulfonyl)diazomethanes; nitrobenzyl sulfonate-based acid generators; iminosulfonate-based acid generators; and disulfonate-based acid generators.

<Other Components>

The resist composition according to the present embodiment may further contain other components in addition to the component (A) and the component (B) described above. Examples of the other components include a component (C), a component (D), a component (E), a component (F), and a component (S), which are described below.

<<Crosslinking Agent Component>>

In a case where the resist composition according to the present embodiment is a “negative-tone resist composition for an alkali developing process” that forms a negative-tone resist pattern in an alkali developing process or in a case where it is a “positive-tone resist composition for a solvent developing process” that forms a positive-tone resist pattern in a solvent developing process, the resist composition according to the present embodiment further contains a crosslinking agent component (hereinafter, also referred to as a “component (C)”) in addition to the component (A) and the component (B).

Examples of the component (C) include a melamine-based crosslinking agent, a urea-based crosslinking agent, an alkylene urea-based crosslinking agent, a glycoluril-based crosslinking agent, a phenol-based crosslinking agent, and an epoxy-based crosslinking agent.

It is noted that the term “lower” used below means having 1 to 5 carbon atoms.

Examples of the melamine-based crosslinking agent include a compound obtained by reacting melamine with formaldehyde to substitute a hydrogen atom of an amino group with a hydroxymethyl group; and a compound obtained by reacting melamine, formaldehyde, and a lower alcohol to substitute a hydrogen atom of an amino group with a lower alkoxymethyl group. Specific examples thereof include hexamethoxymethyl melamine, hexaethoxymethyl melamine, hexapropoxymethyl melamine, and hexabutoxybutyl melamine, among which hexamethoxymethyl melamine is preferable.

Examples of the urea-based crosslinking agent include a compound obtained by reacting urea with formaldehyde to substitute a hydrogen atom of an amino group with a hydroxymethyl group; and a compound obtained by reacting urea, formaldehyde, and a lower alcohol to substitute a hydrogen atom of an amino group with a lower alkoxymethyl group. Specific examples thereof include bismethoxymethyl urea, bisethoxymethyl urea, bispropoxymethyl urea, and bisbutoxymethyl urea, among which bismethoxymethyl urea is preferable.

Examples of the alkylene urea-based crosslinking agent include a compound represented by General Formula (CA-1).

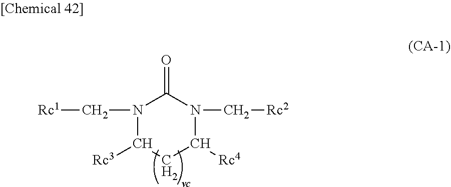

[In General Formula (CA-1), Rc¹ and Rc² each independently represent a hydroxyl group or a lower alkoxy group. Rc³ and Rc⁴ each independently represent a hydrogen atom, a hydroxyl group, or a lower alkoxy group. vc represents an integer in a range of 0 to 2.1

In a case of being a lower alkoxy group, Rc¹ and Rc² are preferably an alkoxy group having 1 to 4 carbon atoms and may be linear or branched. Rc¹ and Rc² may be the same or different from each other, where they are more preferably the same.

In a case of being a lower alkoxy group, Rc³ and Rc⁴ are preferably an alkoxy group having 1 to 4 carbon atoms and may be linear or branched. Rc³ and Rc may be the same or different from each other, where they are more preferably the same.

vc represents an integer in a range of 0 to 2 and is preferably 0 or 1.

In particular, the alkylene urea-based crosslinking agent is preferably a compound in which vc is 0 (an ethylene urea-based crosslinking agent) and/or a compound in which vc is 1 (a propylene urea-based crosslinking agent).

The compound represented by General Formula (CA-1) can be obtained by subjecting an alkylene urea to a condensation reaction with formalin or by subjecting the product of this reaction to a reaction with a lower alcohol.

Specific examples of the alkylene urea-based crosslinking agent include ethylene urea-based crosslinking agents such as mono- and/or dihydroxymethylated ethylene urea, mono- and/or dimethoxymethylated ethylene urea, mono- and/or diethoxymethylated ethylene urea, mono- and/or dipropoxymethylated ethylene urea, and mono- and/or dibutoxymethylated ethylene urea; propylene urea-based crosslinking agents such as mono- and/or dihydroxymethylated propylene urea, mono- and/or dimethoxymethylated propylene urea, mono- and/or diethoxymethylated propylene urea, mono- and/or dipropoxymethylated propylene urea, and mono- and/or dibutoxymethylated propylene urea; 1,3-di(methoxymethyl) 4,5-dihydroxy-2-imidazolidinone; and 1,3-di(methoxymethyl)-4,5-dimethoxy-2-imidazolidinone.

Examples of the glycoluril-based crosslinking agent include a glycoluril derivative having a substitution with one or both of a hydroxyalkyl group and an alkoxyalkyl group having 1 to 4 carbon atoms at the N-position. Such a glycoluril derivative can be obtained by subjecting glycoluril to a condensation reaction with formalin or by subjecting the product of this reaction to a reaction with a lower alcohol. Specific examples of the glycoluril-based crosslinking agents include mono-, di-tri-, and/or tetra-hydroxymethylated glycoluril; mono-, di-, tri-, and/or tetra-methoxymethylated glycoluril; mono-, di-, tri-, and/or tetra-ethoxymethylated glycoluril; mono-, di-, tri-, and/or tetra-propoxymethylated glycoluril; and mono-, di-, tri-, and/or tetra-butoxymethylated glycoluril.

The phenol-based crosslinking agent is not particularly limited as long as it is a compound having a plurality of phenolic core structures in the same molecule, and any phenol-based crosslinking agent can be selected and used. In a case where a plurality of phenolic core structures is contained, crosslinking reactivity is improved.

The number of phenolic core structures is preferably 2 to 5, more preferably 2 to 4, and still more preferably 2 or 3.

Suitable phenol-based crosslinking agents are shown below.

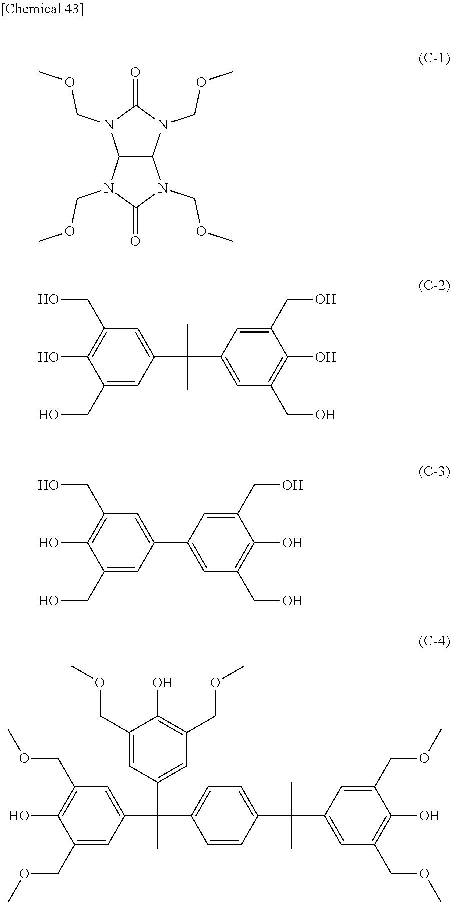

The epoxy-based crosslinking agent is not particularly limited as long as it has an epoxy group, and any epoxy-based crosslinking agent can be selected and used. Among the above, the one having two or more epoxy groups is preferable. In a case where two or more epoxy groups are contained, crosslinking reactivity is improved.

The number of epoxy groups is preferably 2 or more, more preferably 2 to 4, and most preferably 2.

Suitable epoxy-based crosslinking agents are shown below.

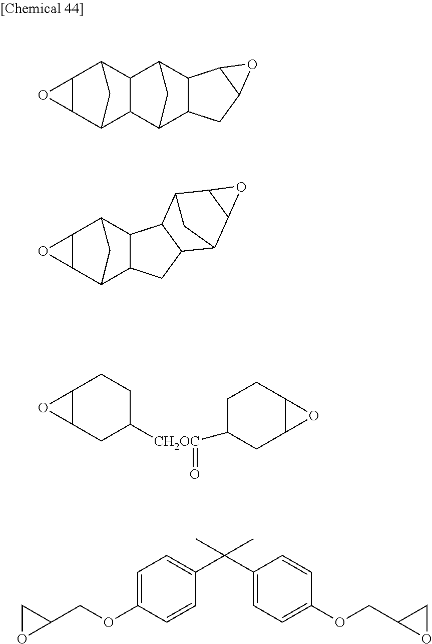

Among them, the component (C) is preferably a compound having an alkylol group such as a methylol group, or an alkoxyalkyl group such as a methoxymethyl group, more preferably a crosslinking agent selected from the group consisting of a glycoluril-based crosslinking agent and a phenol-based crosslinking agent, and still more preferably a glycoluril-based crosslinking agent.

In the resist composition according to the present embodiment, the component (C) may be used alone or in a combination of two or more kinds thereof.

In the resist composition according to the present embodiment, the content of the component (C) is preferably in a range of 1 to 50 parts by mass, more preferably in a range of 3 to 30 parts by mass, still more preferably in a range of 5 to 20 parts by mass, and most preferably in a range of 5 to 15 parts by mass, with respect to 100 parts by mass of the component (A).

In a case where the content of the component (C) is equal to or larger than the lower limit value of the above-described preferred range, the crosslinking proceeds sufficiently to facilitate obtaining a dissolution contrast, and thus resolution performance and lithography characteristics are further improved. In addition, a favorable resist pattern with less swelling can be obtained. In addition, in a case where the content thereof is equal to or smaller than the upper limit value of the above-described preferred range, the storage stability of the resist composition is favorable, and the temporal deterioration of the sensitivity is easily suppressed.

<<Base Component>>

In addition to the component (A) and component (B), or the component (A), the component (B), and component (C), which are described above, the resist composition according to the present embodiment may further contain a base component (D) (hereinafter, referred to as a “component (D)”) which controls the diffusion of the acid generated from the component (B) upon exposure.

Such a component (D) acts as a quencher (an acid diffusion controlling agent) that traps acid that is generated in the resist composition upon exposure.

Examples of the component (D) here include a nitrogen-containing organic compound (D2) (hereinafter, referred to as a “component (D2)”) which does not correspond to the above-described component (B0) and photodecomposable base.

As the component (D2), any known compound may be used. Among the above, aliphatic amines are preferable, and among the aliphatic amines, in particular, a secondary aliphatic amine or a tertiary aliphatic amine is more preferable.

It is preferable that the aliphatic amine is an amine having one or more aliphatic groups, where the aliphatic group has 1 to 12 carbon atoms.

Examples of these aliphatic amines include an amine in which at least one hydrogen atom of ammonia (NH₃) has been substituted with an alkyl group or hydroxyalkyl group having 12 or less carbon atoms (alkyl amines or alkyl alcohol amines) and a cyclic amine.

Specific examples of the alkyl amine and the alkyl alcohol amine include monoalkyl amines such as n-hexyl amine, n-heptyl amine, n-octyl amine, n-nonyl amine, and n-decyl amine; dialkyl amines such as diethyl amine, di-n-propyl amine, di-n-heptyl amine, di-n-octyl amine, and dicyclohexyl amine; trialkyl amines such as trimethyl amine, triethyl amine, tri-n-propyl amine, tri-n-butyl amine, tri-n-pentyl amine, tri-n-hexyl amine, tri-n-heptyl amine, tri-n-octyl amine, tri-n-nonyl amine, tri-n-decyl amine, and tri-n-dodecyl amine; and alkyl alcohol amines such as diethanol amine, triethanol amine, diisopropanol amine, triisopropanol amine, di-n-octanol amine, and tri-n-octanol amine. Among these, trialkyl amines of 5 to 10 carbon atoms are preferable, and tri-n-pentyl amine and tri-n-octyl amine are particularly preferable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine and piperazine.

The aliphatic polycyclic amine preferably has 6 to 10 carbon atoms, and specific examples thereof include 1, 5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine and triethanol amine triacetate, and triethanol amine triacetate is preferable.

In addition, as the component (D2), an aromatic amine may be used.

Examples of the aromatic amine include 4-dimethylaminopyridine, pyrrole, indole, pyrazole, imidazole, and derivatives thereof, tribenzylamine, 2,6-diisopropylaniline, N-tert-butoxycarbonylpyrrolidine, and 2,6-di-tert-butylpyridine.

The component (D2) may be used alone or in a combination of two or more kinds thereof.

In a case where the resist composition contains the component (D2), the content of the component (D2) in the resist composition is generally in a range of 0.01 to 5 parts by mass with respect to 100 parts by mass of the component (A). In a case of setting the content within the above-described range, the resist pattern shape, the post-exposure temporal stability, and the like are improved.

<<At Least One Compound (E) Selected from the Group Consisting of Organic Carboxylic Acid, Phosphorus Oxo Acid, and Derivatives Thereof>>

For the intended purpose of preventing any deterioration in sensitivity and improving the resist pattern shape and the post-exposure temporal stability, the resist composition according to the present embodiment may contain, as an optional component, at least one compound (E) (hereinafter referred to as a “component (E)”) selected from the group consisting of an organic carboxylic acid, and a phosphorus oxo acid and a derivative thereof.

Examples of suitable organic carboxylic acids include acetic acid, malonic acid, citric acid, malic acid, succinic acid, benzoic acid, and salicylic acid.

Examples of the phosphorus oxo acid include phosphoric acid, phosphonic acid, and phosphinic acid. Among these, phosphonic acid is particularly preferable.

Examples of the phosphorus oxo acid derivative include an ester obtained by substituting a hydrogen atom in the above-described oxo acid with a hydrocarbon group. Examples of the hydrocarbon group include an alkyl group having 1 to 5 carbon atoms and an aryl group having 6 to 15 carbon atoms.

Examples of the phosphoric acid derivative include a phosphoric acid ester such as di-n-butyl phosphate or diphenyl phosphate.

Examples of the phosphonic acid derivative include phosphonic acid esters such as dimethyl phosphonate, di-n-butyl phosphonate, phenylphosphonic acid, diphenyl phosphonate, and dibenzyl phosphonate.

Examples of the phosphinic acid derivative include phosphinic acid esters and phenylphosphinic acid.

In the resist composition according to the present embodiment, one kind of the component (E) may be used alone, or two or more kinds thereof may be used in combination.

In a case where the resist composition contains the component (E), the content of the component (E) is generally in a range of 0.01 to 10 parts by mass with respect to 100 parts by mass of the component (A).

<<Fluorine Additive Component (F)>>

The resist composition according to the present embodiment may contain a fluorine additive component (hereinafter, referred to as a “component (F)”) as a hydrophobic resin. The component (F) is used to impart water repellency to the resist film and used as a resin different from the component (A), whereby the lithography characteristics can be improved.

As the component (F), a fluorine-containing polymeric compound described in Japanese Unexamined Patent Application, First Publication No. 2010-002870, Japanese Unexamined Patent Application, First Publication No. 2010-032994, Japanese Unexamined Patent Application, First Publication No. 2010-277043, Japanese Unexamined Patent Application, First Publication No. 2011-13569, and Japanese Unexamined Patent Application, First Publication No. 2011-128226 can be mentioned.

Specific examples of the component (F) include polymers having a constitutional unit (f1) represented by General Formula (f1-1) shown below. This polymer is preferably a polymer (a homopolymer) consisting only of a constitutional unit (f1) represented by General Formula (f1-1); a copolymer of the constitutional unit (f1) and the following constitutional unit (a1); a copolymer of the constitutional unit (f1), a constitutional unit derived from acrylic acid or methacrylic acid, and the following constitutional unit (a1), and more preferably a copolymer of the constitutional unit (f1) and the following constitutional unit (a1).

The constitutional unit (a1) to be copolymerized with the constitutional unit (f1) is preferably a constitutional unit derived from 1-ethyl-1-cyclooctyl (meth)acrylate or a constitutional unit derived from 1-methyl-1-adamantyl (meth)acrylate, and more preferably a constitutional unit derived from 1-ethyl-1-cyclooctyl (meth)acrylate.

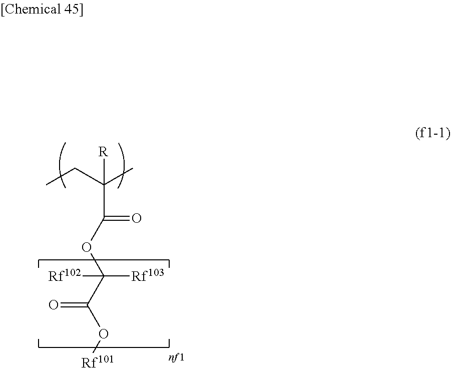

[In the formula, R has the same definition as described above. Rf¹⁰² and Rf¹⁰³ each independently represent a hydrogen atom, a halogen atom, an alkyl group having 1 to 5 carbon atoms, or a halogenated alkyl group having 1 to 5 carbon atoms, and Rf¹⁰² and Rf¹⁰³ may be the same as or different from each other. nf¹ represents an integer in a range of 0 to 5 and Rf¹⁰¹ represents an organic group containing a fluorine atom.]

In General Formula (f1-1), examples of R bonded to the carbon atom at the α-position include an alkyl group having 1 to 5 carbon atoms, a halogenated alkyl group having 1 to 5 carbon atoms, or a hydrogen atom. R is preferably a hydrogen atom or a methyl group.

In General Formula (f1-1), the halogen atom of Rf¹⁰² and Rf¹⁰³ is preferably a fluorine atom. The alkyl group having 1 to 5 carbon atoms as Rf¹⁰² and Rf¹⁰³ is preferably a methyl group or an ethyl group. Specific examples of the halogenated alkyl group having 1 to 5 carbon atoms as Rf¹⁰² and Rf¹⁰³ include groups in which part or all of hydrogen atoms of the above-described alkyl groups of 1 to 5 carbon atoms have been substituted with a halogen atom. The halogen atom is preferably a fluorine atom.

Among the above, Rf¹⁰² and Rf¹⁰³ are preferably a hydrogen atom, a fluorine atom, or an alkyl group having 1 to 5 carbon atoms, more preferably a hydrogen atom, a fluorine atom, a methyl group, or an ethyl group, and still more preferably a hydrogen atom.

In General Formula (f1-1), nf¹ represents an integer in a range of 0 to 5, preferably an integer in a range of 0 to 3, and more preferably an integer of 1 or 2.

In General Formula (f1-1), Rf¹⁰¹ represents an organic group containing a fluorine atom and is preferably a hydrocarbon group containing a fluorine atom.

The hydrocarbon group containing a fluorine atom may be linear, branched, or cyclic, and preferably has 1 to 20 carbon atoms, more preferably 1 to 15 carbon atoms, and particularly preferably 1 to 10 carbon atoms.

In addition, in the hydrocarbon group containing a fluorine atom, 25% or more of the hydrogen atoms in the hydrocarbon group are preferably fluorinated, more preferably 50% or more are fluorinated, and particularly preferably 60% or more are fluorinated since the hydrophobicity of the resist film during immersion exposure increases.

Among them, Rf¹⁰¹ is more preferably a fluorinated hydrocarbon group having 1 to 6 carbon atoms, and particularly preferably a trifluoromethyl group, —CH₂—CF₃, —CH₂—CF₂—CF₃, —CH(CF₃)₂, —CH₂—CH₂—CF₃, or —CH₂—CH₂—CF₂—CF₂—CF₂—CF₃.

The weight average molecular weight (Mw) (in terms of the polystyrene equivalent value determined by gel permeation chromatography) of the component (F) is preferably in a range of 1,000 to 50,000, more preferably in a range of 5,000 to 40,000, and most preferably in a range of 10,000 to 30,000. In a case where the weight average molecular weight is equal to or smaller than the upper limit value of this range, the resist composition exhibits sufficient solubility in a resist solvent to be used as a resist. On the other hand, in a case where the weight average molecular weight is equal to or larger than the lower limit value of this range, the water repellency of the resist film is excellent.

Further, the molecular weight polydispersity (Mw/Mn) of the component (F) is preferably in a range of 1.0 to 5.0, more preferably in a range of 1.0 to 3.0, and most preferably in a range of 1.0 to 2.5.

In the resist composition according to the present embodiment, the component (F) may be used alone or in a combination of two or more kinds thereof.

In a case where the resist composition contains the component (F), the content of the component (F) in the resist composition is preferably in a range of 0.5 to 10 parts by mass and more preferably in a range of 1 to 10 parts by mass with respect to 100 parts by mass of the component (A).

<<Organic Solvent Component (S)>>

The resist composition according to the present embodiment may be produced by dissolving the resist materials in an organic solvent component (hereinafter, referred to as a “component (S)”).

In the resist composition according to the present embodiment, the component (S) may be used alone or as a mixed solvent of two or more kinds thereof. Among these, propylene glycol monomethyl ether acetate (PGMEA), propylene glycol monomethyl ether, γ-butyrolactone, ethyl lactate (EL), or cyclohexanone is preferable.

In addition, a mixed solvent obtained by mixing PGMEA with a polar solvent is also preferable as the component (S). The blending ratio (mass ratio) may be appropriately determined in consideration of the compatibility between PGMEA and the polar solvent.

In addition, the component (S) is also preferably a mixed solvent of at least one selected from PGMEA and EL and γ-butyrolactone. In this case, as the mixing ratio, the mass ratio of the former to the latter is preferably in a range of 70:30 to 95:5.

The amount of the component (S) to be used is not particularly limited and is appropriately set, depending on a thickness of a film to be coated, to a concentration at which the component (S) can be applied onto a substrate or the like.

In the resist composition according to the present embodiment, the solid content concentration of the resist composition is preferably in a range of 0.1% to 10% by mass, more preferably in a range of 0.2% to 5% by mass, and still more preferably in a range of 0.3% to 2% by mass.

In addition, in the resist composition according to the present embodiment, the content proportion of the silicon-containing resin (A) in the solid content of the resist composition is preferably 40% by mass or more, more preferably 45% by mass or more, still more preferably in a range of 45% to 70% by mass, particularly preferably in a range of 50% to 65% by mass, and most preferably in a range of 50% to 60% by mass.

In a case where the content proportion of the component (A) in the solid content of the resist composition is within the above-described preferred range, the etching resistance is easily enhanced.

It is noted that the term “the solid content of the resist composition” shall refer to a content consisting of components constituting the resist composition, excluding the organic solvent component (S).

In addition, in the resist composition of the present embodiment, the content proportion of the silicon (Si) in the solid content of the resist composition is preferably 5% by mass or more, more preferably in a range of 5% to 20% by mass, and still more preferably in a range of 5% to 15% by mass.

In a case where the content proportion of the silicon (Si) in the solid content of the resist composition is equal to or larger than the lower limit value of the above-described preferred range, etching resistance is easily increased, whereas in a case where it is equal to or smaller than the upper limit value of the above-described preferred range, a resist pattern having favorable lithography characteristics is easily formed.

As desired, other miscible additives can also be added to the resist composition according to the present embodiment. For example, for improving the performance of the resist film, an additive resin, a dissolution inhibitor, a plasticizer, a stabilizer, a colorant, a halation prevention agent, and a dye can be appropriately contained therein.

For example, in the resist composition according to the present embodiment, a hydroxystyrene resin, a resin that is a novolak resin and does not contain silicon, or the like may be used in combination, in addition to the component (A0) described above. In the hydroxystyrene resin, the hydrogen atom at the α-position of hydroxystyrene may be substituted with a substituent. Examples of this substituent include an alkyl group and a halogenated alkyl group.

After dissolving the resist material in the component (S), the resist composition according to the present embodiment may be subjected to the removal of impurities and the like by using a porous polyimide membrane, a porous polyamideimide membrane, or the like. For example, the resist composition may be filtered using a filter consisting of a porous polyimide membrane, a filter consisting of a porous polyamideimide membrane, or a filter consisting of a porous polyimide membrane and a porous polyamideimide membrane. Examples of the porous polyimide membrane and the porous polyamideimide membrane include those described in Japanese Unexamined Patent Application, First Publication No. 2016-155121.

In the resist composition according to the present embodiment described above, the silicon-containing resin (the component (A)) is used in combination with the onium salt (the component (B0)) consisting of an anion moiety having an iodine atom and a cation moiety. In particular, since the component (B0) in which an iodine atom is introduced into the anion moiety is employed, sensitivity is enhanced in the formation of the resist pattern. In the resist composition according to the present embodiment, the synergistic action of the component (B0) and the components (A0) makes it possible to achieve high sensitivity and form a further fine-sized pattern in a favorable shape. In addition, since a silicon-containing resin is used as a base material component (a base resin) for such a resist composition, dry etching resistance is also excellent.

Such a resist composition has excellent fine resolution in EUV lithography. In addition, it is possible to form a fine-sized pattern having a line width of ten and several nm in a favorable shape while suppressing roughness, which has been difficult in the related art.

Such a resist composition is a resist material that makes it possible to form a silicon-containing pattern, for example, having a fine line width and reduced roughness, and that can be suitably used in the microfabrication in EUV lithography.

(Resist Pattern Forming Method)

A resist pattern forming method according to the second aspect according to the present invention is a method including a step (i) of forming a resist film on a support using the resist composition according to the first aspect of the present invention described above, a step (ii) of exposing the resist film, and a step (iii) of developing the exposed resist film to form a resist pattern.

Examples of one embodiment of such a resist pattern forming method include a resist pattern forming method carried out as described below.

Step (i):

First, the resist composition of the above-described embodiment is applied onto a support with a spinner or the like, and a baking (post-apply baking (PAB)) treatment is carried out, for example, at a temperature condition in a range of 80° C. to 150° C. for 40 to 120 seconds, preferably for 60 to 90 seconds to form a resist film.

Step (ii):

The selective exposure is carried out on the resist film, for example, by the exposure through a mask (mask pattern) having a predetermined pattern formed on the mask by using an exposure apparatus such as a KrF exposure apparatus, an ArF exposure apparatus, an electron beam drawing apparatus, or an EUV exposure apparatus, or direct irradiation of the resist film for drawing with an electron beam without using a mask pattern.

After the above exposure, a baking (post-exposure baking (PEB)) treatment is carried out, for example, under the temperature condition in a range of 80° C. 150° C. for 40 to 120 seconds and preferably 60 to 90 seconds.

Step (iii):

Next, the exposed resist film is subjected to a developing treatment. The developing treatment is carried out using an alkali developing solution in a case of an alkali developing process, and a developing solution containing an organic solvent (organic developing solution) in a case of a solvent developing process.

After the developing treatment, it is preferable to conduct a rinse treatment. As the rinse treatment, water rinsing using pure water is preferable in a case of an alkali developing process, and rinsing using a rinse liquid containing an organic solvent is preferable in a case of a solvent developing process.

In a case of a solvent developing process, after the developing treatment or the rinse treatment, the developing solution or the rinse liquid remaining on the pattern may be removed by a treatment using a supercritical fluid.

After the developing treatment or the rinse treatment, drying is conducted. As desired, baking treatment (post-baking) can be carried out following the developing treatment.

The support is not specifically limited and a known support in the related art can be used. For example, substrates for electronic components, and such substrates having a predetermined wiring pattern formed thereon can be used. Specific examples of the material of the substrate include metals such as silicon wafer, copper, chromium, iron and aluminum; and glass. Suitable materials for the wiring pattern include copper, aluminum, nickel, and gold.

In addition, as the support, any support having the above-described substrate on which an inorganic and/or organic film is provided may be used. Examples of the inorganic film include an inorganic antireflection film (an inorganic BARC). Examples of the organic film include an organic antireflection film (organic BARC) and an organic film such as a lower-layer organic film used in a multilayer resist method.

Here, the multilayer resist method is a method in which at least one layer of an organic film (lower-layer organic film) and at least one layer of a resist film (upper-layer resist film) are provided on a substrate, and a resist pattern formed on the upper-layer resist film is used as a mask to conduct patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is basically classified into a method in which a double-layer structure consisting of an upper-layer resist film and a lower-layer organic film is formed (double-layer resist method), and a method in which a multilayer structure having at least three layers consisting of an upper-layer resist film, a lower-layer organic film and at least one intermediate layer (thin metal film or the like) provided between the upper-layer resist film and the lower-layer organic film (triple-layer resist method).

The wavelength to be used for exposure is not particularly limited, and the exposure can be carried out using radiation such as an ArF excimer laser, a KrF excimer laser, an F₂ excimer laser, an extreme ultraviolet ray (EUV), a vacuum ultraviolet ray (VUV), an electron beam (EB), an X-ray, or a soft X-ray.

The exposure method for a resist film may be a general exposure (dry exposure) carried out in air or an inert gas such as nitrogen, or liquid immersion lithography.

The liquid immersion lithography is an exposure method in which the region between the resist film and the lens at the lowermost position of the exposure apparatus is pre-filled with a solvent (liquid immersion medium) that has a larger refractive index than the refractive index of air, and the exposure (immersion exposure) is carried out in this state.

As the liquid immersion medium, a solvent that exhibits a refractive index larger than the refractive index of air but smaller than the refractive index of the resist film to be exposed is preferable. The refractive index of the solvent is not particularly limited as long as it is in the above-described range.

Examples of the solvent which exhibits a refractive index that is larger than the refractive index of air but smaller than the refractive index of the resist film include water, a fluorine-based inert liquid, a silicon-based solvent, and a hydrocarbon-based solvent.

Specific examples of the fluorine-based inert liquids include liquids containing a fluorine-based compound such as C₃HCl₂F₅, C₄F₉OCH₃, C₄F₉OC₂H₅, or C₅H₃F₇ as the main component, and the boiling point is preferably in a range of 700 to 180° C. and more preferably in a range of 800 to 160° C. A fluorine-based inert liquid having a boiling point in the above-described range is advantageous in that removing the medium used in the liquid immersion after the exposure can be preferably carried out by a simple method.

The fluorine-based inert liquid is particularly preferably a perfluoroalkyl compound in which all of the hydrogen atoms of the alkyl group are substituted with a fluorine atom. Specific examples of these perfluoroalkyl compounds include perfluoroalkyl ether compounds and perfluoroalkyl amine compounds.

Further, specifically, examples of the perfluoroalkyl ether compound include perfluoro(2-butyl-tetrahydrofuran) (boiling point: 102° C.), and examples of the perfluoroalkyl amine compound include perfluorotributyl amine (boiling point: 174° C.).

As the liquid immersion medium, water is preferable in terms of cost, safety, environment, and versatility.

Examples of the alkali developing solution used for a developing treatment in an alkali developing process include a 0.1% to 10% by mass aqueous solution of tetramethylammonium hydroxide (TMAH).

As the organic solvent contained in the organic developing solution, which is used for a developing treatment in a solvent developing process, any one of the conventionally known organic solvents capable of dissolving the component (A) (component (A) prior to exposure) can be appropriately selected from the conventionally known organic solvents. Specific examples of the organic solvent include polar solvents such as a ketone-based solvent, an ester-based solvent, an alcohol-based solvent, a nitrile-based solvent, an amide-based solvent, an ether-based solvent, and a hydrocarbon-based solvent.

A ketone-based solvent is an organic solvent containing C—C(═O)—C in the structure thereof. An ester-based solvent is an organic solvent containing C—C(═O)—O—C in the structure thereof. An alcohol-based solvent is an organic solvent containing an alcoholic hydroxyl group in the structure thereof. The term “alcoholic hydroxyl group” indicates a hydroxyl group bonded to a carbon atom of an aliphatic hydrocarbon group. A nitrile-based solvent is an organic solvent containing a nitrile group in the structure thereof. An amide-based solvent is an organic solvent containing an amide group in the structure thereof. An ether-based solvent is an organic solvent containing C—O—C in the structure thereof.

Some organic solvents have a plurality of the functional groups which characterize the above-described solvents in the structure thereof. In such a case, the organic solvent can be classified as any type of solvent having a characteristic functional group. For example, diethylene glycol monomethyl ether can be classified as an alcohol-based solvent or an ether-based solvent.

A hydrocarbon-based solvent consists of a hydrocarbon which may be halogenated and does not have any substituent other than a halogen atom. The halogen atom is preferably a fluorine atom.

Among the above, the organic solvent contained in the organic developing solution is preferably a polar solvent and more preferably a ketone-based solvent, an ester-based solvent, or a nitrile-based solvent.

Examples of the ketone-based solvent include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, propylene carbonate, γ-butyrolactone, and methylamyl ketone (2-heptanone). Among these examples, the ketone-based solvent is preferably methylamyl ketone (2-heptanone).

Examples of the ester-based solvent include methyl acetate, butyl acetate, ethyl acetate, isopropyl acetate, amyl acetate, isoamyl acetate, ethyl methoxyacetate, ethyl ethoxyacetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these, the ester-based solvent is preferably butyl acetate.

Examples of the nitrile-based solvent include acetonitrile, propionitrile, valeronitrile, and butyronitrile.

As desired, the organic developing solution may have a conventionally known additive blended. Examples of the additive include surfactants. The surfactant is not particularly limited; however, for example, an ionic or non-ionic fluorine-based and/or a silicon-based surfactant can be used.

The developing treatment can be carried out by a conventionally known developing method. Examples thereof include a method in which the support is immersed in the developing solution for a predetermined time (a dip method), a method in which the developing solution is cast upon the surface of the support by surface tension and maintained for a predetermined time (a puddle method), a method in which the developing solution is sprayed onto the surface of the support (spray method), and a method in which a developing solution is continuously ejected from a developing solution ejecting nozzle and applied onto a support which is scanned at a constant rate while being rotated at a constant rate (dynamic dispense method).

As the organic solvent contained in the rinse liquid used in the rinse treatment after the developing treatment in a case of a solvent developing process, for example, an organic solvent hardly dissolving the resist pattern can be appropriately selected and used, among the organic solvents mentioned as organic solvents that are used for the organic developing solution. In general, at least one kind of solvent selected from a hydrocarbon-based solvent, a ketone-based solvent, an ester-based solvent, an alcohol-based solvent, an amide-based solvent, and an ether-based solvent is used.

As the organic solvent, one kind of solvent may be used alone, or two or more kinds of solvents may be used in combination. In addition, an organic solvent other than the above-described examples or water may be mixed thereto.

The rinse treatment using a rinse liquid (washing treatment) can be carried out by a conventionally known rinse method. Examples of the rinse treatment method include a method in which the rinse liquid is continuously ejected and applied onto the support while rotating it at a constant rate (rotational coating method), a method in which the support is immersed in the rinse liquid for a predetermined time (dip method), and a method in which the rinse liquid is sprayed onto the surface of the support (spray method).

According to the resist pattern forming method according to the present embodiment described above, since the resist composition according to the first aspect described above is used, it is possible to form a fine-sized pattern having both etching resistance and lithography characteristics. For example, even in the lithography by EUV, it is possible to form a fine pattern in a range of ten and several nm, which has excellent fine resolution and sufficient etching resistance.

In particular, the resist pattern forming method according to the present embodiment is a method useful for subjecting the exposed resist film to alkali development to form a resist pattern in the step (iii).

Various materials that are used in the resist composition according to the above-described embodiment and the resist pattern forming method according to the above-described embodiment (for example, a resist solvent, a developing solution, a rinse liquid, a composition for forming an antireflection film, and a composition for forming a top coat) preferably do not contain impurities such as a metal, a metal salt containing halogen, an acid, an alkali, and a component containing a sulfur atom or phosphorus atom. Here, examples of the impurities containing metal atoms include Na, K, Ca, Fe, Cu, Mn, Mg, Al, Cr, Ni, Zn, Ag, Sn, Pb, Li, and salts thereof. The content of the impurities contained in these materials is preferably 200 ppb or less, more preferably 1 ppb or less, still more preferably 100 parts per trillion (ppt) or less, and particularly preferably 10 ppt or less, where it is most preferable that the impurities are substantially free (below the detection limit of the measuring device).

### Examples

Hereinafter, the present invention will be described in more detail based on Examples; however, the present invention is not limited to these Examples.

### Preparation of Resist Composition

### Examples 1 to 26 and Comparative Examples 1 to 7

Each of the components shown in Tables 1 and 2 was mixed and dissolved to prepare a resist composition of each Example.

TABLE 1

| | | | | | | | | Content |
|---|---|---|---|---|---|---|---|---|
| | | | | | | | | proportion |
| | | | | | | | | of silicon |
| | | | | | | | | in solid |
| | Component | Component | | Component | Component | Component | | content/% |
| | (A) | (B) | | (C) | (E) | (S) | | by mass |
| Example 1 | (A)-1 | (B)-3 | (B)-8 | (C)-1 | (E)-1 | (S)-1 | (S)-2 | 12 |
| | [100] | [24] | [47] | [10] | [3] | [19200] | [4800] | |
| Example 2 | (A)-1 | (B)-3 | (B)-9 | (C)-1 | (E)-1 | (S)-1 | (S)-2 | 12 |
| | [100] | [24] | [48] | [10] | [3] | [19200] | [4800] | |
| Example 3 | (A)-1 | (B)-3 | (B)-10 | (C)-1 | (E)-1 | (S)-1 | (S)-2 | 12 |
| | [100] | [32] | [53] | [10] | [3] | [19200] | [4800] | |
| Example 4 | (A)-1 | (B)-3 | (B)-11 | (C)-1 | (E)-1 | (S)-1 | (S)-2 | 12 |
| | [100] | [32] | [48] | [10] | [3] | [19200] | [4800] | |
| Example 5 | (A)-1 | (B)-3 | (B)-12 | (C)-1 | (E)-1 | (S)-1 | (S)-2 | 12 |
| | [100] | [32] | [49] | [10] | [3] | [19200] | [4800] | |
| Example 6 | (A)-1 | (B)-3 | (B)-13 | (C)-1 | (E)-1 | (S)-1 | (S)-2 | 13 |
| | [100] | [32] | [35] | [10] | [3] | [19200] | [4800] | |
| Example 7 | (A)-1 | (B)-1 | (B)-10 | (C)-1 | (E)-1 | (S)-1 | (S)-2 | 12 |
| | [100] | [24] | [53] | [10] | [3] | [19200] | [4800] | |
| Example 8 | (A)-1 | (B)-2 | (B)-10 | (C)-1 | (E)-1 | (S)-1 | (S)-2 | 12 |
| | [100] | [30] | [53] | [10] | [3] | [19200] | [4800] | |
| Example 9 | (A)-1 | (B)-4 | (B)-10 | (C)-1 | (E)-1 | (S)-1 | (S)-2 | 12 |
| | [100] | [30] | [53] | [10] | [3] | [19200] | [4800] | |
| Example 10 | (A)-1 | (B)-5 | (B)-10 | (C)-1 | (E)-1 | (S)-1 | (S)-2 | 12 |
| | [100] | [32] | [53] | [10] | [3] | [19200] | [4800] | |
| Example 11 | (A)-1 | (B)-6 | (B)-10 | (C)-1 | (E)-1 | (S)-1 | (S)-2 | 12 |
| | [100] | [24] | [53] | [10] | [3] | [19200] | [4800] | |
| Example 12 | (A)-1 | (B)-3 | (B)-10 | (C)-2 | (E)-1 | (S)-1 | (S)-2 | 12 |
| | [100] | [32] | [53] | [10] | [3] | [19200] | [4800] | |
| Example 13 | (A)-2 | (B)-3 | (B)-10 | (C)-1 | (E)-1 | (S)-1 | (S)-2 | 10 |
| | [100] | [32] | [53] | [10] | [3] | [19200] | [4800] | |
| Comparative | (A)-1 | (B)-6 | (B)-13 | (C)-1 | (E)-1 | (S)-1 | (S)-2 | 15 |
| Example 1 | [100] | [24] | [27] | [10] | [3] | [19200] | [4800] | |
| Comparative | (A)-1 | (B)-7 | (B)-13 | (C)-1 | (E)-1 | (S)-1 | (S)-2 | 14 |
| Example 2 | [100] | [20] | [27] | [10] | [3] | [19200] | [4800] | |
| Comparative | (A)-6 | (B)-3 | (B)-9 | (C)-1 | (E)-1 | (S)-1 | (S)-2 | 0 |
| Example 3 | [100] | [32] | [53] | [10] | [3] | [19200] | [4800] | |

TABLE 2

| | | | | | | | | Content |
|---|---|---|---|---|---|---|---|---|
| | | | | | | | | proportion |
| | | | | | | | | of silicon |
| | | | | | | | | in solid |
| | Component | Component | | Component | Component | Component | | content/% |
| | (A) | (B) | | (C) | (E) | (S) | | by mass |
| Example 14 | (A)-3 | (B)-3 | (B)-8 | — | (E)-1 | (S)-1 | (S)-2 | 8 |
| | [100] | [24] | [47] | — | [3] | [19200] | [4800] | |
| Example 15 | (A)-3 | (B)-3 | (B)-9 | — | (E)-1 | (S)-1 | (S)-2 | 8 |
| | [100] | [24] | [48] | — | [3] | [19200] | [4800] | |
| Example 16 | (A)-3 | (B)-3 | (B)-10 | — | (E)-1 | (S)-1 | (S)-2 | 8 |
| | [100] | [32] | [53] | — | [3] | [19200] | [4800] | |
| Example 17 | (A)-3 | (B)-3 | (B)-11 | — | (E)-1 | (S)-1 | (S)-2 | 8 |
| | [100] | [32] | [48] | — | [3] | [19200] | [4800] | |
| Example 18 | (A)-3 | (B)-3 | (B)-12 | — | (E)-1 | (S)-1 | (S)-2 | 8 |
| | [100] | [32] | [49] | — | [3] | [19200] | [4800] | |
| Example 19 | (A)-3 | (B)-3 | (B)-13 | — | (E)-1 | (S)-1 | (S)-2 | 9 |
| | [100] | [32] | [35] | — | [3] | [19200] | [4800] | |
| Example 20 | (A)-3 | (B)-1 | (B)-10 | — | (E)-1 | (S)-1 | (S)-2 | 8 |
| | [100] | [24] | [53] | — | [3] | [19200] | [4800] | |
| Example 21 | (A)-3 | (B)-2 | (B)-10 | — | (E)-1 | (S)-1 | (S)-2 | 8 |
| | [100] | [30] | [53] | — | [3] | [19200] | [4800] | |
| Example 22 | (A)-3 | (B)-4 | (B)-10 | — | (E)-1 | (S)-1 | (S)-2 | 8 |
| | [100] | [30] | [53] | — | [3] | [19200] | [4800] | |
| Example 23 | (A)-3 | (B)-5 | (B)-10 | — | (E)-1 | (S)-1 | (S)-2 | 8 |
| | [100] | [32] | [53] | — | [3] | [19200] | [4800] | |
| Example 24 | (A)-3 | (B)-6 | (B)-10 | — | (E)-1 | (S)-1 | (S)-2 | 8 |
| | [100] | [24] | [53] | — | [3] | [19200] | [4800] | |
| Example 25 | (A)-4 | (B)-3 | (B)-10 | — | (E)-1 | (S)-1 | (S)-2 | 6 |
| | [100] | [32] | [53] | — | [3] | [19200] | [4800] | |
| Example 26 | (A)-5 | (B)-3 | (B)-10 | — | (E)-1 | (S)-1 | (S)-2 | 8 |
| | [100] | [32] | [53] | — | [3] | [19200] | [4800] | |
| Comparative | (A)-1 | (B)-6 | (B)-13 | — | (E)-1 | (S)-1 | (S)-2 | 14 |
| Example 4 | [100] | [24] | [27] | — | [3] | [19200] | [4800] | |
| Comparative | (A)-3 | (B)-6 | (B)-13 | — | (E)-1 | (S)-1 | (S)-2 | 10 |
| Example 5 | [100] | [24] | [27] | — | [3] | [19200] | [4800] | |
| Comparative | (A)-3 | (B)-7 | (B)-13 | — | (E)-1 | (S)-1 | (S)-2 | 10 |
| Example 6 | [100] | [20] | [27] | — | [3] | [19200] | [4800] | |
| Comparative | (A)-7 | (B)-3 | (B)-9 | — | (E)-1 | (S)-1 | (S)-2 | 0 |
| Example 7 | [100] | [32] | [53] | — | [3] | [19200] | [4800] | |

In Tables 1 and 2, each abbreviation has the following meaning. The numerical value in the brackets indicate the blending amount (parts by mass: in terms of solid content) of each component.

(A)-1: A polymeric compound represented by Chemical Formula (A0-1). The weight average molecular weight (Mw) in terms of the standard polystyrene equivalent value, acquired by the GPC measurement, is 3,700, and the molecular weight polydispersity (Mw/Mn) is 1.8. The copolymerization compositional ratio (the ratio (molar ratio) between constitutional units in the structural formula) is l/m=60/40. The silicon content proportion in the polymeric compound is 23% by mass.

The silicon content proportion in the polymeric compound represented by Chemical Formula (A0-1) was calculated according to the following expression.

The silicon content proportion (%)=(the number of silicon atoms present in the polymeric compound represented by Chemical Formula (A0-1)×the atomic weight of silicon)/(the total atomic weight calculated by multiplying the number of atoms of each atom constituting the polymeric compound represented by Chemical Formula (A0-1) by each atomic weight and summing up each value obtained)×100

That is, the silicon content proportion in the polymeric compound represented by Chemical Formula (A0-1) was calculated as follows.

{(28×1)×100}/[{(28×1)+(16×2.5)+(1×7)+(12×7)}×60+{(28×1)+(16×1.5)+(1×3)+(12×1)}×40]×100≈22.9(% by mass)

(A)-2: A polymeric compound represented by Chemical Formula (A0-2). The weight average molecular weight (Mw) in terms of the standard polystyrene equivalent value, acquired by the GPC measurement, is 2,500, and the molecular weight polydispersity (Mw/Mn) is 1.5. The copolymerization compositional ratio (the ratio (molar ratio) between constitutional units in the structural formula) is l/m/n=70/10/20. The silicon content proportion in the polymeric compound is 20% by mass.

(A)-3: A polymeric compound represented by Chemical Formula (A0-3). The weight average molecular weight (Mw) in terms of the standard polystyrene equivalent value, acquired by the GPC measurement, is 3,800, and molecular weight polydispersity (Mw/Mn) is 2.0. The copolymerization compositional ratio (the ratio (molar ratio) between constitutional units in the structural formula) is l/m=65/35. The silicon content proportion in the polymeric compound is 15% by mass.

(A)-4: A polymeric compound represented by Chemical Formula (A0-4). The weight average molecular weight (Mw) in terms of the standard polystyrene equivalent value, acquired by the GPC measurement, is 2,900, and molecular weight polydispersity (Mw/Mn) is 2.3. The copolymerization compositional ratio (the ratio (molar ratio) between constitutional units in the structural formula) is l/m/n=20/60/20. The silicon content proportion in the polymeric compound is 12% by mass.

(A)-5: A polymeric compound represented by Chemical Formula (A0-5). The weight average molecular weight (Mw) in terms of the standard polystyrene equivalent value, acquired by the GPC measurement, is 3,300, and the molecular weight polydispersity (Mw/Mn) is 2.3. The copolymerization compositional ratio (the ratio (molar ratio) between constitutional units in the structural formula) is/m=50/50. The silicon content proportion in the polymeric compound is 14% by mass.

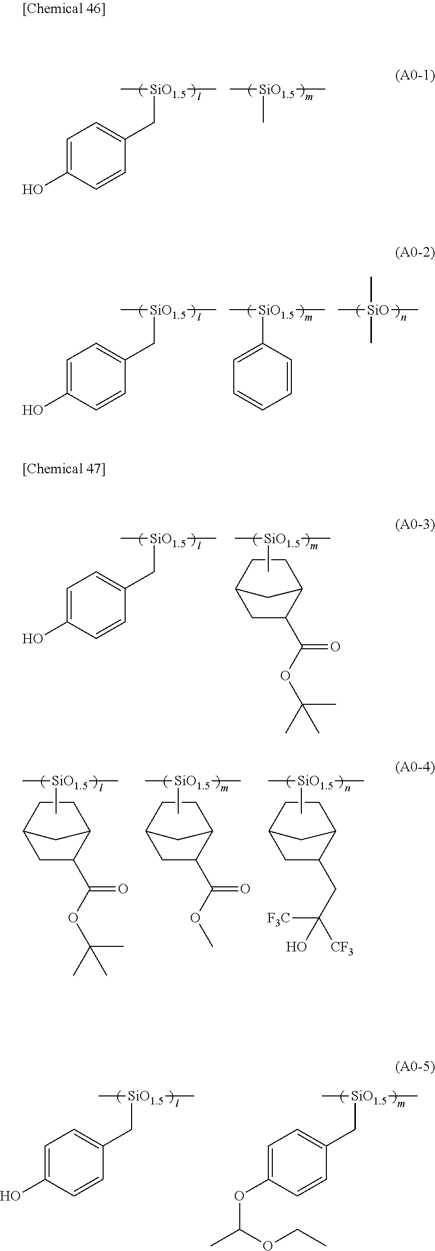

(A)-6: A polymeric compound represented by Chemical Formula (A-1). The weight average molecular weight (Mw) in terms of the standard polystyrene equivalent value, acquired by the GPC measurement, is 2,500, and the molecular weight polydispersity (Mw/Mn) is 1.2. The copolymerization compositional ratio (the ratio (molar ratio) between constitutional units in the structural formula) is l/m=85/15. The silicon content proportion in the polymeric compound is 0% by mass.

(A)-7: A polymeric compound represented by Chemical Formula (A-2). The weight average molecular weight (Mw) in terms of the standard polystyrene equivalent value, acquired by the GPC measurement, is 4,100, and molecular weight polydispersity (Mw/Mn) is 1.4. The copolymerization compositional ratio (the ratio (molar ratio) between constitutional units in the structural formula) is l/m=50/50. The silicon content proportion in the polymeric compound is 0% by mass.

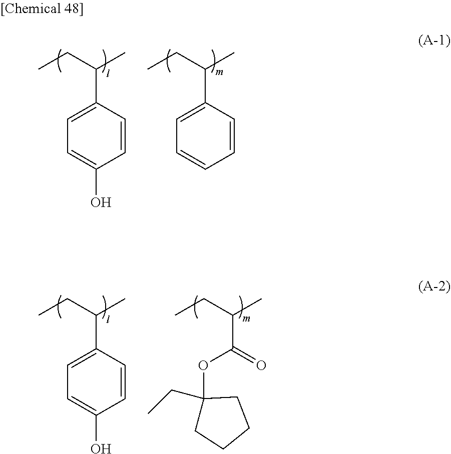

(B)-1 to (B)-5: Acid generators consisting of compounds each represented by Chemical Formulae (b0-1b-1) to (b0-1b-5).

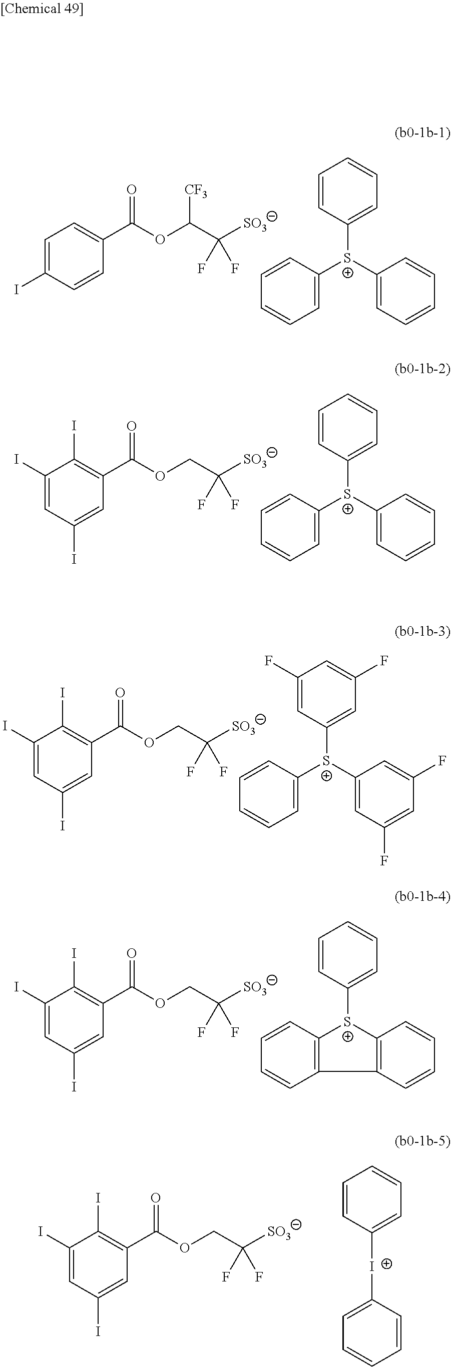

(B)-6: An acid generator consisting of a compound represented by Chemical Formula (B1-1).

(B)-7: An acid generator consisting of a compound represented by Chemical Formula (B1-2).

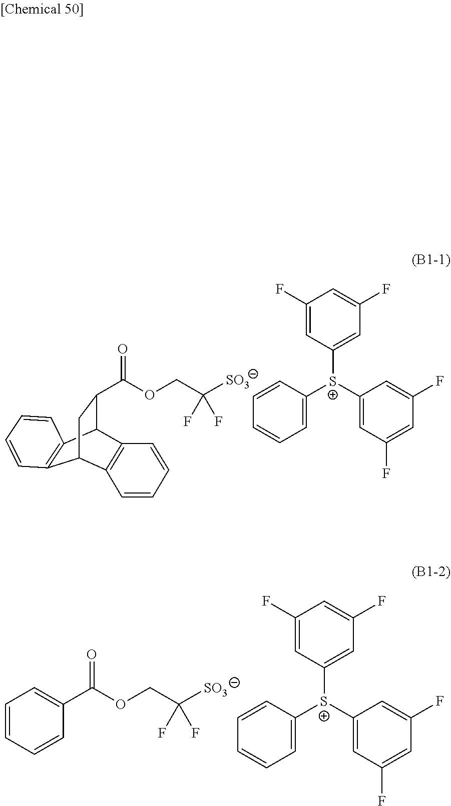

(B)-8 to (B)-12: Acid generators consisting of compounds each represented by Chemical Formulae (b0-2-1) to (b0-2-5).

(B)-13: An acid generator consisting of a compound represented by Chemical Formula (B1-3).

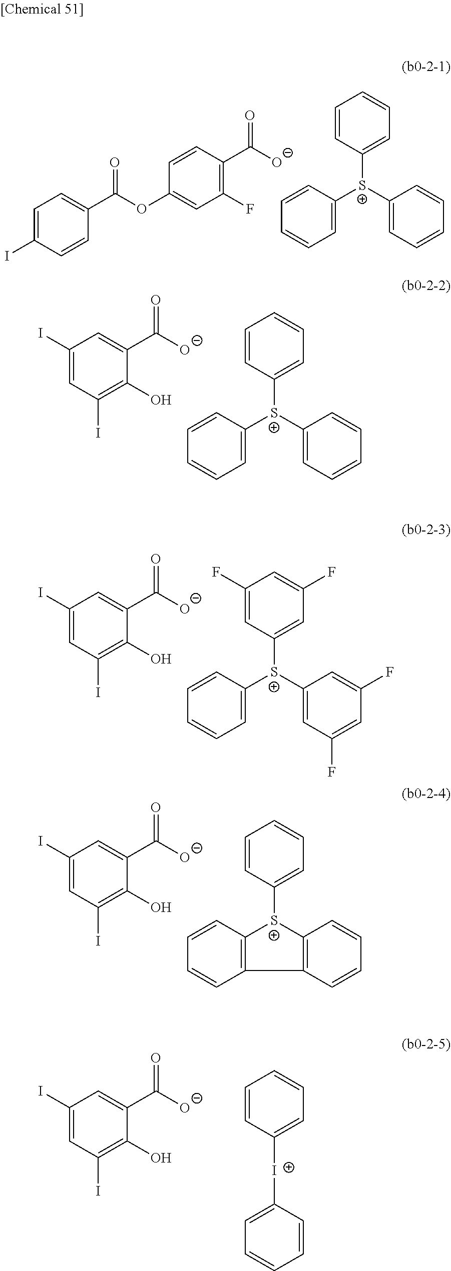

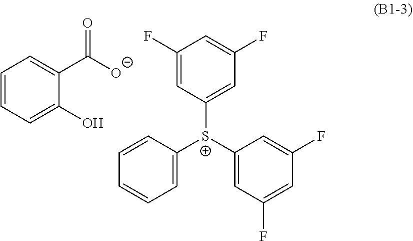 [SMILES: O=C([O-])c1ccccc1O ; Fc1cc(F)cc([S+](c2ccccc2)c2cc(F)cc(F)c2)c1]

(C)-1: A crosslinking agent consisting of a compound represented by Chemical Formula (C-1).

(C)-2: A crosslinking agent consisting of a compound represented by Chemical Formula (C-2).

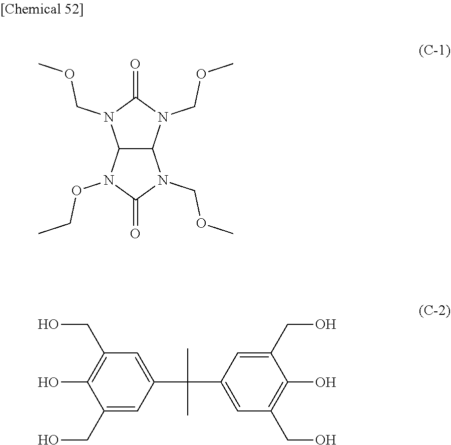

(E)-1: Salicylic acid.

(S)-1: Propylene glycol monomethyl ether.

(S)-2: Propylene glycol monomethyl ether acetate.

<Content Proportion of Silicon in Solid Content of Resist Composition>

The content proportion of the silicon in the solid content of the resist composition was calculated as follows.

In a case of the resist composition of Example 1, the component (A) to be blended is a polymeric compound represented by Chemical Formula (A0-1).

The silicon content proportion in this polymeric compound is 23% by mass.

The content proportion of this polymeric compound in the solid content of the resist composition is 100/(100+24+47+10+3)×100≈54.3 (% by mass).

As a result, the content proportion of the silicon in the solid content of the resist composition is calculated as 23×(54.3/100)=12.4 (% by mass).

<Resist Pattern Formation>

Step (i):

A resist organic underlayer film composition “AL412”, (manufactured by

Brewer Science Inc.) was applied onto a 12-inch silicon wafer using a spin coater and sintered on a hot plate at 205° C. for 60 seconds to form an organic underlayer film having a film thickness of 20 nm.

The resist composition of each example was applied onto the organic underlayer film using a spin coater, and a pre-baking (PAB) treatment was carried out at 85° C. for 60 seconds on a hot plate to form a resist film having a film thickness of 22 nm.

Step (ii):

Next, the resist film was irradiated with EUV light (13.5 nm) through a photomask by an EUV exposure apparatus NXE3400 (manufactured by ASML Holding N.V., numerical aperture (NA)=0.33, illumination conditions: annular σ-in=0.60, σ-out=0.82).

Thereafter, a post-exposure baking (PEB) treatment was carried out on the resist film at 90° C. for 60 seconds.

Step (iii):

Subsequently, alkali development was carried out at 23° C. for 10 seconds with a 2.38% by mass tetramethylammonium hydroxide (TMAH) aqueous solution (product name: NMD-3, manufactured by TOKYO OHKA KOGYO CO., LTD.).

Thereafter, water rinsing was carried out for 30 seconds using pure water, followed by shake-off drying.

As a result, a line and space pattern (an LS pattern) having a line width of 14 nm was formed.

[Evaluation of Optimum Exposure Amount (Eop)]

According to the resist pattern formation described above, an optimum exposure amount Eop (mJ/cm²) for forming an LS pattern having a line width of 14 nm was determined. The results are shown in Tables 3 and 4.

[Evaluation of Linewise Roughness (LWR)]

For the LS pattern having a line width of 14 nm formed according to the resist pattern formation described above, 3σ, which is a scale indicating LWR, was determined.

The term “3σ” means a triple value (unit: nm) of the standard deviation (a) determined from measurement results obtained by measuring 400 line positions in the longitudinal direction of the line with a scanning electron microscope (acceleration voltage: 800V, product name: S-9380, manufactured by Hitachi High-Tech Corporation). The results are shown in Tables 3 and 4.

The smaller the value of 3σ is, the smaller the roughness in the line side wall is, which means an LS pattern having a more uniform width was obtained.

[Evaluation of Etching Resistance]

The resist composition of each example was applied onto an 8-inch silicon wafer using a spin coater, and a baking treatment was carried out at 90° C. for 60 seconds on a hot plate to form a resist film having a film thickness of 50 nm.

An 8% by mass propylene glycol monomethyl ether acetate solution of a cresol novolak resin synthesized according to a conventional method was applied onto an 8-inch silicon wafer using a spin coater, and a baking treatment was carried out at 280° C. for 60 seconds on a hot plate to form an organic film for comparing etching resistance having a film thickness of 200 nm.

Each of the formed resist film and the formed organic film for comparing etching resistance was treated with a TCP type dry etching apparatus (O₂ flow rate=20 sccm, N₂ flow rate=400 sccm, pressure=12 Pa, temperature=25° C., plasma source RF output=600 W, bias RF output=200 W) for 30 seconds.

Then, the etching rate ratio of each resist film formed from the resist composition of each example to the organic film for comparing etching resistance was calculated. The results are shown in Tables 3 and 4.

In a case where the etching rate ratio is less than 0.1, it can be said that the etching resistance is favorable.

TABLE 3

| | PAB | PEB | Eop | LWR | Etching |
|---|---|---|---|---|---|
| | (° C.) | (° C.) | (mJ/cm²) | (nm) | rate ratio |
| Example 1 | 85 | 90 | 61 | 2.93 | 0.061 |
| Example 2 | 85 | 90 | 57 | 2.83 | 0.065 |
| Example 3 | 85 | 90 | 56 | 2.76 | 0.065 |
| Example 4 | 85 | 90 | 57 | 2.81 | 0.063 |
| Example 5 | 85 | 90 | 59 | 2.95 | 0.065 |
| Example 6 | 85 | 90 | 63 | 2.76 | 0.056 |
| Example 7 | 85 | 90 | 55 | 3.04 | 0.059 |
| Example 8 | 85 | 90 | 57 | 2.83 | 0.065 |
| Example 9 | 85 | 90 | 56 | 2.83 | 0.064 |
| Example 10 | 85 | 90 | 59 | 2.81 | 0.064 |
| Example 11 | 85 | 90 | 63 | 2.76 | 0.058 |
| Example 12 | 85 | 90 | 56 | 2.87 | 0.065 |
| Example 13 | 85 | 90 | 58 | 2.92 | 0.070 |
| Comparative | 85 | 90 | 60 | 3.30 | 0.052 |
| Example 1 | | | | | |
| Comparative | 85 | 90 | 54 | 4.16 | 0.051 |
| Example 2 | | | | | |
| Comparative | 85 | 90 | 62 | 3.41 | 1.223 |
| Example 3 | | | | | |

From the results shown in Table 3, in a case where a negative-tone resist pattern is formed according to the alkali developing process, it can be confirmed that the resist compositions of Examples 1 to 13 have a small value of the etching rate ratio and have a small LWR (30) value as compared with the resist compositions of Comparative Examples 1 to 3. That is, according to the resist compositions of Examples 1 to 13 to which the present invention has been applied, it can be said that a fine-sized pattern having both etching resistance and lithography characteristics can be formed.

TABLE 4

| | PAB | PEB | Eop | LWR | Etching |
|---|---|---|---|---|---|
| | (° C.) | (° C.) | (mJ/cm²) | (nm) | rate ratio |
| Example 14 | 85 | 90 | 64 | 3.15 | 0.077 |
| Example 15 | 85 | 90 | 62 | 3.12 | 0.081 |
| Example 16 | 85 | 90 | 61 | 3.08 | 0.082 |
| Example 17 | 85 | 90 | 60 | 3.10 | 0.079 |
| Example 18 | 85 | 90 | 62 | 3.14 | 0.080 |
| Example 19 | 85 | 90 | 67 | 3.10 | 0.074 |
| Example 20 | 85 | 90 | 58 | 3.14 | 0.080 |
| Example 21 | 85 | 90 | 60 | 3.12 | 0.083 |
| Example 22 | 85 | 90 | 58 | 3.11 | 0.084 |
| Example 23 | 85 | 90 | 61 | 3.15 | 0.082 |
| Example 24 | 85 | 90 | 66 | 3.12 | 0.077 |
| Example 25 | 85 | 90 | 63 | 3.13 | 0.097 |
| Example 26 | 85 | 90 | 57 | 3.24 | 0.078 |
| Comparative | 85 | 90 | Not resolved | | 0.055 |
| Example 4 | | | | | |
| Comparative | 85 | 90 | 60 | 3.31 | 0.074 |
| Example 5 | | | | | |
| Comparative | 85 | 90 | 52 | 4.95 | 0.068 |
| Example 6 | | | | | |
| Comparative | 85 | 90 | 57 | 3.24 | 1.418 |
| Example 7 | | | | | |

From the results shown in Table 4, even in a case where a positive-tone resist pattern is formed according to the alkali developing process, it can be confirmed that the resist compositions of Examples 14 to 26 have a small value of the etching rate ratio and have a small LWR (30) value as compared with the resist compositions of Comparative Examples 5 to 6. That is, according to the resist compositions of Examples 14 to 26 to which the present invention has been applied, it can be said that a fine-sized pattern having both etching resistance and lithography characteristics can be formed.

The preferred Examples of the present invention have been described above; however, the present invention is not limited to these Examples. Additions, omissions, substitutions, and other modifications of the configuration can be made without departing from the spirit of the present invention. The present invention is not limited by the description described above and is limited only by the scope of the attached Claims.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

What is claimed is:

1. A resist composition comprising:
a silicon-containing resin (A); and
an acid generator component (B) that generates acid upon exposure,
wherein the acid generator component (B) includes an onium salt (B0) consisting of an anion moiety having an iodine atom and a cation moiety.

2. The resist composition according to claim 1, wherein the onium salt (B0) is at least one onium salt selected from the group consisting of a sulfonic acid salt represented by General Formula (b0-1) and a carboxylic acid salt represented by General Formula (b0-2): 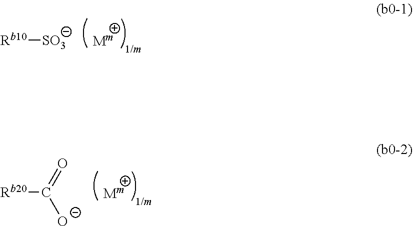
wherein R^{b10} and R^{b20} each independently represents an organic group having an iodine atom, which has 1 to 40 carbon atoms, M^{m+} represents an m-valent onium cation, and m represents an integer of 1 or more.

3. The resist composition according to claim 2, wherein R^{b10} and R^{b20} each independently represents a group represented by General Formula (b0-r-1): 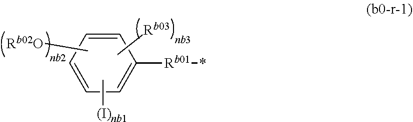
wherein R^{b01} represents a divalent linking group or a single bond, I is an iodine atom, R^{b02} represents a hydrocarbon group having 1 to 6 carbon atoms or a hydrogen atom, R^{b03} represents a hydrocarbon group having 1 to 6 carbon atoms, nb1 represents an integer in a range of 1 to 5, nb2 represents an integer in a range of 0 to 4, nb3 represents an integer in a range of 0 to 4, where 1≤nb1+nb2+nb3≤5 is satisfied, and * represents a bonding site for bonding to a sulfur atom of SO₃⁻ in General Formula (b0-1), or a bonding site for bonding to a carbon atom of C(═O)O⁻ in General Formula (b0-2).

4. The resist composition according to claim 1, wherein the silicon-containing resin (A) includes a silicon-containing polymer (A0) having a constitutional unit represented by General Formula (a0-1): 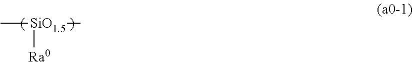
wherein Ra⁰ represents an organic group having 1 to 40 carbon atoms or a hydrogen atom.

5. The resist composition according to claim 4, wherein the silicon-containing polymer (A0) has a constitutional unit represented by General Formula (a0-1-1): 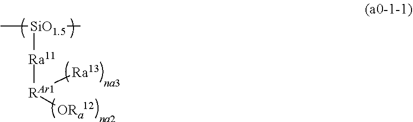
wherein R^{Ar1} represents an aromatic hydrocarbon group, Ra¹¹ represents a divalent linking group or a single bond, Ra¹² represents a hydrocarbon group having 1 to 6 carbon atoms or a hydrogen atom, Ra¹³ represents a hydrocarbon group having 1 to 6 carbon atoms, na2 is 1 or 2, and na3 represents an integer in a range of 0 to 4.

6. The resist composition according to claim 1, further comprising a crosslinking agent component.

7. The resist composition according to claim 4, wherein the silicon-containing polymer (A0) has a constitutional unit represented by General Formula (a0-1-2): 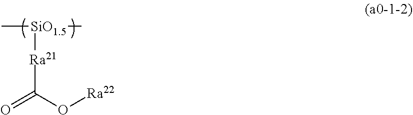
wherein Ra²¹ represents a divalent linking group or a single bond, and Ra²² represents an acid dissociable group.

8. The resist composition according to claim 4, wherein the silicon-containing polymer (A0) has a constitutional unit represented by General Formula (a0-1-3): 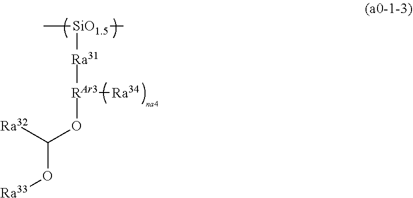
wherein R^{Ar3} represents an aromatic hydrocarbon group, Ra³¹ represents a divalent linking group or a single bond, Ra³² and Ra³³ each independently represent a hydrocarbon group having 1 to 20 carbon atoms or a hydrogen atom, Ra³² and Ra³³ may be bonded to each other to form a ring, Ra³⁴ represents a hydrocarbon group having 1 to 6 carbon atoms, and na4 represents an integer in a range of 0 to 4.

9. The resist composition according to claim 1, wherein a content proportion of silicon (Si) in a solid content of the resist composition is 5% by mass or more.

10. A resist pattern forming method, comprising:
forming a resist film on a support using the resist composition according to claim 1;
exposing the resist film; and
developing the exposed resist film to form a resist pattern.

11. The resist pattern forming method according to claim 10, wherein the resist film is exposed with an extreme ultraviolet ray.
